(19) United States
(12) Patent Application Publication
(10) Pub. No.: US 2025/0287775 A1
(43) Pub. Date: Sep. 11, 2025

(54) Light-Emitting Device And Method For Manufacturing Light-Emitting Apparatus

(71) Applicant: Semiconductor Energy Laboratory Co., Ltd., Kanagawa-ken (JP)

(72) Inventors: Nozomu SUGISAWA, Isehara, Kanagawa (JP); Tsunenori SUZUKI, Yokohama, Kanagawa (JP); Tomoya AOYAMA, Atsugi, Kanagawa (JP); Shinya FUKUZAKI, Atsugi, Kanagawa (JP)

(73) Assignee: Semiconductor Energy Laboratory Co., Ltd., Kanagawa-ken (JP)

(21) Appl. No.: 18/858,931

(22) PCT Filed: Apr. 17, 2023
(86) PCT No.: PCT/IB2023/053892

§ 371 Date: Oct. 22, 2024

(30) Foreign Application Priority Data
Apr. 29, 2022 (JP) 2022-075606
Jun. 2, 2022 (JP) 2022-090426
Jul. 4, 2022 (JP) 2022-107743

(51) Int. Cl. H10K 50/16; H10K 59/00; H10K 59/12; H10K 85/60; H10K 102/00

(52) U.S. Cl. CPC H10K 50/166; H10K 59/1201; H10K 59/771; H10K 85/6572; H10K 2102/351

(57) ABSTRACT

A light-emitting device enabling a light-emitting apparatus that has high resolution, high reliability, and low manufacturing cost to be achieved is provided. A light-emitting device to be provided includes a first electrode, a second electrode, and a first layer and a second layer provided therebetween. The first layer is positioned closer to the first electrode than the second layer is. The first electrode and the first layer are independent layers for each light-emitting device. The second electrode and the second layer are continuous layers shared by a plurality of light-emitting devices. The first layer includes a layer containing a light-emitting substance and a first electron-transport layer. The second layer includes a second electron-transport layer. The first electron-transport layer is positioned between the light-emitting layer and the second electron-transport layer. The first electron-transport layer contains a first compound having an electron-transport property and a glass transition temperature higher than or equal to 110° C. The second electron-transport layer contains a second compound having an electron-transport property.

### TECHNICAL FIELD

One embodiment of the present invention relates to a light-emitting device and a method for manufacturing a light-emitting apparatus.

Note that one embodiment of the present invention is not limited to the above technical field. Examples of the technical field of one embodiment of the present invention include a semiconductor device, a display apparatus, a light-emitting apparatus, a power storage device, a memory device, an electronic device, a lighting device, an input device (e.g., a touch sensor), an input/output device (e.g., a touch panel), a method for driving any of them, and a method for manufacturing any of them.

### BACKGROUND ART

Recent display apparatuses have been expected to be applied to a variety of uses. Usage examples of large-sized display apparatuses include a television device for home use (also referred to as TV or television receiver), digital signage, and a PID (Public Information Display). In addition, a smartphone and a tablet terminal each including a touch panel, and the like, are being developed as portable information terminals.

Furthermore, higher-resolution display apparatuses have also been required. As devices requiring high-resolution display apparatuses, for example, devices for virtual reality (VR), augmented reality (AR), substitutional reality (SR), or mixed reality (MR) have been given, and high-resolution apparatuses used for such devices have been actively developed.

Light-emitting devices using organic compounds suitable for the above high-resolution display apparatuses have been actively researched. Light-emitting devices utilizing an electroluminescence (hereinafter referred to as EL) phenomenon of an organic compound (also referred to as organic EL devices or organic EL elements) have features such as ease of reduction in thickness and weight, high-speed response to input signals, and driving with a constant DC voltage power source, and have been used in display apparatuses.

In order to obtain a higher-resolution light-emitting apparatus using an organic EL device, patterning an organic layer by a photolithography method using a photoresist or the like, instead of an evaporation method using a metal mask, has been studied. By using the photolithography method, a high-resolution display apparatus in which a distance between EL layers is several micrometers can be obtained (see Patent Document 1, for example).

[Reference][Patent Document]

[Patent Document 1] Japanese Translation of PCT International Application No. 2018-521459

### SUMMARY OF THE INVENTION

### Problems to be Solved by the Invention

It has been known that EL layers exposed to atmospheric components such as water and oxygen have affected initial characteristics or reliability, and thus have been treated in a near-vacuum atmosphere in common-sense steps. In particular, light-emitting layers are likely to be affected by exposure to the air and thus needs to be treated prudently.

However, processing steps with the aforementioned photolithography method inevitably include exposure of the surface of the EL layer including the light-emitting layer to the air. Thus, processing by a photolithography method has been often performed on an electron-transport layer which is as far from the light-emitting layer as possible, in particular, on the interface between the electron-transport layer and an electron-injection layer or the interface between the electron-transport layer and a cathode.

In that case, characteristics required to employ the photolithography method, such as tolerances to heat and air exposure, are priorities that should be considered in selecting a material used for the electron-transport layer exposed to an air atmosphere and the photolithography process. As a result, the use of low-cost and high-performance materials, which have been conventionally used, is limited, which causes problems such as the necessity of exploration of a new material and device structures, the necessity of accepting a plateau level of performance, and an increase in cost.

In view of the above, an object of one embodiment of the present invention is to provide a light-emitting apparatus that has high resolution, high reliability, and low manufacturing cost.

Another object of one embodiment of the present invention is to provide a light-emitting device with high heat resistance. Another object of one embodiment of the present invention is to provide a light-emitting device with high reliability.

Another object of one embodiment of the present invention is to provide light-emitting devices with favorable reliability, which can be arranged at a high density. Another object of one embodiment of the present invention is to provide a light-emitting device with favorable reliability, which can provide a high-resolution display apparatus. Another object of one embodiment of the present invention is to provide a light-emitting device with favorable reliability, which can provide an inexpensive high-resolution display apparatus.

Another object of one embodiment of the present invention is to provide a highly reliable display apparatus. Another object of one embodiment of the present invention is to provide a high-definition display apparatus with favorable reliability. Another object of one embodiment of the present invention is to provide an inexpensive high-definition display apparatus with favorable reliability.

Other objects are to provide a novel organic compound, a novel light-emitting device, a novel display apparatus, a novel display module, and a novel electronic device.

Note that the description of these objects does not preclude the existence of other objects. One embodiment of the present invention does not necessarily need to achieve all of these objects. Other objects can be derived from the description of the specification, the drawings, and the claims.

### Means for Solving the Problems

One embodiment of the present invention is a light-emitting device that is one of a plurality of light-emitting devices formed over an insulating surface, including a first electrode, a second electrode, a first layer, and a second layer. The first layer is positioned closer to the first electrode than the second layer is. The first layer and the second layer are positioned between the first electrode and the second electrode. The first electrode is an independent layer for each of the plurality of light-emitting devices. The second electrode is a continuous layer shared by the plurality of light-emitting devices. The first layer is an independent layer for each of the plurality of light-emitting devices. The second layer is a continuous layer shared by the plurality of light-emitting devices. The first layer includes a light-emitting layer containing a light-emitting substance and a first electron-transport layer. The second layer includes a second electron-transport layer. The first electron-transport layer is positioned between the light-emitting layer and the second electron-transport layer. The first electron-transport layer contains a first compound having an electron-transport property and a glass transition temperature higher than or equal to 110° C. The second electron-transport layer contains a second compound having an electron-transport property.

Another embodiment of the present invention is a light-emitting device that is one of a plurality of light-emitting devices formed over an insulating surface, including a first electrode, a second electrode, a first layer, and a second layer. The first layer is positioned closer to the first electrode than the second layer is. The first layer and the second layer are positioned between the first electrode and the second electrode. The first electrode is an independent layer for each of the plurality of light-emitting devices. The second electrode is a continuous layer shared by the plurality of light-emitting devices. The first layer is an independent layer for each of the plurality of light-emitting devices. The second layer is a continuous layer shared by the plurality of light-emitting devices. The first layer includes a light-emitting layer containing a light-emitting substance and a first electron-transport layer. The second layer includes a second electron-transport layer. The first electron-transport layer is positioned between the light-emitting layer and the second electron-transport layer. The first electron-transport layer contains a first compound having an electron-transport property and a glass transition temperature higher than or equal to 110° C. and has a thickness greater than or equal to 5 nm and less than or equal to 30 nm. The second electron-transport layer contains a second compound having an electron-transport property.

Another embodiment of the present invention is a light-emitting device that is one of a plurality of light-emitting devices formed over an insulating surface, including a first electrode, a second electrode, a first layer, and a second layer. The first layer is positioned closer to the first electrode than the second layer is. The first layer and the second layer are positioned between the first electrode and the second electrode. The first electrode is an independent layer for each of the plurality of light-emitting devices. The second electrode is a continuous layer shared by the plurality of light-emitting devices. The first layer is an independent layer for each of the plurality of light-emitting devices. The second layer is a continuous layer shared by the plurality of light-emitting devices. The first layer includes a light-emitting layer containing a light-emitting substance and a first electron-transport layer. The second layer includes a second electron-transport layer and an electron-injection layer. The first electron-transport layer is positioned between the light-emitting layer and the second electron-transport layer. The electron-injection layer is positioned between the second electron-transport layer and the second electrode. The first electron-transport layer contains a first compound having an electron-transport property and a glass transition temperature higher than or equal to 110° C. The second electron-transport layer contains a second compound having an electron-transport property. The electron-injection layer contains an alkali metal, an alkaline earth metal, or a compound of any of the alkali metal and the alkaline earth metal.

Another embodiment of the present invention is a light-emitting device in which a first compound is an organic compound having any one of triazine, pyridine, a furodiazine skeleton, and a diazine skeleton. Note that examples of the diazine skeleton include a pyrazine skeleton, a pyrimidine skeleton, and a pyridazine skeleton.

Another embodiment of the present invention is a light-emitting device having the above structure, in which the first compound has a dibenzoquinoxaline skeleton.

Another embodiment of the present invention is a light-emitting device having the above structure, in which the second compound is an organic compound having any one of a phenanthroline skeleton, a triazine skeleton, a pyridine skeleton, a furodiazine skeleton, and a diazine skeleton or an organometallic complex having a quinolinol ligand.

Another embodiment of the present invention is a light-emitting device having the above structure, in which the first compound is an organic compound having any one of a dibenzoquinoxaline skeleton, a triazine skeleton, a pyridine skeleton, a furodiazine skeleton, and a diazine skeleton, and the second compound is an organic compound having any one of a phenanthroline skeleton, a triazine skeleton, a pyridine skeleton, and a pyrimidine skeleton or an organometallic complex having a quinolinol ligand.

Another embodiment of the present invention is a light-emitting device having the above structure, in which the first compound is an organic compound having a dibenzoquinoxaline skeleton, and the second compound is an organic compound having any one of a phenanthroline skeleton, a triazine skeleton, a pyridine skeleton, a furodiazine skeleton, and a diazine skeleton or an organometallic complex having a quinolinol ligand.

Another embodiment of the present invention is a method for manufacturing a light-emitting apparatus, including steps of forming a plurality of first electrodes over an insulating surface; forming a first layer including a light-emitting layer and a first electron-transport layer over the first electrodes; performing a photolithography process on the first layer to form a plurality of island-shaped first layers that are for the respective first electrodes and independent of each other; performing heating at higher than or equal to 80° C. and lower than 110° C. at a vacuum degree lower than or equal to 1×10⁻⁴ Pa; forming a second layer covering the plurality of island-shaped first layers; and forming a second electrode covering the second layer.

Another embodiment of the present invention is a method for manufacturing a light-emitting apparatus, including steps of forming a plurality of first electrodes over an insulating surface; forming a first layer including a light-emitting layer and a first electron-transport layer over the first electrodes; performing a photolithography process on the first layer to form a plurality of island-shaped first layers that are for the respective first electrodes and independent of each other; performing heating at higher than or equal to 80° C. and lower than 110° C. for longer than or equal to one hour and shorter than or equal to three hours at a vacuum degree lower than or equal to 1×10⁻⁴ Pa; forming a second layer covering the plurality of island-shaped first layers; and forming a second electrode covering the second layer.

Another embodiment of the present invention is a method for manufacturing a light-emitting apparatus having the above structure, in which a wavelength of light irradiation from the formation of the first layer until the formation of the second electrode is greater than or equal to 480 nm.

Another embodiment of the present invention is a display module including the above light-emitting device and at least one of a connector and an integrated circuit.

Another embodiment of the present invention is an electronic device including the above light-emitting device and at least one of a housing, a battery, a camera, a speaker, and a microphone.

### Effect of the Invention

According to one embodiment of the present invention, a light-emitting apparatus that has high resolution, high reliability, and low manufacturing cost can be provided.

According to another embodiment of the present invention, a light-emitting device with favorable heat resistance can be provided. According to another embodiment of the present invention, a light-emitting device with favorable reliability can be provided.

According to another embodiment of the present invention, light-emitting devices with favorable reliability, which can be arranged at a high density, can be provided. According to another embodiment of the present invention, a light-emitting device with favorable reliability, which can provide a high-resolution display apparatus. According to another embodiment of the present invention, a light-emitting device with favorable reliability, which can provide an inexpensive high-resolution display apparatus.

According to another embodiment of the present invention, a highly reliable display apparatus can be provided. According to another embodiment of the present invention, a high-definition display apparatus with favorable reliability can be provided. According to another embodiment of the present invention, an inexpensive high-resolution display apparatus with favorable reliability can be provided.

Another object is to provide a novel display apparatus, a novel display module, or a novel electronic device.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1 shows reliability of light-emitting devices.

FIG. 2 shows reliability of light-emitting devices.

FIG. 3A to FIG. 3C are diagrams illustrating light-emitting devices.

FIG. 4A and FIG. 4B are diagrams each illustrating a light-emitting device.

FIG. 5A and FIG. 5B are a top view and a cross-sectional view of a light-emitting apparatus.

FIG. 6A to FIG. 6E are cross-sectional views illustrating an example of a method for manufacturing a display apparatus.

FIG. 7A to FIG. 7D are cross-sectional views illustrating an example of a method for manufacturing a display apparatus.

FIG. 8A to FIG. 8D are cross-sectional views illustrating an example of a method for manufacturing a display apparatus.

FIG. 9A to FIG. 9C are cross-sectional views illustrating an example of a method for manufacturing a display apparatus.

FIG. 10A to FIG. 10C are cross-sectional views illustrating an example of a method for manufacturing a display apparatus.

FIG. 11A to FIG. 11C are cross-sectional views illustrating an example of a method for manufacturing a display apparatus.

FIG. 12A and FIG. 12B are perspective views illustrating a structure example of a display module.

FIG. 13A and FIG. 13B are cross-sectional views illustrating structure examples of display apparatuses.

FIG. 14 is a perspective view illustrating a structure example of a display apparatus.

FIG. 15 is a cross-sectional view illustrating a structure example of a display apparatus.

FIG. 16 is a cross-sectional view illustrating a structure example of a display apparatus.

FIG. 17 is a cross-sectional view illustrating a structure example of a display apparatus.

FIG. 18A to FIG. 18D are diagrams illustrating examples of electronic devices.

FIG. 19A to FIG. 19F are diagrams illustrating examples of electronic devices.

FIG. 20A to FIG. 20G are diagrams illustrating examples of electronic devices.

FIG. 21 is a graph showing luminance-current density characteristics of light-emitting device B0, light-emitting device B100_1, light-emitting device B100_2, and light-emitting device B100_3.

FIG. 22 is a graph showing luminance-voltage characteristics of light-emitting device B0, light-emitting device B100_1, light-emitting device B100_2, and light-emitting device B100_3.

FIG. 23 is a graph showing current efficiency-luminance characteristics of light-emitting device B0, light-emitting device B100_1, light-emitting device B100_2, and light-emitting device B100_3.

FIG. 24 is a graph showing current-voltage characteristics of light-emitting device B0, light-emitting device B100_1, light-emitting device B100_2, and light-emitting device B100_3.

FIG. 25 is a graph showing emission spectra of light-emitting device B0, light-emitting device B100_1, light-emitting device B100_2, the light-emitting device B100_3.

FIG. 26 is a graph showing luminance-current density characteristics of light-emitting device B0, light-emitting device B80_1, light-emitting device B80_2, and light-emitting device B80_3.

FIG. 27 is a graph showing luminance-voltage characteristics of light-emitting device B0, light-emitting device B80_1, light-emitting device B80_2, and light-emitting device B80_3.

FIG. 28 is a graph showing current efficiency-luminance characteristics of light-emitting device B0, light-emitting device B80_1, light-emitting device B80_2, and light-emitting device B80_3.

FIG. 29 is a graph showing current-voltage characteristics of light-emitting device B0, light-emitting device B80_1, light-emitting device B80_2, and light-emitting device B80_3.

FIG. 30 is a graph showing emission spectra of light-emitting device B0, light-emitting device B80_1, light-emitting device B80_2, and light-emitting device B80_3.

FIG. 31A is a graph showing time dependence of normalized luminance of light-emitting device B0, light-emitting device B100_1, light-emitting device B100_2, and light-emitting device B100_3, and FIG. 31B is a graph showing time dependence of normalized luminance of light-emitting device B0, light-emitting device B80_1, light-emitting device B80_2, and light-emitting device B80_3.

FIG. 32 is a graph showing current density-luminance characteristics of Samples 1-1, 2-1, 3-1, and 4.

FIG. 33 shows blue index-luminance characteristics of Samples 1-1, 2-1, 3-1, and 4.

FIG. 34 is a graph showing luminance-current density characteristics of light-emitting device G0, light-emitting device G100_1, light-emitting device G100_2, and light-emitting device G100_3.

FIG. 35 is a graph showing luminance-voltage characteristics of light-emitting device G0, light-emitting device G100_1, light-emitting device G100_2, and light-emitting device G100_3.

FIG. 36 is a graph showing current efficiency-luminance characteristics of light-emitting device G0, light-emitting device G100_1, light-emitting device G100_2, the light-emitting device G100_3.

FIG. 37 is a graph showing current-voltage characteristics of light-emitting device G0, light-emitting device G100_1, light-emitting device G100_2, and light-emitting device G100_3.

FIG. 38 is a graph showing emission spectra of light-emitting device G0, light-emitting device G100_1, light-emitting device G100_2, the light-emitting device G100_3.

FIG. 39 is a graph showing luminance-current density characteristics of light-emitting device G0, light-emitting device G80_1, light-emitting device G80_2, and light-emitting device G80_3.

FIG. 40 is a graph showing luminance-voltage characteristics of light-emitting device G0, light-emitting device G80_1, light-emitting device G80_2, and light-emitting device G80_3.

FIG. 41 is a graph showing current efficiency-luminance characteristics of light-emitting device G0, light-emitting device G80_1, light-emitting device G80_2, and light-emitting device G80_3.

FIG. 42 is a graph showing current-voltage characteristics of light-emitting device G0, light-emitting device G80_1, light-emitting device G80_2, and light-emitting device G80_3.

FIG. 43 is a graph showing emission spectra of light-emitting device G0, light-emitting device G80_1, light-emitting device G80_2, and light-emitting device G80_3.

FIG. 44 is a graph showing luminance-current density characteristics of light-emitting device G0, light-emitting device G0_1, light-emitting device G0_2, and light-emitting device G0_3.

FIG. 45 is a graph showing luminance-voltage characteristics of light-emitting device G0, light-emitting device G0_1, light-emitting device G0_2, and light-emitting device G0_3.

FIG. 46 is a graph showing current efficiency-luminance characteristics of light-emitting device G0, light-emitting device G0_1, light-emitting device G0_2, and light-emitting device G0_3.

FIG. 47 is a graph showing current-voltage characteristics of light-emitting device G0, light-emitting device G0_1, light-emitting device G0_2, and light-emitting device G0_3.

FIG. 48 is a graph showing emission spectra of light-emitting device G0, light-emitting device G0_1, light-emitting device G0_2, and light-emitting device G0_3.

FIG. 49A is a graph showing time dependence of normalized luminance of light-emitting device G0, light-emitting device G100_1, light-emitting device G100_2, and light-emitting device

G100_3; FIG. 49B is a graph showing time dependence of normalized luminance of light-emitting device G0, light-emitting device G80_1, light-emitting device G80_2, and light-emitting device G80_3; and FIG. 49C is a graph showing time dependence of normalized luminance of light-emitting device G0, light-emitting device G0_1, light-emitting device G0_2, and light-emitting device G0_3.

FIG. 50 is a graph showing luminance-current density characteristics of light-emitting device R0, light-emitting device R100_1, light-emitting device R100_2, and light-emitting device R100_3.

FIG. 51 is a graph showing current efficiency-luminance characteristics of light-emitting device R0, light-emitting device R100_1, light-emitting device R100_2, and light-emitting device R100_3.

FIG. 52 is a graph showing luminance-voltage characteristics of light-emitting device R0, light-emitting device R100_1, light-emitting device R100_2, and light-emitting device R100_3.

FIG. 53 is a graph showing current-voltage characteristics of light-emitting device R0, light-emitting device R100_1, light-emitting device R100_2, and light-emitting device R100_3.

FIG. 54 is a graph showing emission spectra of light-emitting device R0, light-emitting device R100_1, light-emitting device R100_2, and light-emitting device R100_3.

FIG. 55 is a graph showing luminance-current density characteristics of light-emitting device R0, light-emitting device R80_1, light-emitting device R80_2, and light-emitting device R80_3.

FIG. 56 is a graph showing current efficiency-luminance characteristics of light-emitting device R0, light-emitting device R80_1, light-emitting device R80_2, and light-emitting device R80_3.

FIG. 57 is a graph showing luminance-voltage characteristics of light-emitting device R0, light-emitting device R80_1, light-emitting device R80_2, and light-emitting device R80_3.

FIG. 58 is a graph showing current-voltage characteristics of light-emitting device R0, light-emitting device R80_1, light-emitting device R80_2, and light-emitting device R80_3.

FIG. 59 is a graph showing emission spectra of light-emitting device R0, light-emitting device R80_1, light-emitting device R80_2, and light-emitting device R80_3.

FIG. 60 is a graph showing luminance-current density characteristics of light-emitting device R0, light-emitting device R0_1, light-emitting device R0_2, and light-emitting device R0_3.

FIG. 61 is a graph showing current efficiency-luminance characteristics of light-emitting device R0, light-emitting device R0_1, light-emitting device R0_2, and light-emitting device R0_3.

FIG. 62 is a graph showing luminance-voltage characteristics of light-emitting device R0, light-emitting device R0_1, light-emitting device R0_2, and light-emitting device R0_3.

FIG. 63 is a graph showing current-voltage characteristics of light-emitting device R0, light-emitting device R0_1, light-emitting device R0_2, and light-emitting device R0_3.

FIG. 64 is a graph showing emission spectra of light-emitting device R0, light-emitting device R0_1, light-emitting device R0_2, and light-emitting device R0_3.

FIG. 65A is a graph showing time dependence of normalized luminance of light-emitting device R0, light-emitting device R100_1, light-emitting device R100_2, and light-emitting device R100_3; FIG. 65B is a graph showing time dependence of normalized luminance of light-emitting device R0, light-emitting device R80_1, light-emitting device R80_2, and light-emitting device R80_3; and FIG. 65C is a graph showing time dependence of normalized luminance of light-emitting device R0, light-emitting device R0_1, light-emitting device R0_2, and light-emitting device R0_3.

FIG. 66A is a graph showing time dependence of normalized luminance of light-emitting device R0, light-emitting device R100_1, light-emitting device R100_2, and light-emitting device R100_3; FIG. 66B is a graph showing time dependence of normalized luminance of light-emitting device R0, light-emitting device R80_1, light-emitting device R80_2, and light-emitting device R80_3; and FIG. 66C is a graph showing time dependence of normalized luminance of light-emitting device R0, light-emitting device R0_1, light-emitting device R0_2, and light-emitting device R0_3.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

In this specification and the like, a device manufactured using a metal mask or an FMM (a fine metal mask, a high-resolution metal mask) may be referred to as a device having an MM (a metal mask) structure. In this specification and the like, a device formed without using a metal mask or an FMM may be referred to as a device having an MML (metal maskless) structure.

### Embodiment 1

As a method for forming an organic semiconductor film in a predetermined shape, a vacuum evaporation method with a metal mask (mask vapor deposition) is widely used. However, in these days of higher density and higher resolution, mask vapor deposition has come close to the limit of increasing the resolution for various reasons such as the alignment accuracy and the distance between the mask and the substrate. Meanwhile, shape processing of an organic semiconductor film by a photolithography method is expected to achieve an organic semiconductor device with a finer pattern. Moreover, since a photolithography method facilitates processing on a large area as compared to a mask vapor deposition method, the processing of an organic semiconductor film by a photolithography method is being researched.

However, the shape processing of an organic semiconductor film by a photolithography method requires many problems to be overcome. Examples of these problems include an effect of exposure to the air of the organic semiconductor film, an effect of light irradiation during processing, and an effect of developer and water when an exposed photosensitive resin is developed. Moreover, another problematic effect is caused by heat treatment in formation of a protective film over an EL layer to alleviate the above effects on the EL layer, for example.

In a light-emitting device using an organic compound, a light-emitting layer and an electron-injection layer are layers that are particularly likely to be affected by the above-described atmospheric component or the like. The effect on the electron-injection layer is not a big problem because the electron-injection layer can be formed after the photolithography process. Meanwhile, the light-emitting layer necessarily undergoes processing by a photolithography method, so that a countermeasure against the effect on the light-emitting layer is necessary.

Therefore, in order to reduce the damage to the light-emitting layer as much as possible, the photolithography process is, in many cases, performed at a position as far away from the light-emitting layer as possible, that is, a position between the electron-injection layer and an electron-transport layer (or a cathode), as mentioned above.

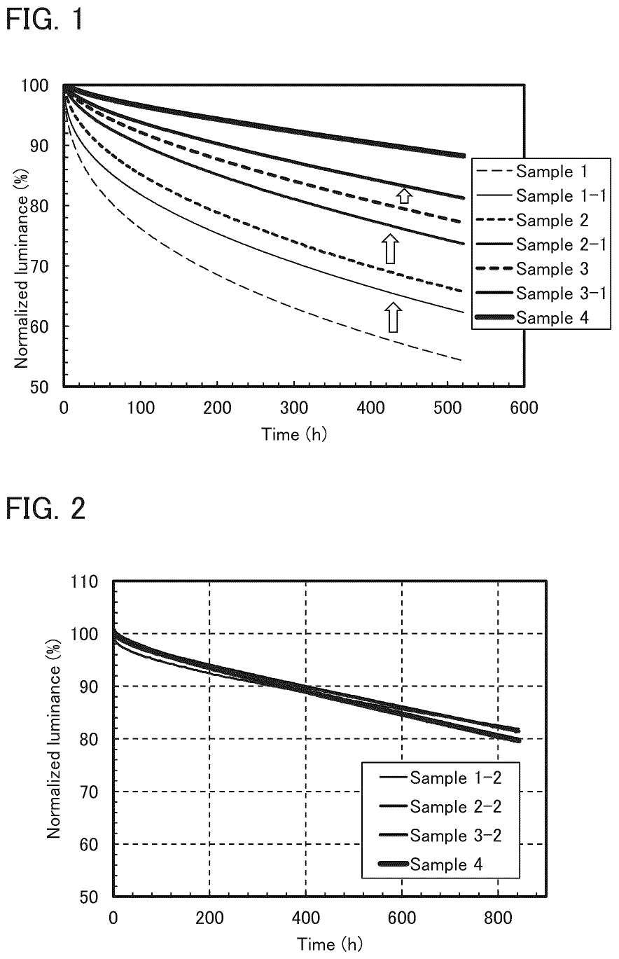

FIG. 1 is a graph showing the relation between the air exposure position and reliability (time dependence of normalized luminance). Samples 1 to 3 are light-emitting devices fabricated through exposure to the air conducted for one hour at different timings. Specifically, for Sample 1, the air exposure was conducted after formation of a light-emitting layer, and then the rest layers were formed; for Sample 2, the air exposure was conducted after formation of a hole-blocking layer (first electron-transport layer), and then the rest layers were formed; and for Sample 3, the air exposure was conducted after formation of an electron-transport layer (second electron-transport layer), and then the rest layers were formed. Sample 4 is a light-emitting device that was not subjected to exposure to the air.

It is found from FIG. 1 that as the position exposed to the air is closer to the light-emitting layer, the effect of exposure to the air is serious.

Note that Sample 1-1, Sample 2-1, and Sample 3-1 are results obtained through vacuum (approx. 1×10⁻⁴ Pa) baking performed at 80° C. for one hour on Sample 1, Sample 2, and Sample 3 in a state where the surfaces to be exposed to the air are exposed. The improvement tendency is observed by the vacuum baking; the improvements have not reached the level in the neighborhood of characteristics of Sample 4 without air exposure.

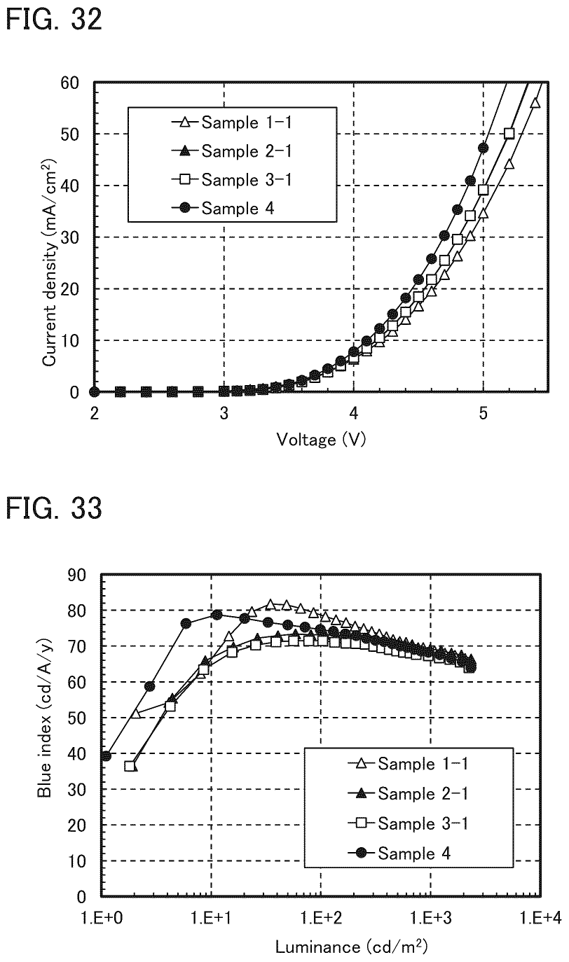

FIG. 32 and FIG. 33 show the current density-luminance characteristics and the blue index-luminance characteristics of Sample 1-1, Sample 2-1, Sample 3-1, and Sample 4. As shown in the graphs, it is found that as the position exposed to the air is closer to the light-emitting layer, initial characteristics are seriously affected by the air exposure, and that even with vacuum baking, the improvement in characteristics do not reach the level in the neighborhood of characteristics of Sample 4 without air exposure.

As described above, in the case where air exposure that is a typical step included in the photolithography process is included, the air exposure is performed at a position as far away from the light-emitting layer as possible, whereby the effect of the air exposure can be reduced; however, it is difficult to eliminate the effect.

Here, the present inventors have found that in a manufacturing process of light-emitting devices, an environment not irradiated with light with a wavelength less than 480 nm is set (Measure 1), vacuum (approx. 1×10⁻⁴ Pa) baking at higher than or equal to 80° C. and lower than 120° C. is performed for longer than or equal to one hour and shorter than or equal to 3 hours in a state where a surface to be exposed to air is exposed (Measure 2), whereby light-emitting devices similar to Sample 2 and Sample 3 as described above can obtain the reliability comparable to that of the light-emitting device not subjected to the air exposure.

Note that the baking time may be set referring to a time taken for moderating a release of water molecules whose molecular weight is 18 at a temperature where quadrupole mass analysis (Q-mass) and measurement are performed on the EL layers subjected to the air exposure in a similar manner under similar pressure conditions. According to this, the preferred vacuum baking time is approximately one hour at 100° C. and that is approximately two hours at 80° C. Note that characteristics of the light-emitting device deteriorate at a temperature higher than or equal to 110° C., and a too long heating time prolongs the manufacturing process, which is not practical; thus, the above temperature range and heating time are preferable.

FIG. 2 is a graph showing the relations between the air exposure position and reliability (time dependence of normalized luminance) of the samples subjected to the above-described measures. Samples 1-2, 2-2, and 3-2 are light-emitting devices fabricated through exposure to the air conducted for one hour at different timings in an environment undergoing Measure 1. Specifically, for Sample 1-2, the air exposure was conducted after formation of a light-emitting layer; for Sample 2-2, the air exposure was conducted after formation of a hole-blocking layer (first electron-transport layer); and for Sample 3-2, the air exposure was conducted after formation of an electron-transport layer (second electron-transport layer). In fabricating of each of these samples, Measure 2 was conducted after the air exposure, and then the rest layers were formed. Sample 4 is a light-emitting device that was not subjected to exposure to the air.

It was found that with Measure 1 and Measure 2 as described above, the reliability of each of the light-emitting devices subjected to the air exposure was comparable to that of the light-emitting device not subjected to the air exposure.

The results suggest that impurities such as atmospheric components diffusing in an EL layer cause some kind of irreversible change in themselves by being irradiated with light with a short wavelength, leading to a cause of degradation, but they do not cause a degradation in a state of no irradiation with light. Thus, a step requiring the air exposure is performed in a state where light with a short wavelength is blocked, whereby the atmospheric components diffusing in the EL layer can be inhibited from being a case of degradation at this time. It was found that the atmospheric components are then removed from the EL layer by performing vacuum baking, so that the effect of the air exposure can be significantly reduced.

However, in the light-emitting devices where the surfaces of the light-emitting layers were exposed to the air, such as Sample 1, Sample 1-1, and Sample 1-2, the initial characteristics were not completely recovered, and reductions in driving voltage and light-emitting efficiency were caused, while their effects on reliability did not appear. This is probably because a slight amount of impurities that are left in the light-emitting layer even after vacuum baking induces a reaction through self emission and causes a degradation. As for the sample subjected to the air exposure on the electron-transport layer, the atmospheric components remaining slightly exist not in the light-emitting layer but in the electron-transport layer and accordingly do not affect the characteristics significantly. Therefore, a layer with a thickness of approximately several nanometers (in this case, the first electron-transport layer (hole-blocking layer)) is provided over the light-emitting layer to perform the air exposure, instead of performing the air exposure on the surface of the light-emitting layer, whereby the effect of the air exposure can be inhibited.

What is important in the above results is the elucidation such that during the manufacture process of a light-emitting device, providing a several-nanometer-thick layer enables the effect of the air exposure to be inhibited as long as an environment not irradiated with a light whose wavelength is less than 480 nm is set, which overthrows a theory such that the reliability is better as the surface exposed to the air is far away from the light-emitting layer.

In other words, for the theory that the reliability is better as the surface exposed to the air is far away from the light-emitting layer, characteristics comparable to those of light-emitting devices not subjected to the air exposure can be obtained when the air exposure is performed at a position very far away from the light-emitting layer. However, the thickness of the EL layer in the light-emitting device is optimized to adjust optical characteristics such as extraction efficiency and color purity, and basically, the resistance of an organic compound is extremely high; thus, it is difficult to make the thickness of the EL layer large intentionally.

Even in recent years where the material development has progressed, only few materials meet requirements of all of favorable carrier-injection and carrier-transport properties, high reliability, and inexpensiveness. Thus, when materials superior to other characteristics such as heat resistance are preferentially used, inconvenience is caused in that an available light-emitting device has only inferior characteristics and in that the cost can be significantly increased even when the light-emitting device is obtained. Moreover, when different material systems are used, device design principles that have been accumulated so far are not adoptable, and other studies and development are necessary, which may increase the cost.

For example, 2,9-di(naphthalen-2-yl)-4,7-diphenyl-1,10-phenanthroline (abbreviation: NBphen) can be given as a material having favorable electron-injection and electron-transport properties and being widely used, that is, being inexpensive. However, NBPhen deposited on the outermost surface of a thin film exhibits low stability of film shape and low heat resistance; thus, NBPhen was not able to be suitably used for a light-emitting device fabricated through processing by a photolithography method. Similarly, a metal complex such as tris(8-quinolinolato)aluminum(III) (abbreviation: Alq), which is widely used in the electron-transport layer, was not able to be used for a light-emitting device fabricated through processing by a photolithography method because of a problem of metal contamination or heat resistance. Furthermore, 8-quinolinolato-lithium (abbreviation: Liq), which is widely used in the electron-injection layer, or the like was not able to be used for a light-emitting device fabricated through processing by a photolithography method because of high solubility in water.

However, with use of one embodiment of the present invention, any of the aforementioned materials can be used after a process including high-temperature heating or a step concerning contamination, such as a photolithography process, is completed, which enables fabrication of a light-emitting apparatus having high resolution, high reliability, and low manufacturing cost. Needless to say, since such a material has high performance, a light-emitting device having more favorable characteristics can be obtained.

Note that in a manufacturing method of a light-emitting device according to one embodiment of the present invention, after a hole-blocking layer (first electron-transport layer) is formed over a light-emitting layer, a step involving air exposure and heating at higher than or equal to 100° C. in a vacuum atmosphere are performed. Accordingly, an organic compound (first compound) included in the hole-blocking layer (first electron-transport layer) preferably has high heat resistance. Specifically, the first compound preferably has a glass transition temperature (Tg) higher than or equal to 100° C., further preferably higher than or equal to 110° C.

As the first compound, an organic compound having an electron-transport property can be used. In particular, an organic compound having a triazine skeleton, a pyridine skeleton, a furodiazine skeleton, and a diazine skeleton, which has high heat resistance, is preferably used, and a quinoxaline skeleton and a pyrimidine skeleton are preferably used in order to provide an element with low driving voltage and low power consumption. Moreover, considering that the photolithography process includes a step of heating the applied resist, use of a compound having high heat resistance can inhibit defects in the shape of a film in the heating step; thus, a dibenzoquinoxaline skeleton having high heat resistance and a high electron-transport property is further preferably used. The electron-transport skeleton preferably has an imidazole skeleton or a pyrrole skeleton as a substituent in terms of hole resistance. Note that examples of the diazine skeleton include a pyrazine skeleton, a pyrimidine skeleton, and a pyridazine skeleton.

Specific examples of electron-transport skeletons suitable for the first compound are as follows: a phenanthroline skeleton having any of a cyano group, halogen, a nitro group, a substituted or unsubstituted alkoxy group having 1 to 6 carbon atoms, a substituted or unsubstituted chain alkyl group having 1 to 6 carbon atoms, a substituted or unsubstituted cycloalkyl group having 3 to 10 carbon atoms, a substituted or unsubstituted aryl group having 6 to 30 carbon atoms, and a substituted or unsubstituted heteroaryl group having 2 to 30 carbon atoms, the number of each of which is 1 to 8; a triazine skeleton having any of a cyano group, halogen, a nitro group, a substituted or unsubstituted alkoxy group having 1 to 6 carbon atoms, a substituted or unsubstituted chain alkyl group having 1 to 6 carbon atoms, a substituted or unsubstituted cycloalkyl group having 3 to 10 carbon atoms, a substituted or unsubstituted aryl group having 6 to 30 carbon atoms, and a substituted or unsubstituted heteroaryl group having 2 to 30 carbon atoms, the number of each of which is 1 to 3; a pyridine skeleton having any of a cyano group, halogen, a nitro group, a substituted or unsubstituted alkoxy group having 1 to 6 carbon atoms, a substituted or unsubstituted chain alkyl group having 1 to 6 carbon atoms, a substituted or unsubstituted cycloalkyl group having 3 to 10 carbon atoms, a substituted or unsubstituted aryl group having 6 to 30 carbon atoms, and a substituted or unsubstituted heteroaryl group having 2 to 30 carbon atoms, the number of each of which is 1 to 5; a diazine skeleton (any of a pyrazine skeleton, a pyrimidine skeleton, or a pyridazine skeleton) having any of a cyano group, halogen, a nitro group, a substituted or unsubstituted alkoxy group having 1 to 6 carbon atoms, a substituted or unsubstituted chain alkyl group having 1 to 6 carbon atoms, a substituted or unsubstituted cycloalkyl group having 3 to 10 carbon atoms, a substituted or unsubstituted aryl group having 6 to 30 carbon atoms and a substituted or unsubstituted heteroaryl group having 2 to 30 carbon atoms, the number of each of which is 1 to 4; and a furodiazine skeleton having any of a cyano group, halogen, a nitro group, a substituted or unsubstituted alkoxy group having 1 to 6 carbon atoms, a substituted or unsubstituted chain alkyl group having 1 to 6 carbon atoms, a substituted or unsubstituted cycloalkyl group having 3 to 10 carbon atoms, a substituted or unsubstituted aryl group having 6 to 30 carbon atoms, and a substituted or unsubstituted heteroaryl group having 2 to 30 carbon atoms, the number of each of which is 1 to 6. Among the above skeletons, a triazine skeleton, a pyrimidine skeleton, and a furodiazine skeleton are particularly preferable in terms of driving voltage and emission efficiency, and in the furodiazine skeleton, benzofuro[3,2-d]pyrimidine is preferable in terms of synthesis costs and driving voltage. The electron-transport skeleton preferably has high hole resistance, in which case degradation due to holes can be inhibited and the lifetime can be increased. Specifically, the electron-transport skeleton preferably has an imidazole skeleton or a pyrrole skeleton as a substituent; specifically, a benzimidazole skeleton, a pyrrole skeleton, an indole skeleton, or a carbazole skeleton is preferable. Meanwhile, when the HOMO level of the compound at the first position is increased, holes are extracted from the light-emitting layer to the first compound, which leads to a decrease in emission efficiency; thus, the HOMO level is preferably deeper than −5.6 eV. Thus, a carbazole skeleton is particularly preferable among the pyrrole skeleton, the indole skeleton, and the carbazole skeleton; specifically, a carbazolyl skeleton having any of a substituted or unsubstituted chain alkyl group having 1 to 6 carbon atoms, a substituted or unsubstituted cycloalkyl group having 3 to 10 carbon atoms, a substituted or unsubstituted aryl group having 6 to 30 carbon atoms, and a substituted or unsubstituted heteroaryl group having 2 to 30 carbon atoms, the number of each of which is 1 to 8. In particular, a carbazolyl skeleton is preferably any of a 3,3′-bicarbazole skeleton, a 2,2′-bicarbazole skeleton, and a 2,3′-bicarbazole skeleton which have bonding at a 2- or 3-position, in which case a light-emitting device with a favorable carrier balance can be provided and high heat resistance can be obtained.

Specifically, it is preferable to use a dibenzoquinoxaline compound such as 2-{3-[3-(N-phenyl-9H-carbazol-3-yl)-9H-carbazol-9-yl]phenyl}dibenzo[f,h]quinoxaline (abbreviation: 2mPCCzPDBq), 2-{3-[2-(N-phenyl-9H-carbazol-3-yl)-9H-carbazol-9-yl]phenyl}dibenzo[f,h]quinoxaline (abbreviation: 2mPCCzPDBq-02), 2-{3-[3-(N-phenyl-9H-carbazole-2-yl)-9H-carbazole-9-yl]phenyl}dibenzo[f,h]quinoxaline (abbreviation: 2mPCCzPDBq-03), or 2-(3-{3-[N-(3,5-di-tert-butylphenyl)-9H-carbazol-3-yl]-9H-carbazol-9-yl}phenyl)dibenzo[f,h]quinoxaline; a pyrimidine compound such as 4-[3,5-bis(9H-carbazol-9-yl)phenyl]-2-phenyl-6-(1,1′-biphenyl-4-yl)pyrimidine (abbreviation: 6BP-4Cz2PPm), 6-(1,1′-biphenyl-3-yl)-4-[3,5-bis(9H-carbazol-9-yl)phenyl]-2-phenylpyrimidine (abbreviation: 6mBP-4Cz2PPm), 9-[3-(4,6-diphenyl-pyrimidin-2-yl)phenyl]-9′-phenyl-3,3′-bi-9H-carbazole (abbreviation: 2PCCzPPm), or 9-(4,6-diphenyl-pyrimidin-2-yl)-9′-phenyl-3,3′-bi-9H-carbazole (abbreviation: 2PCCzPm); a triazine compound such as 9-[3-(4,6-diphenyl-1,3,5-triazin-2-yl)phenyl]-9′-phenyl-3,3′-bi-9H-carbazole (abbreviation: mPCCzPTzn), 9-[3-(4,6-diphenyl-1,3,5-triazin-2-yl)phenyl]-9′-phenyl-2,3′-bi-9H-carbazole (abbreviation: mPCCzPTzn-02), 9-[4-(4,6-diphenyl-1,3,5-triazin-2-yl)phenyl]-9′-phenyl-3,3′-bi-9H-carbazole (abbreviation: PCCzPTzn), or 9-(4,6-diphenyl-1,3,5-triazin-2-yl)-9′-phenyl-3,3′-bi-9H-carbazole (abbreviation: PCCzTzn (CzT)); a furodiazine compound such as 4-[2-(N-phenyl-9H-carbazol-3-yl)-9H-carbazol-9-yl]benzofuro[3,2-d]pyrimidine (abbreviation: 4PCCzBfpm-02); a benzoquinoxaline compound such as 4-{3-[3-(N-phenyl-9H-carbazol-3-yl)-9H-carbazol-9-yl]phenyl}benzo[h]quinazoline; or a pyridine compound such as 9-[3-(2,6-diphenyl-pyridin-4-yl)phenyl]-9′-phenyl-3,3′-bi-9H-carbazole.

Note that in order to achieve high emission efficiency or a long driving lifetime, the HOMO level of the first compound is preferably deeper than-5.6 eV because it is important to inhibit holes to be extracted from the light-emitting layer to a layer containing the first compound adjacent to the light-emitting layer. To achieve high emission efficiency, the HOMO level is further preferably deeper than-5.8 eV.

The thickness of the first electron-transport layer (hole-blocking layer) is preferably greater than or equal to 2 nm and less than or equal to 20 nm, further preferably greater than or equal to 5 nm and less than or equal to 15 nm.

Note that the air exposure step (photolithography process) is performed on the surface of the first electron-transport layer; accordingly, a first layer, i.e., the first electron-transport layer and layers in an EL layer positioned closer to an anode than the first electron-transport layer is, is processed so that a space is provided between EL layers of adjacent light-emitting devices. Since the first electron-transport layer and layers (first layer) in the EL layer positioned closer to the anode than the first electron-transport layer is are processed with a photolithography process, the distance between adjacent layers or the distance between adjacent first electrodes can be greater than or equal to 2 μm and less than or equal to 5 μm, which is extremely small, leading to high-resolution display apparatuses.

In the case where the EL layer is processed by a photolithography method, the organic semiconductor devices can be arranged at an extremely high density (the distance between the first electrodes can be approximately 2 μm to 5 μm). In the case where the organic semiconductor devices are display devices (light-emitting devices), an extremely high-resolution display apparatus with 500 ppi or more and an aperture ratio of 30% or more can be provided. Furthermore, an extremely high-resolution display apparatus with 100 ppi or more and an aperture ratio of 40% or more can be provided. Moreover, an extremely high-resolution display apparatus with 3000 ppi or more and an aperture ratio of 30% or more, or even 50% or more can be provided.

A second layer (second electron-transport layer (electron-injection layer)) is formed after the air exposure step and the vacuum baking step are completed, and thus is formed as a continuous layer shared by a plurality of light-emitting devices formed in the light-emitting apparatus. The second layer does not undergo air exposure that is a typical step included in the photolithography process, a heating step at high temperatures, or the like. Thus, without strict limitations due to the preference for the convenience in processing by a photolithography method, such as heat resistance or air exposure resistance to the air, it is possible to select a material that has favorable performance, characteristics, or both of them, such as a carrier-transport property, a carrier-injection property, a cost, and stable characteristics.

The second electron-transport layer included in the second layer contains a second compound. As the second compound, a compound having an electron-transport property is preferably used, and a compound having a high electron-injection property is preferable. In particular, an organic compound having any one of a phenanthroline skeleton, a triazine skeleton, a pyridine skeleton, and a diazine skeleton is preferably used because of having a favorable electron-transport property. Alternatively, the preferred second compound is a metal complex, particularly an organometallic complex having a quinolinol ligand, and a lithium complex is more particularly preferable because of having a favorable electron-injection property.

Note that in the case where the second compound is a metal complex, the second compound is preferably mixed with a third compound having an electron-transport property. The third compound is preferably an organic compound having any one of an anthracene skeleton, a triazine skeleton, a phenanthroline skeleton, a pyridine skeleton, a diazine skeleton, and a furodiazine skeleton. The electron-transport skeleton preferably has an imidazole skeleton or a pyrrole skeleton as a substituent.

Specific examples of electron-transport skeletons suitable for the second compound are follows: a phenanthroline skeleton having any of a cyano group, halogen, a nitro group, a substituted or unsubstituted alkoxy group having 1 to 6 carbon atoms, a substituted or unsubstituted chain alkyl group having 1 to 6 carbon atoms, a substituted or unsubstituted cycloalkyl group having 3 to 10 carbon atoms, a substituted or unsubstituted aryl group having 6 to 30 carbon atoms, and a substituted or unsubstituted heteroaryl group having 2 to 30 carbon atoms, the number of each of which is 1 to 8; a triazine skeleton having any of a cyano group, halogen, a nitro group, a substituted or unsubstituted alkoxy group having 1 to 6 carbon atoms, a substituted or unsubstituted chain alkyl group having 1 to 6 carbon atoms, a substituted or unsubstituted cycloalkyl group having 3 to 10 carbon atoms, a substituted or unsubstituted aryl group having 6 to 30 carbon atoms, and a substituted or unsubstituted heteroaryl group having 2 to 30 carbon atoms, the number of each of which is 1 to 3; a pyridine skeleton having any of a cyano group, halogen, a nitro group, a substituted or unsubstituted alkoxy group having 1 to 6 carbon atoms, a substituted or unsubstituted chain alkyl group having 1 to 6 carbon atoms, a substituted or unsubstituted cycloalkyl group having 3 to 10 carbon atoms, a substituted or unsubstituted aryl group having 6 to 30 carbon atoms, and a substituted or unsubstituted heteroaryl group having 2 to 30 carbon atoms, the number of each of which is 1 to 5; a diazine skeleton (any of a pyrazine skeleton, a pyrimidine skeleton, or a pyridazine skeleton) having any of a cyano group, halogen, a nitro group, a substituted or unsubstituted alkoxy group having 1 to 6 carbon atoms, a substituted or unsubstituted chain alkyl group having 1 to 6 carbon atoms, a substituted or unsubstituted cycloalkyl group having 3 to 10 carbon atoms, a substituted or unsubstituted aryl group having 6 to 30 carbon atoms and a substituted or unsubstituted heteroaryl group having 2 to 30 carbon atoms, the number of each of which is 1 to 4; and a furodiazine skeleton having any of a cyano group, halogen, a nitro group, a substituted or unsubstituted alkoxy group having 1 to 6 carbon atoms, a substituted or unsubstituted chain alkyl group having 1 to 6 carbon atoms, a substituted or unsubstituted cycloalkyl group having 3 to 10 carbon atoms, a substituted or unsubstituted aryl group having 6 to 30 carbon atoms, and a substituted or unsubstituted heteroaryl group having 2 to 30 carbon atoms, the number of each of which is 1 to 6. Among the above skeletons, a triazine skeleton, a pyrimidine skeleton, and a furodiazine skeleton are particularly preferable in terms of driving voltage and emission efficiency, and in the furodiazine skeleton, a benzofuro[3,2-d]pyrimidine skeleton is preferable in terms of synthesis costs and driving voltage. The electron-transport skeleton preferably has high hole resistance, in which case degradation due to holes can be inhibited and the lifetime can be increased. Specifically, the electron-transport skeleton preferably has an imidazole skeleton or a pyrrole skeleton as a substituent; specifically, a benzimidazole skeleton, a pyrrole skeleton, an indole skeleton, or a carbazole skeleton is preferable. Meanwhile, when the HOMO level of the compound at the first position is increased, holes are extracted from the light-emitting layer to the first compound, which leads to a decrease in emission efficiency; thus, the HOMO level is preferably deeper than-5.6 eV. Thus, a carbazole skeleton is particularly preferable among the pyrrole skeleton, the indole skeleton, and the carbazole skeleton; specifically, a carbazolyl skeleton having any of a substituted or unsubstituted chain alkyl group having 1 to 6 carbon atoms, a substituted or unsubstituted cycloalkyl group having 3 to 10 carbon atoms, a substituted or unsubstituted aryl group having 6 to 30 carbon atoms, and a substituted or unsubstituted heteroaryl group having 2 to 30 carbon atoms, the number of each of which is 1 to 8. In particular, a carbazolyl skeleton is preferably a 3,3′-bicarbazole skeleton, a 2,2′-bicarbazole skeleton, and a 2,3′-bicarbazole skeleton which have bonding at a 2- or 3-position, in which case a light-emitting device with a favorable carrier balance can be provided and high heat resistance can be obtained.

In the case where the second compound is a metal complex, it is specifically an 8-quinolinol skeleton having any of a cyano group, halogen, a nitro group, a substituted or unsubstituted alkoxy group having 1 to 6 carbon atoms, a substituted or unsubstituted aryl group having 6 to 30 carbon atoms, and a substituted or unsubstituted heteroaryl group having 2 to 30 carbon atoms, the number of each of which is 1 to 6 and a quinolinol complex having a metal. Examples of the metal include aluminum, lithium, zinc, copper, gallium, potassium, sodium, beryllium, magnesium, calcium, silver, gold, germanium, and tin. In order to have a high electron-injection property, any of lithium, aluminum, or zinc is preferable, and lithium is particularly preferable.

For the second compound, specifically, it is preferable to use a dibenzoquinoxaline compound such as 2-{3-[3-(N-phenyl-9H-carbazol-3-yl)-9H-carbazol-9-yl]phenyl}dibenzo[f,h]quinoxaline (abbreviation: 2mPCCzPDBq), 2-{3-[2-(N-phenyl-9H-carbazol-3-yl)-9H-carbazol-9-yl]phenyl}dibenzo[f,h]quinoxaline (abbreviation: 2mPCCzPDBq-02), 2-{3-[3-(N-phenyl-9H-carbazole-2-yl)-9H-carbazole-9-yl]phenyl}dibenzo[f,h]quinoxaline (abbreviation: 2mPCCzPDBq-03), or 2-(3-{3-[N-(3,5-di-tert-butylphenyl)-9H-carbazole-3-yl]-9H-carbazole-9-yl}phenyl)dibenzo[f,h]quinoxaline (abbreviation: 2mPCCzPDBq-03); a pyrimidine compound such as 4-[3,5-bis(9H-carbazol-9-yl)phenyl]-2-phenyl-6-(1,1′-biphenyl-4-yl)pyrimidine (abbreviation: 6BP-4Cz2PPm), 6-(1,1′-biphenyl-3-yl)-4-[3,5-bis(9H-carbazol-9-yl)phenyl]-2-phenylpyrimidine (abbreviation: 6mBP-4Cz2PPm), 9-[3-(4,6-diphenyl-pyrimidin-2-yl)phenyl]-9′-phenyl-3,3′-bi-9H-carbazole (abbreviation: 2PCCzPPm), or 9-(4,6-diphenyl-pyrimidin-2-yl)-9′-phenyl-3,3′-bi-9H-carbazole (abbreviation: 2PCCzPm); a triazine compound such as 9-[3-(4,6-diphenyl-1,3,5-triazin-2-yl)phenyl]-9′-phenyl-3,3′-bi-9H-carbazole (abbreviation: mPCCzPTzn), 9-[3-(4,6-diphenyl-1,3,5-triazin-2-yl)phenyl]-9′-phenyl-2,3′-bi-9H-carbazole (abbreviation: mPCCzPTzn-02), 9-[4-(4,6-diphenyl-1,3,5-triazin-2-yl)phenyl]-9′-phenyl-3,3′-bi-9H-carbazole (abbreviation: PCCzPTzn), or 9-(4,6-diphenyl-1,3,5-triazin-2-yl)-9′-phenyl-3,3′-bi-9H-carbazole (abbreviation: PCCzTzn (CzT)); a furodiazine compound such as 4-[2-(N-phenyl-9H-carbazol-3-yl)-9H-carbazol-9-yl]benzofuro[3,2-d]pyrimidine (abbreviation: 4PCCzBfpm-02) or 2,6-bis(4-naphthalen-1-ylphenyl)-4-[4-(3-pyridyl)phenyl]pyrimidine (abbreviation: 2,4NP-6PyPPm); a benzoquinoxaline compound such as 4-{3-[3-(N-phenyl-9H-carbazol-3-yl)-9H-carbazol-9-yl]phenyl}benzo[h]quinazoline; a pyridine compound such as 9-[3-(2,6-diphenyl-pyridin-4-yl)phenyl]-9′-phenyl-3,3′-bi-9H-carbazole; 2-{4-[9,10-di(naphthalen-2-yl)-2-anthryl]phenyl}-1-phenyl-1H-benzimidazole (abbreviation: ZADN); 2-[3-(2,6-dimethyl-3-pyridinyl)-5-(9-phenanthrenyl)phenyl]-4,6-diphenyl-1,3,5-triazine (abbreviation: mPn-mDMePyPTzn); 2,2′-(1,3-phenylene)bis(9-phenyl-1,10-phenanthroline) (abbreviation: mPPhen2P); 2,9-di(naphthalen-2-yl)-4,7-diphenyl-1,10-phenanthroline (abbreviation: NBPhen); bathophenanthroline (abbreviation: BPhen); bathocuproine (abbreviation: BCP); 1-[4-(10-[1,1′-biphenyl]-4-yl-9-anthracenyl)phenyl]-2-ethyl-1H-benzimidazole (abbreviation: EtBImPBPhA); 2-[(1,1′-biphenyl)-4-yl]-4-phenyl-6-[9,9′-spirobi (9H-fluoren)-2-yl]-1,3,5-triazine (abbreviation: BP-SFTzn); or the like. In particular, a compound having a phenanthroline skeleton, such as mPPhen2P, NBPhen, BPhen, or BCP, is preferably used, in which case an effect of reducing the driving voltage can be expected.

In the case where the second compound is a metal complex, a preferable metal complex is a zinc- or aluminum-based metal complex, such as 8-quinolinolato-lithium (abbreviation: Liq), tris(8-quinolinolato)aluminum (III) (abbreviation: Alq), tris(4-methyl-8-quinolinolato)aluminum (III) (abbreviation: Almq₃), bis(10-(abbreviation: BeBq₂), bis(2-methyl-8-hydroxybenzo[h]quinolinato) beryllium (II) quinolinolato) (4-phenylphenolato)aluminum (III) (abbreviation: BAlq), and bis(8-quinolinolato) zinc (II) (abbreviation: Znq). Liq and Alq are inexpensive and available and have favorable characteristics, which are preferable. Furthermore, Liq is preferably used as the second compound because it has a high electron-injection property. When the organometallic complex having a quinolinol ligand such as Liq is in contact with liquid including water, the organometallic complex is dissociated into a metal ion and a ligand and decomposed; thus, such an organometallic complex is significantly damaged by processing in a photolithography process. Accordingly, when being deposited by evaporation after a photolithography process, such an organometallic complex can be used in processing of an organic device.

Specific examples of electron-transport skeletons suitable for the third compounds are follows: an anthracene skeleton having any of a cyano group, halogen, a nitro group, a substituted or unsubstituted alkoxy group having 1 to 6 carbon atoms, a substituted or unsubstituted chain alkyl group having 1 to 6 carbon atoms, a substituted or unsubstituted cycloalkyl group having 3 to 10 carbon atoms, a substituted or unsubstituted aryl group having 6 to 30 carbon atoms, and a substituted or unsubstituted heteroaryl group having 2 to 30 carbon atoms, the number of each of which is 1 to 10; a phenanthroline skeleton having any of a cyano group, halogen, a nitro group, a substituted or unsubstituted alkoxy group having 1 to 6 carbon atoms, a substituted or unsubstituted chain alkyl group having 1 to 6 carbon atoms, a substituted or unsubstituted cycloalkyl group having 3 to 10 carbon atoms, a substituted or unsubstituted aryl group having 6 to 30 carbon atoms, and a substituted or unsubstituted heteroaryl group having 2 to 30 carbon atoms, the number of each of which is 1 to 8; a triazine skeleton having any of a cyano group, halogen, a nitro group, a substituted or unsubstituted alkoxy group having 1 to 6 carbon atoms, a substituted or unsubstituted chain alkyl group having 1 to 6 carbon atoms, a substituted or unsubstituted cycloalkyl group having 3 to 10 carbon atoms, a substituted or unsubstituted aryl group having 6 to 30 carbon atoms, and a substituted or unsubstituted heteroaryl group having 2 to 30 carbon atoms, the number of each of which is 1 to 3; a pyridine skeleton having any of a cyano group, halogen, a nitro group, a substituted or unsubstituted alkoxy group having 1 to 6 carbon atoms, a substituted or unsubstituted chain alkyl group having 1 to 6 carbon atoms, a substituted or unsubstituted cycloalkyl group having 3 to 10 carbon atoms, a substituted or unsubstituted aryl group having 6 to 30 carbon atoms, and a substituted or unsubstituted heteroaryl group having 2 to 30 carbon atoms, the number of each of which is 1 to 5; a diazine skeleton (any of a pyrazine skeleton, a pyrimidine skeleton, or a pyridazine skeleton) having any of a cyano group, halogen, a nitro group, a substituted or unsubstituted alkoxy group having 1 to 6 carbon atoms, a substituted or unsubstituted chain alkyl group having 1 to 6 carbon atoms, a substituted or unsubstituted cycloalkyl group having 3 to 10 carbon atoms, a substituted or unsubstituted aryl group having 6 to 30 carbon atoms and a substituted or unsubstituted heteroaryl group having 2 to 30 carbon atoms, the number of each of which is 1 to 4; and a furodiazine skeleton having any of a cyano group, halogen, a nitro group, a substituted or unsubstituted alkoxy group having 1 to 6 carbon atoms, a substituted or unsubstituted chain alkyl group having 1 to 6 carbon atoms, a substituted or unsubstituted cycloalkyl group having 3 to 10 carbon atoms, a substituted or unsubstituted aryl group having 6 to 30 carbon atoms, and a substituted or unsubstituted heteroaryl group having 2 to 30 carbon atoms, the number of each of which is 1 to 6. Among the above skeletons, a triazine skeleton, a pyrimidine skeleton, and a furodiazine skeleton are particularly preferable in terms of driving voltage and emission efficiency, and in the furodiazine skeleton, a benzofuro[3,2-d]pyrimidine skeleton is preferable in terms of synthesis costs and driving voltage. The electron-transport skeleton preferably has high hole resistance, in which case degradation due to holes can be inhibited and the lifetime can be increased. Specifically, the electron-transport skeleton preferably has an imidazole skeleton or a pyrrole skeleton as a substituent; specifically, a benzimidazole skeleton, a pyrrole skeleton, an indole skeleton, or a carbazole skeleton is preferable. Meanwhile, when the HOMO level of the compound at the first position is increased, holes are extracted from the light-emitting layer to the first compound, which leads to a decrease in emission efficiency; thus, the HOMO level is preferably deeper than-5.6 eV. Thus, a carbazole skeleton is particularly preferable among the pyrrole skeleton, the indole skeleton, and the carbazole skeleton; specifically, a carbazolyl skeleton having any of a substituted or unsubstituted chain alkyl group having 1 to 6 carbon atoms, a substituted or unsubstituted cycloalkyl group having 3 to 10 carbon atoms, a substituted or unsubstituted aryl group having 6 to 30 carbon atoms, and a substituted or unsubstituted heteroaryl group having 2 to 30 carbon atoms, the number of each of which is 1 to 8. In particular, a carbazolyl skeleton is preferably a 3,3′-bicarbazole skeleton, a 2,2′-bicarbazole skeleton, and a 2,3′-bicarbazole skeleton which have bonding at a 2- or 3-position, in which case a light-emitting device with a favorable carrier balance can be provided and high heat resistance can be obtained.

For the third compound, specifically it is preferable to use 9-(1-naphthyl)-10-[4-(2-naphthyl)phenyl]anthracene (abbreviation: αN-BNPAnth), 2-{4-[9,10-di(naphthalen-2-yl)-2-anthryl]phenyl}-1-phenyl-1H-benzimidazole (abbreviation: ZADN), 2-[3-(2,6-dimethyl-3-pyridinyl)-5-(9-phenanthrenyl)phenyl]-4,6-diphenyl-1,3,5-triazine (abbreviation: mPn-mDMePyPTzn), 2,2′-(1,3-phenylene)bis(9-phenyl-1,10-phenanthroline) (abbreviation: mPPhen2P), 2,9-di(naphthalen-2-yl)-4,7-diphenyl-1,10-phenanthroline (abbreviation: NBPhen), bathophenanthroline (abbreviation: BPhen), bathocuproine (abbreviation: BCP), 1-[4-(10-[1,1′-biphenyl]-4-yl-9-anthracenyl)phenyl]-2-ethyl-1H-benzimidazole (abbreviation: EtBImPBPhA), 2-[(1,1′-biphenyl)-4-yl]-4-phenyl-6-[9,9′-spirobi (9H-fluoren)-2-yl]-1,3,5-triazine (abbreviation: BP-SFTzn), 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 9-[4-(4,6-diphenyl-1,3,5-triazin-2-yl)phenyl]-9′-phenyl-3,3′-bi-9H-carbazole (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), 9,9′-[pyrimidine-4,6-diylbis(biphenyl-3,3′-diyl)]bis(9H-carbazole) (abbreviation: 4,6mCzBP2Pm), 2-[3′-(9,9-dimethyl-9H-fluoren-2-yl)-1,1′-biphenyl-3-yl]-4,6-diphenyl-1,3,5-triazine (abbreviation: mFBPTzn), 8-(1,1′-biphenyl-4-yl)-4-[3-(dibenzothiophen-4-yl)phenyl]-[1]benzofuro[3,2-d]pyrimidine (abbreviation: 8BP-4mDBtPBfpm), 9-[3′-(dibenzothiophen-4-yl) biphenyl-3-yl]naphtho[1′,2′:4,5]furo[2,3-b]pyrazine 9-[3′-(dibenzothiophen-4-yl) biphenyl-4-(abbreviation: 9mDBtBPNfpr), yl]naphtho[1′,2′:4,5]furo[2,3-b]pyrazine (abbreviation: 9pmDBtBPNfpr), 11-[3′-(dibenzothiophen-4-yl) biphenyl-3-yl]phenanthro[9′,10′:4,5]furo[2,3-b]pyrazine (abbreviation: 11mDBtBPPnfpr), 11-[3′-dibenzothiophen-4-yl) biphenyl-4-yl]phenanthro[9′,10′:4,5]furo[2,3-b]pyrazine, 11-[(3′-(9H-carbazol-9-yl)-3-yl]phenanthro[9′,10′:4,5]furo[2,3-b]pyrazine, 12-(9′-phenyl-3,3′-bi-9H-carbazol-9-yl)phenanthro[9′,10′:4,5]furo[2,3-b]pyrazine (abbreviation: 12PCCzPnfpr), 9-[(3′-9-phenyl-9H-carbazol-3-yl) biphenyl-4-yl]naphtho[1′,2′:4,5]furo[2,3-b]pyrazine (abbreviation: 9pmPCBPNfpr), 9-(9′-phenyl-3,3′-bi-9H-carbazol-9-yl)naphtho[1′,2′:4,5]furo[2,3-b]pyrazine (abbreviation: 9PCCzNfpr), 10-(9′-phenyl-3,3′-bi-9H-carbazol-9-yl)naphtho[1′,2′:4,5]furo[2,3-b]pyrazine (abbreviation: 10PCCzNfpr), 9-[3′-(6-phenylbenzo[b]naphtho[1,2-d]furan-8-yl) biphenyl-3-yl]naphtho[1′,2′:4,5]furo[2,3-b]pyrazine (abbreviation: 9mBnfBPNfpr), 9-{3-[6-(9,9-dimethylfluoren-2-yl)dibenzothiophen-4-yl]phenyl}naphtho[1′,2′:4,5]furo[2,3-b]pyrazine (abbreviation: 9mFDBtPNfpr), 9-[3′-(6-phenyldibenzothiophen-4-yl) biphenyl-3-yl]naphtho[1′,2′:4,5]furo[2,3-b]pyrazine (abbreviation: 9mDBtBPNfpr-02), 9-[3-(9′-phenyl-3,3′-bi-9H-carbazol-9-yl)phenyl]naphtho[1′,2′:4,5]furo[2,3-b]pyrazine (abbreviation: 9mPCCzPNfpr), 9-[3′-(2,8-diphenyldibenzothiophen-4-yl) biphenyl-3-yl]naphtho[1′,2′:4,5]furo[2,3-b]pyrazine, 11-[3′-(2,8-diphenyldibenzothiophen-4-yl) biphenyl-3-yl]phenanthro[9′,10′:4,5]furo[2,3-b]pyrazine, 5-[3-(4,6-diphenyl-1,3,5-triazin-2-yl)phenyl]-7,7-dimethyl-5H,7H-indeno[2,1-b]carbazole (abbreviation: mINc(II)PTzn), 2-[3′-(triphenylen-2-yl)-1,1′-biphenyl-3-yl]-4,6-diphenyl-1,3,5-triazine (abbreviation: mTpBPTzn), 2,6-bis(4-naphthalen-1-ylphenyl)-4-[4-(3-pyridyl)phenyl]pyrimidine (abbreviation: 2,4NP-6PyPPm), 3-[9-(4,6-diphenyl-1,3,5-triazin-2-yl)-2-dibenzofuranyl]-9-phenyl-9H-carbazole (abbreviation: PCDBfTzn), 2-[1,1′-biphenyl]-3-yl-4-phenyl-6-(8-[1,1′:4′,1″-terphenyl]-4-yl-1-dibenzofuranyl)-1,3,5-triazine (abbreviation: mBP-TPDBfTzn), 6-(1,1′-biphenyl-3-yl)-4-[3,5-bis(9H-carbazol-9-yl)phenyl]-2-phenylpyrimidine (abbreviation: 6mBP-4Cz2PPm), or 4-[3,5-bis(9H-carbazol-9-yl)phenyl]-2-phenyl-6-(1,1′-biphenyl-4-yl)pyrimidine (abbreviation: 6BP-4Cz2PPm).

Here, in a display apparatus in which a plurality of light-emitting devices each including a pixel electrode and a common electrode are arranged on a plane, the first electrode is the pixel electrode independently included in each of the plurality of organic semiconductor devices, and the second electrode is the common electrode which is provided as a continuous layer and shared by the plurality of organic semiconductor devices.

Note that in the case where the first layers of adjacent light-emitting devices do not overlap with each other, that is, a space is provided between the organic compound layers of adjacent light-emitting devices or between layers (the first electron-transport layer and layers provided therebelow) of adjacent light-emitting devices, this structure is particularly preferable because crosstalk between the adjacent semiconductor devices can be inhibited. This is particularly effective when a distance between adjacent light-emitting devices is an extremely small distance greater than or equal to 2 μm and less than or equal to 5 μm.

### Embodiment 2

In this embodiment, a light-emitting device of one embodiment of the present invention will be described in detail.

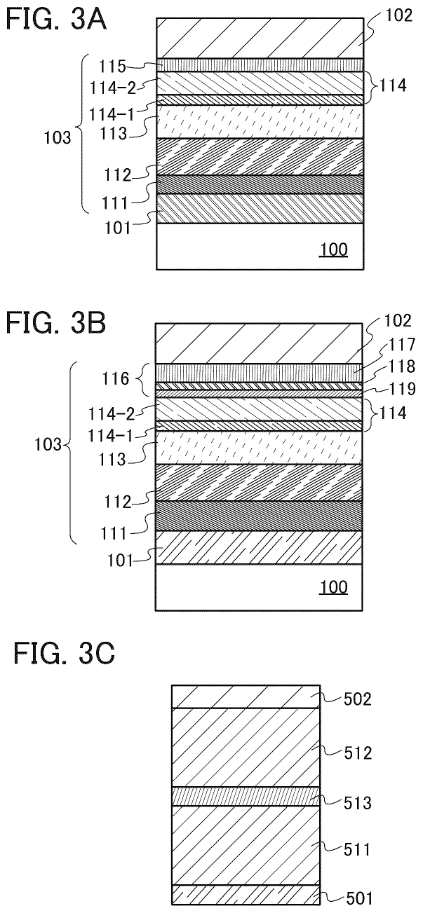

FIG. 3 shows schematic diagrams of a light-emitting device of one embodiment of the present invention. The light-emitting device includes a first electrode 101 over an insulator 100, and an EL layer 103 between the first electrode 101 and a second electrode 102. The EL layer includes at least a light-emitting layer 113 and an electron-transport layer 114 (a first electron-transport layer (hole-blocking layer) 114-1 and a second electron-transport layer 114-2). The first electrode is independent from that of another light-emitting device, and the second electrode is formed as a layer shared by a plurality of light-emitting devices.

The EL layer 103 includes a first layer (the light-emitting layer and the first electron-transport layer (hole-blocking layer) 114-1) that is an independent layer in each light-emitting device and a second layer (the second electron-transport layer 114-2) formed as a layer shared by the plurality of light-emitting devices.

Furthermore, the EL layer 103 preferably includes functional layers such as a hole-injection layer 111, a hole-transport layer 112, and an electron-injection layer 115, as shown in FIG. 3A. The EL layer 103 may include functional layers other than the above functional layers, such as a hole-blocking layer, an electron-blocking layer, an exciton-blocking layer, and a charge-generation layer. Alternatively, any of the above-described layers may be omitted.

Note that a layer positioned closer to the first electrode than the first electron-transport layer 114-1 is is included in the first layer. A layer positioned closer to the second electrode 102 than the second electron-transport layer 114-2 is included in the second layer.

Note that as described above, for the light-emitting device according to one embodiment of the present invention, after the first electron-transport layer (hole-blocking layer) 114-1 is formed over the light-emitting layer, a step involving air exposure is performed and then heating at higher than or equal to 100° C. is performed in a vacuum atmosphere; thus, the organic compound (first compound) contained in the first electron-transport layer (hole-blocking layer) 114-1 preferably has high heat resistance. Specifically, the first compound preferably has a Tg higher than or equal to 100° C. and further preferably has a Tg higher than or equal to 110° C.

As the first compound, an organic compound having an electron-transport property can be used. In particular, an organic compound having a triazine skeleton, a pyridine skeleton, a furodiazine skeleton, and a diazine skeleton, which has high heat resistance, is preferable, and a quinoxaline skeleton and a pyrimidine skeleton are preferable in order to provide an element with low driving voltage and low power consumption. Moreover, when a compound having high heat resistance is used in the photolithography process, defects in the shape of a film caused by the heating step can be reduced, so that a dibenzoquinoxaline skeleton having high heat resistance and a high electron-transport property is further preferable. An electron-transport skeleton of the first compound preferably has an imidazole skeleton or a pyrrole skeleton as a substituent in terms of hole resistance.

Specific skeletons included in the first compound, specific examples of the first compound, and preferable structures are described in Embodiment 1 and thus repeated description thereof is omitted. Refer to the description in Embodiment 1.

The thickness of the hole-blocking layer (first electron-transport layer) is preferably greater than or equal to 2 nm and less than or equal to 20 nm, further preferably greater than or equal to 5 nm and less than or equal to 15 nm.

The second layer (second electron-transport layer 114-2 in FIG. 3A) is formed after the air exposure step and the vacuum baking step are completed, and thus is formed as a continuous layer shared by a plurality of light-emitting devices formed in the light-emitting apparatus. The second electron-transport layer does not undergo air exposure that is a typical step included in the photolithography process, a heating step at high temperatures, or the like. Thus, without strict limitations due to the preference for the convenience in processing by a photolithography method, such as heat resistance or air exposure resistance to the air, it is possible to select a material that has favorable performance, characteristics, or both of them, such as a carrier-transport property, a carrier-injection property, a cost, and stable characteristics.

The second electron-transport layer is a layer containing the second compound. As the second compound, a compound having an electron-transport property is preferably used, and a compound having a high electron-injection property is preferable. In particular, an organic compound having any one of a phenanthroline skeleton, a triazine skeleton, a pyridine skeleton, and a diazine skeleton has a favorable electron-transport property and thus is preferable. Alternatively, the preferred second compound is a metal complex, particularly an organometallic complex having a quinolinol ligand, and a lithium complex is more particularly preferable because of having a favorable electron-injection property.

Specific skeletons included in the second compound, specific examples of the second compound, and preferable structures are described in Embodiment 1 and thus repeated description thereof is omitted. Refer to the description in Embodiment 1.

Note that in the case where the second compound is a metal complex, the second compound is preferably mixed with the third compound having an electron-transport property. The third compound is preferably an organic compound having any one of an anthracene skeleton, a triazine skeleton, a phenanthroline skeleton, a pyridine skeleton, a diazine skeleton, and a furodiazine skeleton. An electron-transport skeleton of the third compound preferably has an imidazole skeleton or a pyrrole skeleton as a substituent.

Specific skeletons included in the third compound, specific examples of the third compound, and preferable structures are described in Embodiment 1 and thus repeated description thereof is omitted. Refer to the description in Embodiment 1.

Note that the first electron-transport layer and layers in the EL layer (i.e., the first layer) positioned closer to the first electrode than the first electron-transport layer is are independent from those of the light-emitting devices because an air exposure step (photolithography process) can be performed on the surface of the first electron-transport layer, and a space is preferably provided between the first layers of adjacent light-emitting devices. Since the first electron-transport layer and layers in the EL layer (first layer) positioned closer to the anode than the first electron-transport layer is are processed by a photolithography process, the distance between adjacent EL layers or the distance between adjacent first electrodes can be extremely narrowed to greater than or equal to 2 μm and less than or equal to 5 μm, so that a high-resolution display apparatus can be provided.

In the case where the EL layer is processed by a photolithography method, the organic semiconductor devices can be arranged at an extremely high density (a distance between the first electrodes can be approximately 2 μm to 5 μm). In the case where the organic semiconductor devices are display devices (light-emitting devices), an extremely high-resolution display apparatus with 500 ppi or more and an aperture ratio of 30% or more can be provided. Furthermore, an extremely high-resolution display apparatus with 100 ppi or more and an aperture ratio of 40% or more can be provided. Moreover, an extremely high-resolution display apparatus with 3000 ppi or more and an aperture ratio of 30% or more, or even 50% or more can be provided.

Note that in the case where the EL layers of adjacent light-emitting devices do not overlap with each other, that is, a space is provided between the organic compound layers of the adjacent light-emitting devices or between layers, which are provided below the first electron-transport layer, of adjacent semiconductor devices, this structure is preferable because crosstalk between the adjacent semiconductor devices can be inhibited. This is particularly effective when a distance between adjacent light-emitting devices is an extremely small distance greater than or equal to 2 μm or less than or equal to 5 μm.

Although the first electrode 101 includes an anode and the second electrode 102 includes a cathode in this embodiment, the first electrode 101 may include a cathode and the second electrode 102 may include an anode. The first electrode 101 and the second electrode 102 each have a single-layer structure or a stacked-layer structure. In the case of the stacked-layer structure, a layer in contact with the EL layer 103 serves as an anode or a cathode. In the case where the electrodes each have the stacked-layer structure, there is no limitation on work functions of materials for layers other than the layer in contact with the EL layer 103, and the materials can be selected in accordance with required properties such as a resistance value, processing easiness, reflectivity, light-transmitting property, and stability.

The anode is preferably formed using any of metals, alloys, and conductive compounds with a high work function (specifically, higher than or equal to 4.0 eV), mixtures thereof, and the like. Specific examples include indium oxide-tin oxide (ITO: Indium Tin Oxide), indium oxide-tin oxide containing silicon or silicon oxide, indium oxide-zinc oxide, and indium oxide containing tungsten oxide and zinc oxide (IWZO). Such conductive metal oxide films are usually formed by a sputtering method, but may be formed by application of a sol-gel method or the like. In an example of the formation method, indium oxide-zinc oxide is formed by a sputtering method using a target obtained by adding 1 to 20 wt % of zinc oxide to indium oxide. Furthermore, indium oxide containing tungsten oxide and zinc oxide (IWZO) can be formed by a sputtering method using a target in which tungsten oxide and zinc oxide are added to indium oxide at 0.5 to 5 wt % and 0.1 to 1 wt %, respectively. Other examples of the material used for the anode include gold (Au), platinum (Pt), nickel (Ni), tungsten (W), chromium (Cr), molybdenum (Mo), iron (Fe), cobalt (Co), copper (Cu), palladium (Pd), titanium (Ti), aluminum (Al), and nitride of a metal material (e.g., titanium nitride). The anode may be a stack of layers formed using any of these materials. For example, a film in which Al, Ti, and ITSO are stacked in this order over Ti is preferable because the film has high efficiency owing to high reflectivity and enables high resolution of several thousand ppi. Graphene can also be used for the anode. Note that when a composite material described later, which can be used in the hole-injection layer 111, is used for a layer (typically, a hole-injection layer) that is in contact with the anode, an electrode material can be selected regardless of its work function.

The hole-injection layer 111 is provided in contact with the anode and has a function of facilitating injection of holes into the EL layer 103. The hole-injection layer 111 can be formed using phthalocyanine (abbreviation: H₂Pc), a phthalocyanine-based compound or complex compound such as copper phthalocyanine (abbreviation: CuPc), an aromatic amine compound such as 4,4′-bis[N-(4-diphenylaminophenyl)-N-phenylamino]biphenyl (abbreviation: DPAB) or 4,4′-bis(N-{4-[N-(3-methylphenyl)-N′-phenylamino]phenyl}-N-phenylamino) biphenyl (abbreviation: DNTPD), a high molecular compound such as poly(3,4-ethylenedioxythiophene)/(polystyrenesulfonic acid) (abbreviation: PEDOT/PSS), or the like.

The hole-injection layer 111 may be formed using a substance having an electron-acceptor property. Examples of the substance having an acceptor property include an organic compound having an electron-withdrawing group (a halogen group, a cyano group, or the like), such as 7,7,8,8-tetracyano-2,3,5,6-tetrafluoroquinodimethane (abbreviation: F4-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), or 2-(7-dicyanomethylen-1,3,4,5,6,8,9,10-octafluoro-7H-pyren-2-ylidene)malononitrile. A compound in which electron-withdrawing groups are bonded to a condensed aromatic ring having a plurality of heteroatoms, such as HAT-CN, is particularly preferable because it is thermally stable. A [3]radialene derivative having an electron-withdrawing group (in particular, a cyano group or a halogen group such as a fluoro group) has a very high electron-accepting property and thus is preferable. Specific examples include α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], and α,α′,α″-1,2,3-cyclopropanetriylidenetris[2,3,4,5,6-pentafluorobenzeneacetonitrile]. As the substance having an acceptor property, transition metal oxide such as molybdenum oxide, vanadium oxide, ruthenium oxide, tungsten oxide, or manganese oxide can also be used, other than the above-described organic compounds.

The hole-injection layer 111 is preferably formed using a composite material containing the above material having an acceptor property and an organic compound having a hole-transport property.

As the organic compound having a hole-transport property that is used in the composite material, any of a variety of organic compounds such as aromatic amine compounds, heteroaromatic compounds, aromatic hydrocarbons, and high molecular compounds (e.g., oligomers, dendrimers, or polymers) can be used. Note that the organic compound having a hole-transport property that is used in the composite material preferably has a hole mobility of 1×10⁻⁶ cm²/Vs or higher. The organic compound having a hole-transport property that is used in the composite material is preferably a compound having a condensed aromatic hydrocarbon ring or a π-electron rich heteroaromatic ring. As the condensed aromatic hydrocarbon ring, an anthracene ring, a naphthalene ring, or the like is preferable. As the π-electron rich heteroaromatic ring, a condensed aromatic ring having at least one of a pyrrole skeleton, a furan skeleton, and a thiophene skeleton in the ring is preferable; specifically, a carbazole ring, a dibenzothiophene ring, or a ring in which an aromatic ring or a heteroaromatic ring is further condensed to the carbazole ring or the dibenzothiophene ring is preferable.

Such an organic compound having a hole-transport property further preferably has any of a carbazole skeleton, a dibenzofuran skeleton, a dibenzothiophene skeleton, and an anthracene skeleton. In particular, an aromatic amine having a substituent that includes a dibenzofuran ring or a dibenzothiophene ring, an aromatic monoamine that includes a naphthalene ring, or an aromatic monoamine in which a 9-fluorenyl group is bonded to nitrogen of amine through an arylene group may be used. Note that the organic compound having a hole-transport property preferably has an N,N-bis(4-biphenyl)amino group because a light-emitting device having a long lifetime can be manufactured.

Specific examples of the above-described organic compounds having a hole-transport property include N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf (6)), N,N-bis(4-biphenyl)benzo[b]naphtho[1,2-d]furan-8-amine (abbreviation: BBABnf (8)), N,N-bis(4-biphenyl)benzo[b]naphtho[2,3-d]furan-4-amine (abbreviation: BBABnf (II) (4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-(6;1′-binaphthyl-2-yl)triphenylamine (abbreviation: BBAαNβNB), 4,4′-diphenyl-4″-(7;1′-binaphthyl-2-yl)triphenylamine (abbreviation: BBAαNβNB-03), 4,4′-diphenyl-4″-(7-phenyl) naphthyl-2-yltriphenylamine (abbreviation: BBAPbNB-03), 4,4′-diphenyl-4″-(6;2′-binaphthyl-2-yl)triphenylamine (abbreviation: BBA(βN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAβNαNB), 4,4′-diphenyl-4″-(5;2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl) biphenyl-4-yl]triphenylamine (abbreviation: YGTBi1BP), 4′-[4-(3-phenyl-9H-carbazol-9-yl)phenyl]tris(1,1′-biphenyl-4-yl)amine (abbreviation: YGTBi1BP-02), 4-[4′-(carbazol-9-yl) biphenyl-4-yl]-4′-(2-naphthyl)-4″-phenyltriphenylamine (abbreviation: YGTBiβNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis([1,1′-biphenyl]-4-yl)-9,9′-spirobi[9H-fluoren]-2-amine (abbreviation: BBASF), N,N-bis([1,1′-biphenyl]-4-yl)-9,9′-spirobi[9H-fluoren]-4-amine (abbreviation: BBASF (4)), N-(1,1′-biphenyl-2-yl)-N-(9,9-dimethyl-9H-fluoren-2-yl)-9,9′-spirobi[9H-fluoren]-4-amine (abbreviation: oFBiSF), N-(biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]-9,9′-spirobi[9H-fluoren]-2-amine (abbreviation: PCBASF), N-(1,1′-biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, and N,N-bis(9,9-dimethyl-9H-fluoren-2-yl)-9,9′-spirobi-9H-fluoren-1-amine.

As the material having a hole-transport property, the following aromatic amine compounds can also be used: N,N′-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), 4,4′-bis(N-{4-[N′-(3-methylphenyl)-N′-phenylamino]phenyl}-N-phenylamino) biphenyl (abbreviation: DNTPD), and 1,3,5-tris[N-(4-diphenylaminophenyl)-N-phenylamino]benzene (abbreviation: DPA3B).

The formation of the hole-injection layer 111 can improve the hole-injection property, whereby a light-emitting device having a low driving voltage can be obtained.

Among substances having an acceptor property, an organic compound having an acceptor property is easy to use because it is easily deposited by vapor deposition.

Note that the first compound may be used for the hole-injection layer 111.

The hole-transport layer 112 contains an organic compound having a hole-transport property. The organic compound having a hole-transport property preferably has a hole mobility higher than or equal to 1×10⁻⁶ cm²/Vs.

Examples of the material having a hole-transport property include compounds having an aromatic amine skeleton, such as 4,4′-bis[N-(1-naphthyl)-N-phenylamino]biphenyl (abbreviation: NPB), N,N′-diphenyl-N,N′-bis(3-methylphenyl)-4,4′-diaminobiphenyl (abbreviation: TPD), N,N′-bis(9,9′-spirobi[9H-fluoren]-2-yl)-N,N′-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), and N-phenyl-N-[4-(9-phenyl-9H-carbazol-3-yl)phenyl]-9,9′-spirobi[9H-fluoren]-2-amine (abbreviation: PCBASF); compounds having a carbazole skeleton, such as 1,3-bis(N-carbazolyl)benzene (abbreviation: mCP), 4,4′-di(N-carbazolyl) biphenyl (abbreviation: CBP), 3,6-bis(3,5-diphenylphenyl)-9-phenylcarbazole (abbreviation: CzTP), 3,3′-bis(9-phenyl-9H-carbazole) (abbreviation: PCCP), 9,9′-bis(biphenyl-4-yl)-3,3′-bi-9H-carbazole (abbreviation: BisBPCz), 9,9′-bis(1,1′-biphenyl-3-yl)-3,3′-bi-9H-carbazole (abbreviation: BismBPCz), 9-(1,1′-biphenyl-3-yl)-9′-(1,1′-biphenyl-4-yl)-9H,9′H-3,3′-bicarbazole (abbreviation: mBPCCBP), 9-(2-naphthyl)-9′-phenyl-9H,9′H-3,3′-bicarbazole (abbreviation: βNCCP), 9-(3-biphenyl)-9′-(2-naphthyl)-3,3′-bi-9H-carbazole (abbreviation: βNCCmBP), 9-(4-biphenyl)-9′-(2-naphthyl)-3,3′-bi-9H-carbazole (abbreviation: βNCCBP), 9,9′-di-2-naphthyl-3,3′-9H,9′H-bicarbazole (abbreviation: BisβNCz), 9-(2-naphthyl)-9′-[1,1′: 4′,1″-terphenyl]-3-yl-3,3′-9H,9′H-bicarbazole, 9-(2-naphthyl)-9′-[1,1′:3′,1″-terphenyl]-3-yl-3,3′-9H,9′H-bicarbazole, 9-(2-naphthyl)-9′-[1,1′:3′,1″-terphenyl]-5′-yl-3,3′-9H,9′H-bicarbazole, 9-(2-naphthyl)-9′-[1,1′: 4′,1″-terphenyl]-4-yl-3,3′-9H,9′H-bicarbazole, 9-(2-naphthyl)-9′-[1,1′:3′,1″-terphenyl]-4-yl-3,3′-9H,9′H-bicarbazole, 9-(2-naphthyl)-9′-(triphenylen-2-yl)-3,3′-9H,9′H-bicarbazole, 9-phenyl-9′-(triphenylen-2-yl)-3,3′-9H,9′H-bicarbazole (abbreviation: PCCzTp), 9,9′-bis(triphenylen-2-yl)-3,3′-9H,9′H-bicarbazole, 9-(4-biphenyl)-9′-(triphenylen-2-yl)-3,3′-9H,9′H-bicarbazole, and 9-(triphenylen-2-yl)-9′-[1,1′:3′,1″-terphenyl]-4-yl-3,3′-9H,9′H-bicarbazole; compounds having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV); and compounds having a furan skeleton, such as 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II). Among the above materials, the compound having an aromatic amine skeleton and the compound having a carbazole skeleton are preferable because these compounds are highly reliable and have high hole-transport properties to contribute to a reduction in driving voltage. Note that any of the substances given as examples of the hole-transport material used for the composite material for the hole-injection layer 111 can also be suitably used as the material included in the hole-transport layer 112.

The light-emitting layer 113 is a layer containing a light-emitting substance and preferably contains a light-emitting substance and a host material. The light-emitting layer may additionally contain other materials. Alternatively, the light-emitting layer may be a stack of two layers with different compositions.

The light-emitting substance may be a fluorescent substance, a phosphorescent substance, a substance exhibiting thermally activated delayed fluorescence (TADF), or another light-emitting substance.

Examples of the material that can be used as a fluorescent substance in the light-emitting layer are as follows. Other fluorescent substances can also be used.

The examples include 5,6-bis[4-(10-phenyl-9-anthryl)phenyl]-2,2′-bipyridine (abbreviation: PAP2BPy), 5,6-bis[4′-(10-phenyl-9-anthryl) biphenyl-4-yl]-2,2′-bipyridine (abbreviation: PAPP2BPy), N,N′-diphenyl-N,N′-bis[4-(9-phenyl-9H-fluoren-9-yl)phenyl]pyrene-1,6-diamine (abbreviation: 1,6FLPAPrn), N,N′-bis(3-methylphenyl)-N,N′-bis[3-(9-phenyl-9H-fluoren-9-yl)phenyl]pyrene-1,6-diamine (abbreviation: 1,6mMemFLPAPrn), N,N′-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra-tert-butylperylene (abbreviation: TBP), 4-(10-phenyl-9-anthryl)-4′-(9-phenyl-9H-carbazol-3-yl)triphenylamine (abbreviation: PCBAPA), N,N″-(2-tert-butylanthracene-9,10-diyldi-4,1-phenylene)bis[N,N′,N′-triphenyl-1,4-phenylenediamine](abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N′,N′-triphenyl-1,4-phenylenediamine (abbreviation: 2DPAPPA), N,N,N′,N′,N″,N″,N′″,N′″-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(1,1′-biphenyl-2-yl)-2-anthryl]-N,9-diphenyl-9H-carbazol-3-amine (abbreviation: 2PCABPhA), N-(9,10-diphenyl-2-anthryl)-N,N′,N′-triphenyl-1,4-phenylenediamine (abbreviation: 2DPAPA), N-[9,10-bis(1,1′-biphenyl-2-yl)-2-anthryl]-N,N′,N′-triphenyl-1,4-phenylenediamine (abbreviation: 2DPABPhA), 9,10-bis(1,1′-biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N′-diphenylquinacridone (abbreviation: DPQd), rubrene, 5,12-bis(1,1′-biphenyl-4-yl)-6,11-diphenyltetracene (abbreviation: BPT), 2-(2-{2-[4-(dimethylamino)phenyl]ethenyl}-6-methyl-4H-pyran-4-ylidene) propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene) propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), N,N′-diphenyl-N,N′-(1,6-pyrene-diyl)bis[(6-phenylbenzo[b]naphtho[1,2-d]furan)-8-amine](abbreviation: 1,6BnfAPrn-03), 3,10-bis[N-(9-phenyl-9H-carbazol-2-yl)-N-phenylamino]naphtho[2,3-b;6,7-b′]bisbenzofuran (abbreviation: 3,10PCA2Nbf (IV)-02), and 3,10-bis[N-(dibenzofuran-3-yl)-N-phenylamino]naphtho[2,3-b;6,7-b′]bisbenzofuran (abbreviation: 3,10FrA2Nbf (IV)-02). Condensed aromatic diamine compounds typified by pyrenediamine compounds such as 1,6FLPAPrn, 1,6mMemFLPAPrn, and 1,6BnfAPrn-03 are particularly preferable because of their high hole-trapping properties, high emission efficiency, or high reliability.

A fused heteroaromatic compound containing nitrogen and boron, especially a compound having a diaza-boranaphtho-anthracene skeleton, exhibits a narrow emission spectrum, emits blue light with high color purity, and can thus be suitably used. Examples of the compound include 5,9-diphenyl-5,9-diaza-13b-boranaphtho[3,2,1-de]anthracene (abbreviation: DABNA1), 9-([1,1′-diphenyl]-3-yl)-N,N,5,11-tetraphenyl-5,9-dihydro-5,9-diaza-13b-boranaphtho[3,2,1-de]anthracen-3-amine (abbreviation: DABNA2), 2,12-di(tert-butyl)-5,9-di(4-tert-butylphenyl)-N,N-diphenyl-5H,9H-[1,4]benzazaborino[2,3,4-kl]phenazaborin-7-amine (abbreviation: DPhA-tBu4DABNA), 2,12-di(tert-butyl)-N,N,5,9-tetra(4-tert-butylphenyl)-5H,9H-[1,4]benzazaborino[2,3,4-kl]phenazaborin-7-amine (abbreviation: tBuDPhA-tBu4DABNA), 2,12-di(tert-butyl)-5,9-di(4-tert-butylphenyl)-7-methyl-5H,9H-[1,4]benzazaborino[2,3,4-kl]phenazaborine (abbreviation: Me-tBu4DABNA), N⁷,N⁷,N¹³,N¹³,5,9,11,15-octaphenyl-5H,9H,11H,15H-[1,4]benzazaborino[2,3,4-kl][1,4]benzazaborino[4′,3′,2′:4,5][1,4]benzazaborino[3,2-b]phenazaborine-7,13-diamine (abbreviation: v-DABNA), and 2-(4-tert-butylphenyl)benz[5,6]indolo[3,2,1-jk]benzo[b]carbazole (abbreviation: tBuPBibc).

Besides the above compounds, 9,10,11-tris[3,6-bis(1,1-dimethylethyl)-9H-carbazolyl-9-yl]-2,5,15,18-tetrakis(1,1-dimethylethyl)indolo[3,2,1-de]indolo[3′,2′,1′:8,1][1,4]benzazaborino[2,3,4-kl]phenazaborine (abbreviation: BBCz-G), 9,11-bis[3,6-bis(1,1-dimethylethyl)-9H-carbazolyl-9-yl]-2,5,15,18-tetrakis(1,1-dimethylethyl)indolo[3,2,1-de]indolo[3′,2′,1′:8,1][1,4]benzazaborino[2,3,4-kl]phenazaborine (abbreviation: BBCz-Y), or the like can be suitably used.

Examples of the material that can be used when a phosphorescent substance is used as the light-emitting substance in the light-emitting layer are as follows.

The examples include an organometallic iridium complex having a 4H-triazole skeleton, such as tris {2-[5-(2-methylphenyl)-4-(2,6-dimethylphenyl)-4H-1,2,4-triazol-3-yl-κN2]phenyl-κC}iridium(III) (abbreviation: [Ir(mpptz-dmp)₃]) or tris(5-methyl-3,4-diphenyl-4H-1,2,4-triazolato)iridium(III) (abbreviation: [Ir(Mptz)₃]); an organometallic iridium complex having a 1H-triazole skeleton, such as tris[3-methyl-1-(2-methylphenyl)-5-phenyl-1H-1,2,4-triazolato]iridium(III) (abbreviation: [Ir(Mptz1-mp)₃]) or tris(1-methyl-5-phenyl-3-propyl-1H-1,2,4-triazolato)iridium(III) (abbreviation: [Ir(Prptz1-Me)₃]); an organometallic iridium complex having an imidazole skeleton, such as fac-tris[1-(2,6-diisopropylphenyl)-2-phenyl-1H-imidazole]iridium(III) (abbreviation: [Ir(iPrpim)₃]), tris[3-(2,6-dimethylphenyl)-7-methylimidazo[1,2-f]phenanthridinato]iridium(III) (abbreviation: [Ir(dmpimpt-Me)₃]), or tris(2-[1-{2,6-bis(1-methylethyl)phenyl}-1H-imidazol-2-yl-κN₃]-4-cyanophenyl-κC) (abbreviation: CNImIr); an organometallic complex having a benzimidazolidene skeleton, such as tris[(6-tert-butyl-3-phenyl-(2H-imidazo[4,5-b]pyrazin-1-yl-κC2)phenyl-κC]iridium(III) (abbreviation: [Ir(cb)₃]); and an organometallic iridium complex in which a phenylpyridine derivative having an electron-withdrawing group is a ligand, such as bis[2-(4′,6′-difluorophenyl)pyridinato-N,C²]iridium(III) tetrakis(1-pyrazolyl) borate (abbreviation: FIr6), bis[2-(4′,6′-difluorophenyl)pyridinato-N,C^{2′}]iridium(III) picolinate (abbreviation: FIrpic), bis{2-[3′,5′-bis(trifluoromethyl)phenyl]pyridinato-N,C^{2′}}iridium(III) picolinate (abbreviation: [Ir(CF₃ppy)₂(pic)]), or bis[2-(4′,6′-difluorophenyl)pyridinato-N,C^{2′}]iridium(III) acetylacetonate (abbreviation: FIracac). These compounds exhibit blue phosphorescent light and have an emission peak in the wavelength range of 450 nm to 520 nm.

Other examples include an organometallic iridium complex having a pyrimidine skeleton, such as tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), or (acetylacetonato)bis(4,6-diphenylpyrimidinato)iridium(III) (abbreviation: [Ir(dppm)₂(acac)]); an organometallic iridium complex having a pyrazine skeleton, such as (acetylacetonato)bis(3,5-dimethyl-2-phenylpyrazinato)iridium(III) (abbreviation: [Ir(mppr-Me)₂(acac)]) or (acetylacetonato)bis(5-isopropyl-3-methyl-2-phenylpyrazinato)iridium(III) (abbreviation: [Ir(mppr-iPr)₂(acac)]); an organometallic iridium complex having a pyridine skeleton, such as tris(2-phenylpyridinato-N,C^{2′})iridium(III) (abbreviation: [Ir(ppy)₃]), bis(2-phenylpyridinato-N,C^{2′})iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C^{2′})iridium(III) (abbreviation: [Ir(pq)₃]), bis(2-phenylquinolinato-N,C^{2′})iridium(III) acetylacetonate (abbreviation: [Ir(pq)₂(acac)]), [2-d₃-methyl-8-(2-pyridinyl-κN)benzofuro[2,3-b]pyridine-κC]bis[2-(5-d₃-methyl-2-pyridinyl-κN²)phenyl-κ]iridium(III) (abbreviation: [Ir(5mppy-d₃)₂(mbfpypy-d₃)]), [2-d₃-methyl-(2-pyridinyl-κN)benzofuro[2,3-b]pyridine-κC]bis[2-(2-pyridinyl-κN)phenyl-κC]iridium(III) (abbreviation: [Ir(ppy)₂(mbfpypy-d₃)]), [2-(4-d₃-methyl-5-phenyl-2-pyridinyl-κN²)phenyl-κC]bis[2-(5-d₃-methyl-2-pyridinyl-κN²)phenyl-κC]iridium(III) (abbreviation: [Ir(5mppy-d₃)₂(mdppy-d₃)]), [2-methyl-8-(2-pyridinyl-κN)benzofuro[2,3-b]pyridine-κC]bis[2-(2-pyridinyl-κN)phenyl-κC]iridium(III) (abbreviation: [Ir(ppy)₂(mbfpypy)]), or [2-(4-methyl-5-phenyl-2-pyridinyl-κN)phenyl-κC]bis[2-(2-pyridinyl-κN)phenyl-«C]iridium(III) (abbreviation: [Ir(ppy)₂(mdppy)]); and a rare earth metal complex such as tris(acetylacetonato) (monophenanthroline) terbium (III) (abbreviation: [Tb(acac)₃(Phen)]). These are mainly compounds that exhibit green phosphorescent light and have an emission peak in the wavelength range of 500 nm to 600 nm. Note that organometallic iridium complexes having a pyrimidine skeleton have distinctively high reliability or emission efficiency and thus are particularly preferable.

The examples include an organometallic iridium complex having a pyrimidine skeleton, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), or bis[4,6-di(naphthalen-1-yl)pyrimidinato](dipivaloylmethanato)iridium(III) (abbreviation: [Ir(d1npm)₂(dpm)]); an organometallic iridium complex having a pyrazine skeleton, such as (acetylacetonato)bis(2,3,5-triphenylpyrazinato)iridium(III) (abbreviation: [Ir(tppr)₂(acac)]), bis(2,3,5-triphenylpyrazinato) (dipivaloylmethanato)iridium(III) (abbreviation: [Ir(tppr)₂(dpm)]), or (acetylacetonato)bis[2,3-bis(4-fluorophenyl) quinoxalinato]iridium(III) (abbreviation: [Ir(Fdpq)₂(acac)]); an organometallic iridium complex having a pyridine skeleton, such as tris(1-phenylisoquinolinato-N,C^{2′})iridium(III) (abbreviation: [Ir(piq)₃]), bis(1-phenylisoquinolinato-N,C^{2′})iridium(III) acetylacetonate (abbreviation: [Ir(piq)₂(acac)]), (3,7-diethyl-4,6-nonanedionato-κO4, κO6)bis[2,4-dimethyl-6-[7-(1-methylethyl)-1-isoquinolinyl-κN]phenyl-κC]iridium(III), and (3,7-diethyl-4,6-nonanedionato-κO4,κO6)bis[2,4-dimethyl-6-[5-(1-methylethyl)-2-quinolinyl-κN]phenyl-κC]iridium(III); a platinum complex such as 2,3,7,8,12,13,17,18-octaethyl-21H,23H-porphyrinplatinum (II) (abbreviation: PtOEP); and a rare earth metal complex such as tris(1,3-diphenyl-1,3-propanedionato) (monophenanthroline) europium (III) (abbreviation: [Eu(DBM)₃(Phen)]) or tris[1-(2-thenoyl)-3,3,3-trifluoroacetonato](monophenanthroline) europium (III) (abbreviation: [Eu(TTA)₃(Phen)]). These compounds exhibit red phosphorescent light and have an emission peak in the wavelength range of 600 nm to 700 nm. Organometallic iridium complexes having a pyrazine skeleton can provide red light emission with favorable chromaticity.

Besides the above-described phosphorescent compounds, other known phosphorescent compounds may be selected and used.

Examples of the TADF material include a fullerene, a derivative thereof, an acridine, a derivative thereof, and an eosin derivative. Furthermore, a metal-containing porphyrin, such as a porphyrin containing magnesium (Mg), zinc (Zn), cadmium (Cd), tin (Sn), platinum (Pt), indium (In), or palladium (Pd), can be given as an example. Examples of the metal-containing porphyrin include a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), and an octaethylporphyrin-platinum chloride complex (PtCl₂OEP), which are represented by the following structural formulae.

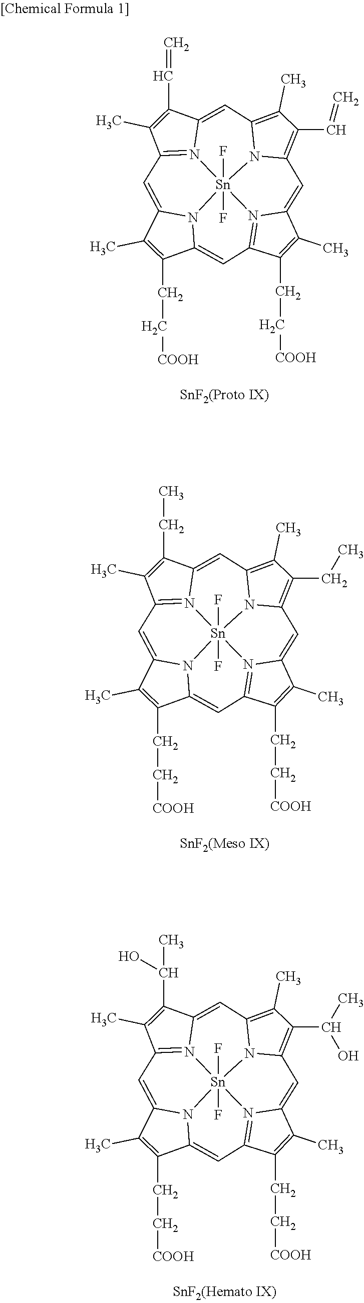

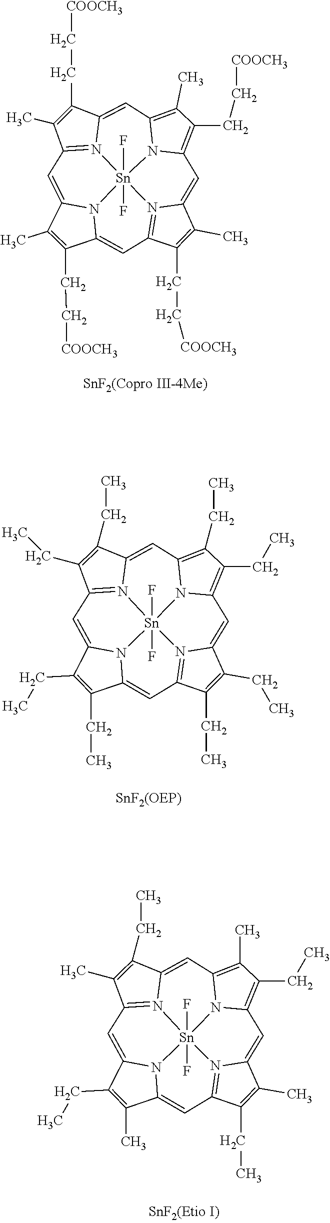

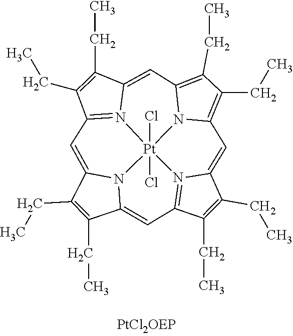

Alternatively, a heterocyclic compound having one or both of a π-electron rich heteroaromatic ring and a r-electron deficient heteroaromatic ring that is represented by the following structural formulae, such as 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bi-9H-carbazole (abbreviation: PCCzTzn), 9-[4-(4,6-diphenyl-1,3,5-triazin-2-yl)phenyl]-9′-phenyl-3,3′-bi-9H-carbazole (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), or 10-phenyl-10H,10′H-spiro[acridin-9,9′-anthracen]-10′-one (abbreviation: ACRSA) can be used. Such a heterocyclic compound is preferable because of having excellent electron-transport and hole-transport properties owing to a π-electron rich heteroaromatic ring and a π-electron deficient heteroaromatic ring. Among skeletons having the π-electron deficient heteroaromatic ring, a pyridine skeleton, a diazine skeleton (a pyrimidine skeleton, a pyrazine skeleton, and a pyridazine skeleton), and a triazine skeleton are preferable because of their high stability and reliability. In particular, a benzofuropyrimidine skeleton, a benzothienopyrimidine skeleton, a benzofuropyrazine skeleton, and a benzothienopyrazine skeleton are preferable because of their high acceptor properties and high reliability. Among skeletons having the π-electron rich heteroaromatic ring, an acridine skeleton, a phenoxazine skeleton, a phenothiazine skeleton, a furan skeleton, a thiophene skeleton, and a pyrrole skeleton have high stability and reliability; thus, at least one of these skeletons is preferably included. A dibenzofuran skeleton and a dibenzothiophene skeleton are preferable as a furan skeleton and a thiophene skeleton, respectively. As a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable. Note that a substance in which the π-electron rich heteroaromatic ring is directly bonded to the π-electron deficient heteroaromatic ring is particularly preferred because the electron-donating property of the T-electron rich heteroaromatic ring and the electron-accepting property of the π-electron deficient heteroaromatic ring are both improved, the energy difference between the S1 level and the T1 level becomes small, and thus thermally activated delayed fluorescence can be obtained with high efficiency. Note that an aromatic ring to which an electron-withdrawing group such as a cyano group is bonded may be used instead of the π-electron deficient heteroaromatic ring. As a π-electron rich skeleton, an aromatic amine skeleton, a phenazine skeleton, or the like can be used. As a π-electron deficient skeleton, a xanthene skeleton, a thioxanthene dioxide skeleton, an oxadiazole skeleton, a triazole skeleton, an imidazole skeleton, an anthraquinone skeleton, a skeleton containing boron such as phenylborane or boranthrene, an aromatic ring having a cyano group or a nitrile group such as benzonitrile or cyanobenzene, a heteroaromatic ring, a carbonyl skeleton such as benzophenone, a phosphine oxide skeleton, a sulfone skeleton, or the like can be used. As described above, a π-electron deficient skeleton and a π-electron rich skeleton can be used instead of at least one of the π-electron deficient heteroaromatic ring and the π-electron rich heteroaromatic ring.

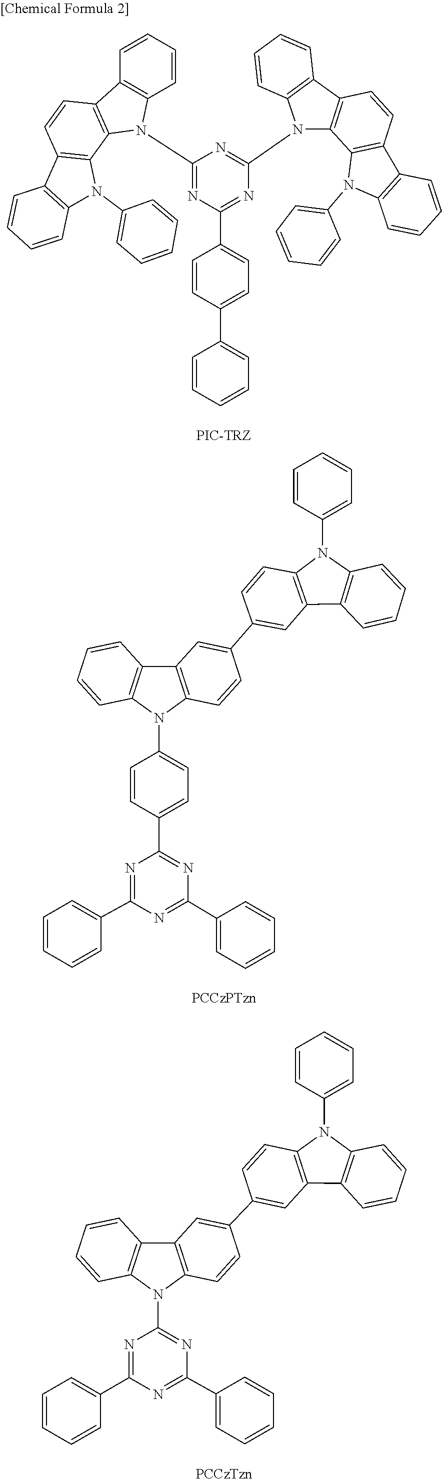 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2nc(-c3ccccc3)nc(-n3c4ccccc4c4cc(-c5ccc6c(c5)c5ccccc5n6-c5ccccc5)ccc43)n2)cc1]

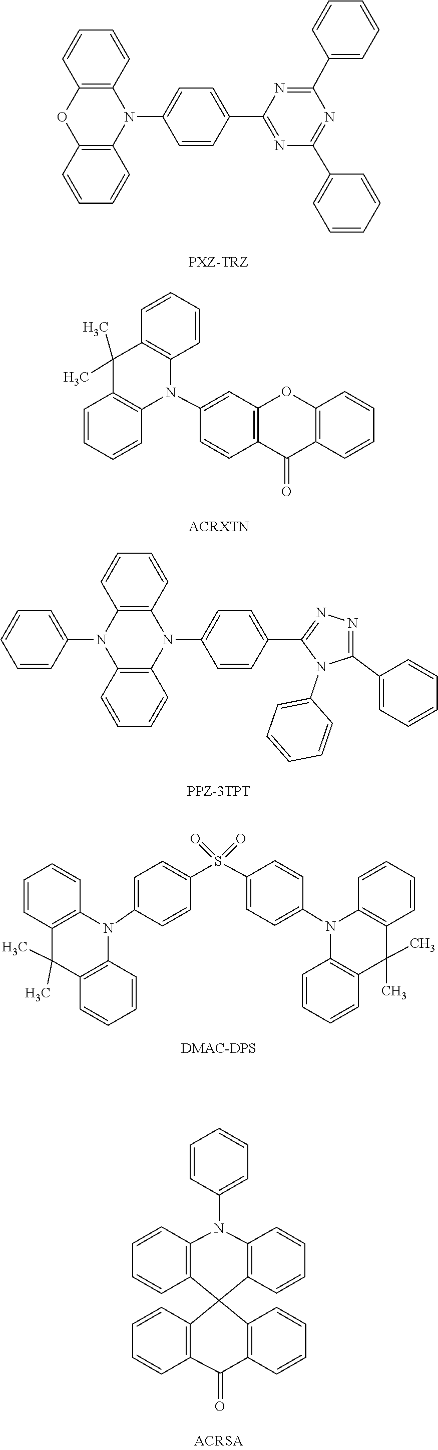

Note that a TADF material is a material having a small difference between the S1 level and the T1 level and a function of converting triplet excitation energy into singlet excitation energy by reverse intersystem crossing. Thus, it is possible to upconvert triplet excitation energy into singlet excitation energy (i.e., reverse intersystem crossing) using a small amount of thermal energy and efficiently generate a singlet excited state. In addition, the triplet excitation energy can be converted into luminescence.

An exciplex whose excited state is formed of two kinds of substances has an extremely small difference between the S1 level and the T1 level and has a function of a TADF material capable of converting triplet excitation energy into singlet excitation energy.

A phosphorescent spectrum observed at low temperature (e.g., 77 K to 10 K) may be used for an index of the T1 level. When the level of energy with a wavelength of the line obtained by extrapolating a tangent to the fluorescent spectrum at a tail on the short wavelength side is the S1 level and the level of energy with a wavelength of the line obtained by extrapolating a tangent to the phosphorescent spectrum at a tail on the short wavelength side is the T1 level, the difference between the S1 level and the T1 level of the TADF material is preferably smaller than or equal to 0.3 eV, further preferably smaller than or equal to 0.2 eV.

When a TADF material is used as the light-emitting substance, the S1 level of the host material is preferably higher than the S1 level of the TADF material. In addition, the T1 level of the host material is preferably higher than the T1 level of the TADF material.

As the host material in the light-emitting layer, various carrier-transport materials such as materials having an electron-transport property and/or materials having a hole-transport property, and the TADF materials can be used.

The material having a hole-transport property is preferably an organic compound having an amine skeleton, a π-electron rich heteroaromatic ring skeleton, or the like. As the π-electron rich heteroaromatic ring, a condensed aromatic ring having at least one of an acridine skeleton, a phenoxazine skeleton, a phenothiazine skeleton, a furan skeleton, a thiophene skeleton, and a pyrrole skeleton is preferable; specifically, a carbazole ring, a dibenzothiophene ring, or a ring in which an aromatic ring or a heteroaromatic ring is further condensed to the carbazole ring or the dibenzothiophene ring is preferable.

Such an organic compound having a hole-transport property further preferably has any of a carbazole skeleton, a dibenzofuran skeleton, a dibenzothiophene skeleton, and an anthracene skeleton. In particular, an aromatic amine having a substituent that includes a dibenzofuran ring or a dibenzothiophene ring, an aromatic monoamine that includes a naphthalene ring, or an aromatic monoamine in which a 9-fluorenyl group is bonded to nitrogen of amine through an arylene group may be used. Note that the organic compound having a hole-transport property preferably has an N,N-bis(4-biphenyl)amino group because a light-emitting device having a long lifetime can be manufactured.

Examples of such an organic compound include a compound having an aromatic amine skeleton, such as 4,4′-bis[N-(1-naphthyl)-N-phenylamino]biphenyl (abbreviation: NPB), N,N′-diphenyl-N,N′-bis(3-methylphenyl]-4,4′-diaminnobiphenyl (abbreviation: TPD), 4,4′-bis(9,9′-spirobi[9H-fluoren]-2-yl)-N,N-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), or N-phenyl-N-[4-(9-phenyl-9H-carbazol-3-yl)phenyl]-9,9′-spirobi[9H-fluoren]-2-amine (abbreviation: PCBASF); a compound having a carbazole skeleton, such as 1,3-bis(N-carbazolyl)benzene (abbreviation: mCP), 4,4′-di(N-carbazolyl) biphenyl (abbreviation: CBP), 3,6-bis(3,5-diphenylphenyl)-9-phenylcarbazole (abbreviation: CzTP), or 3,3′-bis(9-phenyl-9H-carbazole) (abbreviation: PCCP); a compound having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), or 4-[4-(9-phenyl-9H-fluoren-9-yl)phenyl]-6-phenyldibenzothiophene (abbreviation: DBTFLP-IV); and a compound having a furan skeleton, such as 4,4′,4″-(benzene-1,3,5-triyl)tri(dibenzofuran) (abbreviation: DBF3P-II) or 4-{3-[3-(9-phenyl-9H-fluoren-9-yl)phenyl]phenyl}dibenzofuran (abbreviation: mmDBFFLBi-II). Among the above materials, the compound having an aromatic amine skeleton and the compound having a carbazole skeleton are preferable because these compounds are highly reliable and have high hole-transport properties to contribute to a reduction in driving voltage. In addition, the organic compounds given as examples of the material having a hole-transport property that can be used for the hole-transport layer can also be used.

The material having an electron-transport property is preferably a substance having an electron mobility higher than or equal to 1×10⁻⁷ cm²/Vs, further preferably higher than or equal to 1×10⁻⁶ cm²/Vs in the case where the square root of the electric field strength [V/cm] is 600. Note that any other substance can also be used as long as the substance has an electron-transport property higher than a hole-transport property.

As the material having an electron-transport property, for example, a metal complex such as bis(10-hydroxybenzo[h]quinolinato) beryllium (II) (abbreviation: BeBq₂), bis(2-methyl-8-quinolinolato) (4-phenylphenolato)aluminum (III) (abbreviation: BAlq), bis(8-quinolinolato) zinc (II) (abbreviation: Znq), bis[2-(2-benzoxazolyl)phenolato]zinc (II) (abbreviation: ZnPBO), or bis[2-(2-benzothiazolyl)phenolato]zinc (II) (abbreviation: ZnBTZ); or an organic compound having a π-electron deficient heteroaromatic ring is preferable. The organic compound having a π-electron deficient heteroaromatic ring skeleton is preferably one or more of an organic compound having a heteroaromatic ring having a polyazole skeleton, an organic compound having a heteroaromatic ring having a pyridine skeleton, an organic compound having a heteroaromatic ring having a diazine skeleton, and an organic compound having a heteroaromatic ring having a triazine skeleton.

Among the above materials, the organic compound having a heteroaromatic ring having a diazine skeleton (such as a pyrimidine skeleton, a pyrazine skeleton, or a pyridazine skeleton), the organic compound having a heteroaromatic ring having a pyridine skeleton, and the organic compound having a heteroaromatic ring having a triazine skeleton have high reliability and thus are preferable. In particular, the organic compound having a heteroaromatic ring having a diazine (pyrimidine or pyrazine) skeleton and the organic compound having a heteroaromatic ring having a triazine skeleton have a high electron-transport property to contribute to a reduction in driving voltage. In particular, a benzofuropyrimidine skeleton, a benzothienopyrimidine skeleton, a benzofuropyrazine skeleton, and a benzothienopyrazine skeleton are preferable because of their high acceptor property and reliability.

Examples of the organic compound having a π-electron deficient heteroaromatic ring include an organic compound having an azole skeleton, such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), or 4,4′-bis(5-methylbenzoxazol-2-yl) stilbene (abbreviation: BzOs); an organic compound having a heteroaromatic ring having a pyridine skeleton, such as 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), bathophenanthroline (abbreviation: Bphen), bathocuproine (abbreviation: BCP), 2,9-di(naphthalen-2-yl)-4,7-diphenyl-1,10-phenanthroline (abbreviation: NBphen), 2,2′-(1,3-phenylene)bis(9-phenyl-1,10-phenanthroline) (abbreviation: mPPhen2P), 2-[3-(2-triphenylenyl)phenyl]-1,10-phenanthroline (abbreviation: mTpPPhen), 2-phenyl-9-(2-triphenylenyl)-1,10-phenanthroline (abbreviation: Ph-TpPhen), 2-[4-(9-phenanthrenyl)-1-naphthalenyl]-1,10-phenanthroline (abbreviation: PnNPhen), or 2-[4-(2-triphenylenyl)phenyl]-1,10-phenanthroline (abbreviation: pTpPPhen); an organic compound having a diazine skeleton, such as 2-[3-(dibenzothiophen-4-yl)phenyl]dibenzo[f,h]quinoxaline (abbreviation: 2mDBTPDBq-II), 2-[3-(3′-dibenzothiophen-4-yl) biphenyl]dibenzo[f,h]quinoxaline (abbreviation: 2mDBTBPDBq-II), 2-[3′-(9H-carbazol-9-yl) biphenyl-3-yl]dibenzo[f,h]quinoxaline (abbreviation: 2mCzBPDBq), 2-[4′-(9-phenyl-9H-carbazol-3-yl)-3,1′-biphenyl-1-yl]dibenzo[f,h]quinoxaline (abbreviation: 2mpPCBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 9-[3′-(dibenzothiophen-4-yl) biphenyl-3-yl]naphtho[1′,2′: 4,5]furo[2,3-b]pyrazine (abbreviation: 9mDBtBPNfpr), 9-[3′-(dibenzothiophen-4-yl) biphenyl-4-yl]naphtho[1′,2′: 4,5]furo[2,3-b]pyrazine (abbreviation: 9pmDBtBPNfpr), 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 9,9′-[pyrimidine-4,6-diylbis(biphenyl-3,3′-diyl)]bis(9H-carbazole) (abbreviation: 4,6mCzBP2Pm), 8-(1,1′-biphenyl-4-yl)-4-[3-(dibenzothiophen-4-yl)phenyl]-[1]benzofuro[3,2-d]pyrimidine (abbreviation: 8BP-4mDBtPBfpm), 3,8-bis[3-(dibenzothiophen-4-yl)phenyl]benzofuro[2,3-b]pyrazine (abbreviation: 3,8mDBtP2Bfpr), 4,8-bis[3-(dibenzothiophen-4-yl)phenyl]-[1]benzofuro[3,2-d]pyrimidine (abbreviation: 4,8mDBtP2Bfpm), 8-[3′-(dibenzothiophen-4-yl) (1,1′-biphenyl-3-yl)]naphtho[1′,2′:4,5]furo[3,2-d]pyrimidine (abbreviation: 8mDBtBPNfpm), 8-[(2,2′-binaphthalen)-6-yl]-4-[3-(dibenzothiophen-4-yl)phenyl]-[1]benzofuro[3,2-d]pyrimidine (abbreviation: 8 (βN2)-4mDBtPBfpm), 2,2′-(pyridine-2,6-diyl)bis(4-phenylbenzo[h]quinazoline) (abbreviation: 2,6 (P-Bqn)2Py), 2,2′-(pyridine-2,6-diyl)bis{4-[4-(2-naphthyl)phenyl]-6-phenylpyrimidine}(abbreviation: 2,6 (NP-PPm)2Py), 6-(1,1′-biphenyl-3-yl)-4-[3,5-bis(9H-carbazol-9-yl)phenyl]-2-phenylpyrimidine (abbreviation: 6mBP-4Cz2PPm), 2,6-bis(4-naphthalen-1-ylphenyl)-4-[4-(3-pyridyl)phenyl]pyrimidine (abbreviation: 2,4NP-6PyPPm), 4-[3,5-bis(9H-carbazol-9-yl)phenyl]-2-phenyl-6-(1,1′-biphenyl-4-yl)pyrimidine (abbreviation: 6BP-4Cz2PPm), or 7-[4-(9-phenyl-9H-carbazol-2-yl) quinazolin-2-yl]-7H-dibenzo[c,g]carbazole (abbreviation: PC-cgDBCzQz); and an organic compound having a heteroaromatic ring having a triazine skeleton, such as 2-[(1,1′-biphenyl)-4-yl]-4-phenyl-6-[9,9′-spirobi (9H-fluoren)-2-yl]-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]]naphtho[1,2-d]furan-6-yl)phenyl]phenyl}-4,6-diphenyl-1,3,5-triazine (abbreviation: mBnfBPTzn-02), 9-[4-(4,6-diphenyl-1,3,5-triazin-2-yl)phenyl]-9′-phenyl-3,3′-bi-9H-carbazole (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 2-[3′-(9,9-dimethyl-9H-fluoren-2-yl)-1,1′-biphenyl-3-yl]-4,6-diphenyl-1,3,5-triazine (abbreviation: mFBPTzn), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-{3-[3-(dibenzothiophen-4-yl)phenyl]phenyl}-4,6-diphenyl-1,3,5-triazine (abbreviation: mDBtBPTzn), 2,4,6-tris(3′-(pyridin-3-yl) biphenyl-3-yl)-1,3,5-triazine (abbreviation: TmPPPyTz), 2-[3-(2,6-dimethyl-3-pyridinyl)-5-(9-phenanthrenyl)phenyl]-4,6-diphenyl-1,3,5-triazine (abbreviation: mPn-mDMePyPTzn), 11-(4-[1,1′-biphenyl]-4-yl-6-phenyl-1,3,5-triazin-2-yl)-11,12-dihydro-12-phenyl-indolo[2,3-a]carbazole (abbreviation: BP-Icz(II)Tzn), 2-[3′-(triphenylen-2-yl)-1,1′-biphenyl-3-yl]-4,6-diphenyl′1,3,5-triazine (abbreviation: mTpBPTzn), 3-[9-(4,6-diphenyl-1,3,5-triazin-2-yl)-2-dibenzofuranyl]-9-phenyl-9H-carbazole (abbreviation: PCDBfTzn), or 2-[1,1′-biphenyl]-3-yl-4-phenyl-6-(8-[1,1′:4′,1″-terphenyl]-4-yl-1-dibenzofuranyl)-1,3,5-triazine (abbreviation: mBP-TPDBfTzn). Among the above materials, the organic compound having a heteroaromatic ring having a diazine skeleton, the organic compound having a heteroaromatic ring having a pyridine skeleton, and the organic compound having a heteroaromatic ring having a triazine skeleton have high reliability and thus are preferable. In particular, the organic compound having a heteroaromatic ring having a diazine (pyrimidine or pyrazine) skeleton and the organic compound having a heteroaromatic ring having a triazine skeleton have a high electron-transport property to contribute to a reduction in driving voltage.

As the TADF material that can be used as the host material, the above materials mentioned as the TADF material can also be used. When the TADF material is used as the host material, triplet excitation energy generated in the TADF material is converted into singlet excitation energy by reverse intersystem crossing and transferred to the light-emitting substance, whereby the emission efficiency of the light-emitting device can be increased. Here, the TADF material functions as an energy donor, and the light-emitting substance functions as an energy acceptor.

This is very effective in the case where the light-emitting substance is a fluorescent substance. In that case, the S1 level of the TADF material is preferably higher than the S1 level of the fluorescent substance in order that high emission efficiency be achieved. Furthermore, the T1 level of the TADF material is preferably higher than the S1 level of the fluorescent substance. Therefore, the T1 level of the TADF material is preferably higher than the T1 level of the fluorescent substance.

It is also preferable to use a TADF material that emits light whose wavelength overlaps with the wavelength on a lowest-energy-side absorption band of the fluorescent substance. This enables smooth transfer of excitation energy from the TADF material to the fluorescent substance and accordingly enables efficient light emission, which is preferable.

In addition, in order to efficiently generate singlet excitation energy from the triplet excitation energy by reverse intersystem crossing, carrier recombination preferably occurs in the TADF material. It is also preferable that the triplet excitation energy generated in the TADF material not be transferred to the triplet excitation energy of the fluorescent substance. For that reason, the fluorescent substance preferably has a protecting group around a luminophore (a skeleton which causes light emission) of the fluorescent substance. As the protecting group, a substituent having no π bond and a saturated hydrocarbon are preferably used. Specific examples include an alkyl group having 3 to 10 carbon atoms, a substituted or unsubstituted cycloalkyl group having 3 to 10 carbon atoms, and a trialkylsilyl group having 3 to 10 carbon atoms. It is further preferable that the fluorescent substance have a plurality of protecting groups. The substituents having no a bond are poor in carrier-transport performance; therefore, the TADF material and the luminophore of the fluorescent substance can be made away from each other with little influence on carrier-transportation or carrier recombination. Here, the luminophore refers to an atomic group (skeleton) that causes light emission in a fluorescent substance. The luminophore is preferably a skeleton having a π bond, further preferably includes an aromatic ring, and still further preferably includes a condensed aromatic ring or a condensed heteroaromatic ring. Examples of the condensed aromatic ring or the condensed heteroaromatic ring include a phenanthrene skeleton, a stilbene skeleton, an acridone skeleton, a phenoxazine skeleton, and a phenothiazine skeleton. Specifically, a fluorescent substance having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferable because of its high fluorescence quantum yield.

In the case where a fluorescent substance is used as the light-emitting substance, a material having an anthracene skeleton is suitably used as the host material. The use of a substance having an anthracene skeleton as the host material for the fluorescent substance makes it possible to obtain a light-emitting layer with high emission efficiency and high durability. As the substance having an anthracene skeleton that is used as the host material, a substance having a diphenylanthracene skeleton, in particular, a substance having a 9,10-diphenylanthracene skeleton, is chemically stable and thus is preferably used. The host material preferably has a carbazole skeleton because the hole-injection and hole-transport properties are improved; further preferably, the host material has a benzocarbazole skeleton in which a benzene ring is further condensed to carbazole because the HOMO level thereof is shallower than that of carbazole by approximately 0.1 eV and thus holes enter the host material easily. In particular, the host material preferably has a dibenzocarbazole skeleton because the HOMO level thereof is shallower than that of carbazole by approximately 0.1 eV so that holes enter the host material easily, the hole-transport property is improved, and the heat resistance is increased. Accordingly, a substance that has both a 9,10-diphenylanthracene skeleton and a carbazole skeleton (or a benzocarbazole skeleton or a dibenzocarbazole skeleton) is further preferable as the host material. Note that in terms of the hole-injection and hole-transport properties described above, instead of a carbazole skeleton, a benzofluorene skeleton or a dibenzofluorene skeleton may be used. Examples of such a substance include 9-phenyl-3-[4-(10-phenyl-9-anthryl)phenyl]-9H-carbazole (abbreviation: PCzPA), 3-[4-(1-naphthyl)phenyl]-9-phenyl-9H-carbazole (abbreviation: PCPN), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]benzo[b]naphtho[1,2-d]furan (abbreviation: 2mBnfPPA), 9-phenyl-10-[4-(9-phenyl-9H-fluoren-9-yl) biphenyl-4′-yl]anthracene (abbreviation: FLPPA), 9-(1-naphthyl)-10-[4-(2-naphthyl)phenyl]anthracene (abbreviation: αN-βNPAnth), 9-(1-naphthyl)-10-(2-naphthyl) anthracene (abbreviation: α,βADN), 2-(10-phenylanthracen-9-yl)dibenzofuran, 2-(10-phenyl-9-anthracenyl)benzo[b]naphtho[2,3-d]furan (abbreviation: Bnf(II)PhA), 9-(2-naphthyl)-10-[3-(2-naphthyl)phenyl]anthracene (abbreviation: βN-mβNPAnth), and 1-[4-(10-[1,1′-biphenyl]-4-yl-9-anthracenyl)phenyl]-2-ethyl-1H-benzimidazole (abbreviation: EtBImPBPhA). In particular, CzPA, cgDBCzPA, 2mBnfPPA, and PCzPA exhibit excellent properties and thus are preferably selected.

The host material may be a mixture of a plurality of kinds of substances; in the case of using a mixed host material, it is preferable to mix a material having an electron-transport property with a material having a hole-transport property. By mixing the material having an electron-transport property with the material having a hole-transport property, the transport property of the light-emitting layer 113 can be easily adjusted and a recombination region can be easily controlled. The weight ratio of the content of the material having a hole-transport property to the content of the material having an electron-transport property may be 1:19 to 19:1.

Note that a phosphorescent substance can be used as part of the mixed material. When a fluorescent substance is used as the light-emitting substance, a phosphorescent substance can be used as an energy donor for supplying excitation energy to the fluorescent substance.

An exciplex may be formed of these mixed materials. These mixed materials are preferably selected so as to form an exciplex that exhibits light emission overlapping with the wavelength of a lowest-energy-side absorption band of the light-emitting substance, in which case energy can be transferred smoothly and light emission can be obtained efficiently. The use of such a structure is preferable because the driving voltage can also be reduced.

Note that at least one of the materials forming an exciplex may be a phosphorescent substance. In this case, triplet excitation energy can be efficiently converted into singlet excitation energy by reverse intersystem crossing.

Combination of a material having an electron-transport property and a material having a hole-transport property whose HOMO level is higher than or equal to that of the material having an electron-transport property is preferable for forming an exciplex efficiently. In addition, the LUMO level of the material having a hole-transport property is preferably higher than or equal to the LUMO level of the material having an electron-transport property. Note that the LUMO levels and the HOMO levels of the materials can be derived from the electrochemical characteristics (the reduction potentials and the oxidation potentials) of the materials that are measured by cyclic voltammetry (CV).

The formation of an exciplex can be confirmed by a phenomenon in which the emission spectrum of a mixed film in which the hole-transport material and the electron-transport material are mixed is shifted to a longer wavelength than the emission spectrum of each of the materials (or has another peak on the longer wavelength side) observed in comparison of the emission spectrum of the hole-transport material, the emission spectrum of the electron-transport material, and the emission spectrum of the mixed film of these materials, for example. Alternatively, the formation of an exciplex can be confirmed by a difference in transient response, such as a phenomenon in which the transient photoluminescence (PL) lifetime of the mixed film has longer lifetime components or has a larger proportion of delayed components than the transient PL lifetime of each of the materials, observed in comparison of the transient PL of the hole-transport material, the transient PL of the electron-transport material, and the transient PL of the mixed film of these materials. The transient PL can be rephrased as transient electroluminescence (EL). That is, the formation of an exciplex can also be confirmed by a difference in transient response observed in comparison of the transient EL of the hole-transport material, the transient EL of the electron-transport material, and the transient EL of the mixed film of these materials.

The electron-transport layer 114 has the above-described structure. In the case where the above structure is not employed (e.g., the case of an electron-transport layer in a light-emitting unit on the anode side of a tandem device), the electron-transport layer 114 is formed as a layer containing a substance having an electron-transport property. The material having an electron-transport property is preferably a substance having an electron mobility higher than or equal to 1×10⁻⁷ cm²/Vs, further preferably higher than or equal to 1×10⁻⁶ cm²/Vs in the case where the square root of the electric field strength [V/cm] is 600. Note that any other substance can also be used as long as the substance has an electron-transport property higher than a hole-transport property. An organic compound having a π-electron deficient heteroaromatic ring is preferable as the above organic compound. The organic compound having a π-electron deficient heteroaromatic ring is preferably one or more of an organic compound having a heteroaromatic ring having a polyazole skeleton, an organic compound having a heteroaromatic ring having a pyridine skeleton, an organic compound having a heteroaromatic ring having a diazine skeleton, and an organic compound having a heteroaromatic ring having a triazine skeleton.

As the organic compound having an electron-transport property that can be used in the electron-transport layer 114, the organic compound that can be used as the organic compound having an electron-transport property in the light-emitting layer 113 can be similarly used. Among the above materials, the organic compound having a heteroaromatic ring having a diazine skeleton, the organic compound having a heteroaromatic ring having a pyridine skeleton, and the organic compound having a heteroaromatic ring having a triazine skeleton have high reliability and thus are preferable. In particular, the organic compound having a heteroaromatic ring having a diazine (pyrimidine or pyrazine) skeleton and the organic compound having a heteroaromatic ring having a triazine skeleton have a high electron-transport property to contribute to a reduction in driving voltage. In particular, organic compounds having a phenanthroline skeleton, such as mTpPPhen, PnNPhen, and mPPhen2P, are preferred, and an organic compound having a phenanthroline dimeric structure, such as mPPhen2P, is further preferred because of its excellent stability.

Note that the electron-transport layer 114 may have a stacked-layer structure. A layer that is included in the stacked-layer structure of the electron-transport layer 114 and that is in contact with the light-emitting layer 113 may function as a hole-blocking layer. In the case where the electron-transport layer in contact with the light-emitting layer functions as a hole-blocking layer, the electron-transport layer is preferably formed using a material having a deeper HOMO level than a material included in the light-emitting layer 113 by greater than or equal to 0.5 eV.

A layer that contains an alkali metal, an alkaline earth metal, or a compound thereof such as lithium fluoride (LiF), cesium fluoride (CsF), calcium fluoride (CaF₂), or8-(quinolinolato) lithium (abbreviation: Liq), a layer that contains 1,1′-pyridine-2,6-diyl-bis(1,3,4,6,7,8-hexahydro-2H-pyrimido[1,2-a]pyrimidine) (abbreviation: hpp2Py), or the like may be provided as the electron-injection layer 115. An electrode or a layer that is formed using a substance having an electron-transport property and that contains an alkali metal, an alkaline earth metal, or a compound thereof may be used as the electron-injection layer 115. Examples of the electrode include a substance in which electrons are added at high concentration to calcium oxide-aluminum oxide.

Note that as the electron-injection layer 115, it is possible to use a layer containing a substance that has an electron-transport property (preferably an organic compound having a bipyridine skeleton) and includes a fluoride of the alkali metal or the alkaline earth metal at a concentration higher than or equal to that at which the electron-injection layer 115 becomes in a microcrystalline state (50 wt % or higher). Since the layer has a low refractive index, a light-emitting device having higher external quantum efficiency can be provided.

The electron-injection layer 115 may be formed using any of the above substances alone, or any of the above substances contained in a layer containing a substance having an electron-transport property.

Instead of the electron-injection layer 115, a charge-generation layer 116 may be provided (FIG. 3B). The charge-generation layer 116 refers to a layer capable of injecting holes into a layer in contact with the cathode side of the charge-generation layer and electrons into a layer in contact with the anode side thereof when a potential is applied. The charge-generation layer 116 includes at least a P-type layer 117. The P-type layer 117 is preferably formed using any of the composite materials given above as the materials that can be used for the hole-injection layer 111. The P-type layer 117 may be formed by stacking a film including the above-described acceptor material as a material included in the composite material and a film including a hole-transport material. When a potential is applied to the P-type layer 117, electrons are injected into the electron-transport layer 114 and holes are injected into the cathode; thus, the light-emitting device operates.

Note that the charge-generation layer 116 preferably includes one or both of an electron-relay layer 118 and an N-type layer 119 in addition to the P-type layer 117.

The electron-relay layer 118 at least contains a substance having an electron-transport property and has a function of preventing an interaction between the N-type layer 119 and the P-type layer 117 and smoothly transferring electrons. The LUMO level of the substance having an electron-transport property contained in the electron-relay layer 118 is preferably between the LUMO level of the acceptor substance in the P-type layer 117 and the LUMO level of a substance contained in a layer of the electron-transport layer 114 that is in contact with the charge-generation layer 116. As a specific value of the energy level, the LUMO level of the substance having an electron-transport property used in the electron-relay layer 118 is preferably higher than or equal to −5.0 eV, further preferably higher than or equal to −5.0 eV and lower than or equal to −3.0 eV. Note that as the substance having an electron-transport property used in the electron-relay layer 118, a phthalocyanine-based material or a metal complex having a metal-oxygen bond and an aromatic ligand is preferably used.

The N-type layer 119 can be formed using a substance having a high electron-injection property, e.g., an alkali metal, an alkaline earth metal, a rare earth metal, or a compound thereof (an alkali metal compound (including an oxide such as lithium oxide, a halide, and a carbonate such as lithium carbonate or cesium carbonate), an alkaline earth metal compound (including an oxide, a halide, and a carbonate), or a rare earth metal compound (including an oxide, a halide, and a carbonate)).

In the case where the N-type layer 119 is formed so as to contain the substance having an electron-transport property and a donor substance, an organic compound such as tetrathianaphthacene (abbreviation: TTN), nickelocene, or decamethylnickelocene can be used as the donor substance, as well as an alkali metal, an alkaline earth metal, a rare earth metal, a compound thereof (an alkali metal compound (including an oxide such as lithium oxide, a halide, and a carbonate such as lithium carbonate or cesium carbonate), an alkaline earth metal compound (including an oxide, a halide, and a carbonate), or a rare earth metal compound (including an oxide, a halide, and a carbonate)). Note that as the substance having an electron-transport property, a material similar to the above-described material forming the electron-transport layer 114 can be used for the formation.

The second electrode 102 includes a cathode. The second electrode 102 may have a stacked-layer structure where the layer in contact with the EL layer 103 functions as the cathode. As a substance of the cathode, any of metals, alloys, and electrically conductive compounds with a low work function (specifically, lower than or equal to 3.8 eV), mixtures thereof, and the like can be used. Specific examples of such a cathode material include elements belonging to Group 1 or 2 of the periodic table, such as alkali metals (e.g., lithium (Li) and cesium (Cs)), magnesium (Mg), calcium (Ca), and strontium (Sr), alloys containing these elements (e.g., MgAg and AlLi), compounds containing these elements (e.g., lithium fluoride (LiF), cesium fluoride (CsF), and calcium fluoride (CaF₂)), rare earth metals such as europium (Eu) and ytterbium (Yb), and alloys containing these rare earth metals. However, when the electron-injection layer 115 or a thin film including any of the above materials with a low work function is provided between the second electrode 102 and the electron-transport layer, a variety of conductive materials such as Al, Ag, ITO, and indium oxide-tin oxide containing silicon or silicon oxide can be used for the cathode regardless of the work function.

When the second electrode 102 is formed using a material that transmits visible light, the light-emitting device can emit light from the second electrode 102 side.

Films of these conductive materials can be formed by a dry process such as a vacuum evaporation method or a sputtering method, an ink-jet method, a spin coating method, or the like. Alternatively, a wet process using a sol-gel method or a wet process using a paste of a metal material may be employed.

Any of a variety of methods can be used for forming the EL layer 103, regardless of whether it is a dry process or a wet process. For example, a vacuum evaporation method, a gravure printing method, an offset printing method, a screen printing method, an ink-jet method, a spin coating method, or the like may be used.

Different film formation methods may be used to form the electrodes or the layers described above.

Next, an embodiment of a light-emitting device with a structure where a plurality of light-emitting units are stacked (also referred to as a stacked-type device or a tandem device) will be described with reference to FIG. 3C. This organic EL element is a light-emitting device includes a plurality of light-emitting units between an anode and a cathode. One light-emitting unit has substantially the same structure as the EL layer 103 illustrated in FIG. 3A. In other words, the organic EL element illustrated in FIG. 3C includes a plurality of light-emitting units, and the organic EL elements illustrated in FIGS. 3A and 3B each include a single light-emitting unit.

In FIG. 3C, a first light-emitting unit 511 and a second light-emitting unit 512 are stacked between a first electrode 501 and a second electrode 502, and a charge-generation layer 513 is provided between the first light-emitting unit 511 and the second light-emitting unit 512. The first electrode 501 and the second electrode 502 correspond, respectively, to the first electrode 101 and the second electrode 102 illustrated in FIG. 3A, and the materials given in the description for FIG. 3A can be used. Furthermore, the first light-emitting unit 511 and the second light-emitting unit 512 may have the same structure or different structures.

The charge-generation layer 513 has a function of injecting electrons into one of the light-emitting units and injecting holes into the other light-emitting unit when a voltage is applied to the first electrode 501 and the second electrode 502. That is, in FIG. 3C, any layer can be used as the charge-generation layer 513 as long as the layer injects electrons into the first light-emitting unit 511 and injects holes into the second light-emitting unit 512 in the case where a voltage is applied such that the potential of the anode is higher than the potential of the cathode.

The charge-generation layer 513 is preferably formed with a structure similar to that of the charge-generation layer 116 described with reference to FIG. 3B. A composite material of an organic compound and a metal oxide used in the P-type layer has an excellent carrier-injection property and an excellent carrier-transport property; thus, low-voltage driving and low-current driving can be achieved. Note that in the case where the anode-side surface of a light-emitting unit is in contact with the charge-generation layer 513, the charge-generation layer 513 can also serve as a hole-injection layer of the light-emitting unit; therefore, a hole-injection layer is not necessarily provided in the light-emitting unit.

The charge-generation layer 513 preferably includes the N-type layer 119. In the case where the N-type layer 119 is formed in the intermediate layer, the N-type layer 119 functions as the electron-injection layer in the light-emitting unit on the anode side; thus, an electron-injection layer is not necessarily formed in the light-emitting unit on the anode side (here, the first light-emitting unit 511).

The light-emitting device having two light-emitting units is described with reference to FIG. 3C; however, the same can also be applied to a light-emitting device in which three or more light-emitting units are stacked. With a plurality of light-emitting units partitioned by the charge-generation layer 513 between a pair of electrodes as in the light-emitting device of this embodiment, it is possible to provide a long-life device that can emit light with high luminance at a low current density. A light-emitting apparatus that can be driven at a low voltage and has low power consumption can be achieved.

When the emission colors of the light-emitting units are different, light emission of a desired color can be obtained from the light-emitting device as a whole. For example, in a light-emitting device having two light-emitting units, the emission colors of the first light-emitting unit may be red and green and the emission color of the second light-emitting unit may be blue, so that the light-emitting device can emit white light as the whole.

The EL layer 103, the first light-emitting unit 511, the second light-emitting unit 512, and the layers such as the charge-generation layer, and the electrodes that are described above can be formed by a method such as an evaporation method (including a vacuum evaporation method), a droplet discharge method (also referred to as an ink-jet method), a coating method, or a gravure printing method, for example. A low molecular material, a middle molecular material (including an oligomer and a dendrimer), or a high molecular material may be included in the layers or electrodes.

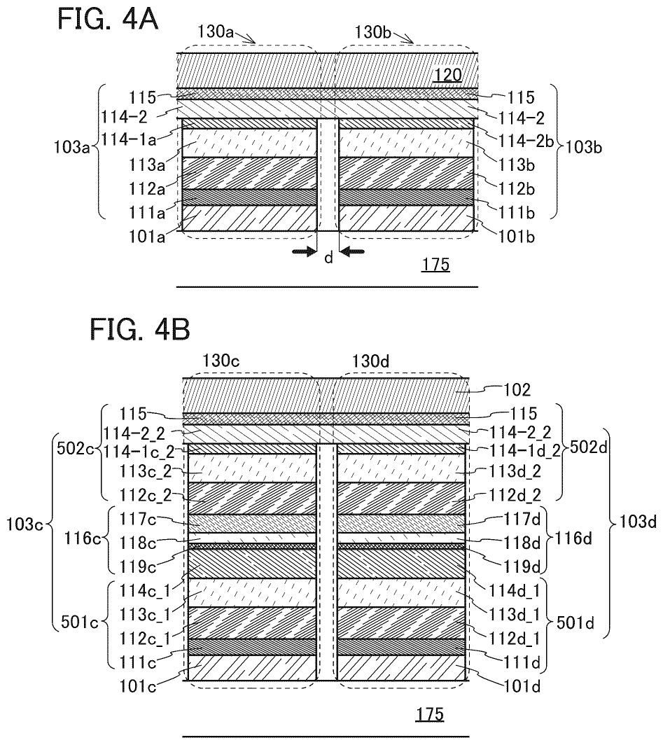

FIG. 4A illustrates two adjacent light-emitting devices (a light-emitting device 130a and a light-emitting device 130b) included in the light-emitting apparatus of one embodiment of the present invention.

The light-emitting device 130a includes an EL layer 103a between a first electrode 101a and the second electrode 102 that is an opposite electrode, over an insulating layer 175. The illustrated EL layer 103a includes a hole-injection layer 111a, a hole-transport layer 112a, a light-emitting layer 113a, a first electron-transport layer 114-1a, the second electron-transport layer 114-2, and the electron-injection layer 115, but may have a different stacked-layer structure. Note that the hole-injection layer 111a, the hole-transport layer 112a, the light-emitting layer 113a, and the first electron-transport layer 114-la correspond to the first layer, and the second electron-transport layer 114-2 and the electron-injection layer 115 correspond to the second layer.

The light-emitting device 130b includes an EL layer 103b between a first electrode 101b and the second electrode 102 that is an opposite electrode, over the insulating layer 175. The illustrated EL layer 103b includes a hole-injection layer 111b, a hole-transport layer 112b, a light-emitting layer 113b, a first electron-transport layer 114-1b, the second electron-transport layer 114-2, and the electron-injection layer 115, but may have a different stacked-layer structure. Note that the hole-injection layer 111b, the hole-transport layer 112b, the light-emitting layer 113b, and the first electron-transport layer 114-1b correspond to the first layer, and the second electron-transport layer 114-2 and the electron-injection layer 115 correspond to the second layer.

The second layer (second electron-transport layer 114-2 and the electron-injection layer 115) and the second electrode 102 are each preferably one layer shared by the light-emitting device 130a and the light-emitting device 130b. The first layers in the light-emitting devices are independent of each other because they are processed by a photolithography method after the formation of the first electron-transport layer 114-1a and the first electron-transport layer 114-1b. Since edges (contours) of the first layer are processed by a photolithography method, the edges are substantially aligned in the direction perpendicular to the substrate surface.

Due to the processing by a photolithography method, a space d exists between the first layer of the light-emitting device 130a and the first layer of the light-emitting device 130b. Since the organic compound layers are processed by a photolithography method, the space d between the first electrode 101a and the first electrode 101b can be smaller than that of the case where the light-emitting devices are formed through mask vapor deposition. The space d can be more than or equal to 2 μm and less than or equal to 5 μm.

FIG. 4B illustrates two adjacent tandem light-emitting devices (a light-emitting device 130c and a light-emitting device 130d) included in the display apparatus of one embodiment of the present invention.

The light-emitting device 130c includes an EL layer 103c between a first electrode 101c and the second electrode 102 over the insulating layer 175. The EL layer 103c has a structure in which a first light-emitting unit 501c and a second light-emitting unit 502c are stacked with a charge-generation layer 116c therebetween. Although two light-emitting units are stacked in the example illustrated in FIG. 4B, three or more light-emitting units may be stacked.

The first light-emitting unit 501c includes a hole-injection layer 111c, a first hole-transport layer 112c_1, a first light-emitting layer 113c_1, and an electron-transport layer 114c_1. The charge-generation layer 116c includes a P-type layer 117c, an electron-relay layer 118c, and an N-type layer 119c. The electron-relay layer 118c is not necessarily provided. The second light-emitting unit 502c includes a hole-transport layer 112c_2, a light-emitting layer 113c_2, a first electron-transport layer 114-1c_2, a second electron-transport layer 114-2_2, and the electron-injection layer 115.

The light-emitting device 130d includes an EL layer 103d between a first electrode 101d and the second electrode 102 over the insulating layer 175. The EL layer 103d has a structure in which a first light-emitting unit 501d and a second light-emitting unit 502d are stacked with a charge-generation layer 116d therebetween. Although two light-emitting units are stacked in the example illustrated in FIG. 4B, three or more light-emitting units may be stacked.

The first light-emitting unit 501d includes a hole-injection layer 111d, a first hole-transport layer 112d_1, a light-emitting layer 113d_1, and an electron-transport layer 114d_1. The charge-generation layer 116d includes a P-type layer 117d, an electron-relay layer 118d, and an N-type layer 119d. The electron-relay layer 118d is not necessarily provided. The second light-emitting unit 502d includes a hole-transport layer 112d_2, a light-emitting layer 113d_2, a first electron-transport layer 114-1d_2, a second electron-transport layer 114-2_2, and the electron-injection layer 115.

The second electron-transport layer 114-2_2, the electron-injection layer 115, and the second electrode 102 are preferably one layer shared by the light-emitting device 130c and the light-emitting device 130d. The first light-emitting unit 501c, the charge-generation layer 116c, the hole-transport layer 112c_2, the light-emitting layer 113c_2, and the first electron-transport layer 114-1c_2 correspond to a first layer in the light-emitting device 130c; the first light-emitting unit 501d, the charge-generation layer 116d, the hole-transport layer 112d_2, the light-emitting layer 113d_2, and the first electron-transport layer 114-1d_2 correspond to a first layer in the light-emitting device 130d; and the second electron-transport layer 114-2_2 and the electron-injection layer 115 correspond to a second layer.

The first layers are independent of each other because they are processed by a photolithography method after formation of the first electron-transport layer 114-1c_2 and the first electron-transport layer 114-1d_2. Since edges (contours) of the first layer are processed by a photolithography method, the edges are substantially aligned in the direction perpendicular to the substrate surface.

Due to the processing by a photolithography method, the space d exists between the first layer of the light-emitting device 130c and the first layer of the light-emitting device 130d. Since the organic compound layers are processed by a photolithography method, the space d between the first electrode 101c and the first electrode 101d can be smaller than that of the case where the light-emitting devices are formed through mask vapor deposition. The space d can be more than or equal to 2 μm and less than or equal to 5 μm.

The second layers in the light-emitting device 130a to the light-emitting device 130d do not undergo air exposure that is a typical step included in the photolithography process, a heating step at high temperatures, or the like. Thus, without strict limitations due to the preference for the convenience in processing by a photolithography method, such as heat resistance or air exposure resistance to the air, it is possible to select a material that has favorable performance, characteristics, or both of them, such as a carrier-transport property, a carrier-injection property, a cost, and stable characteristics. As a result, with use of the light-emitting device of one embodiment of the present invention, a highly reliable and inexpensive light-emitting apparatus with high resolution can be provided.

### Embodiment 3

In this embodiment, a mode in which the light-emitting device of one embodiment of the present invention is used as a display element of a display apparatus will be described.

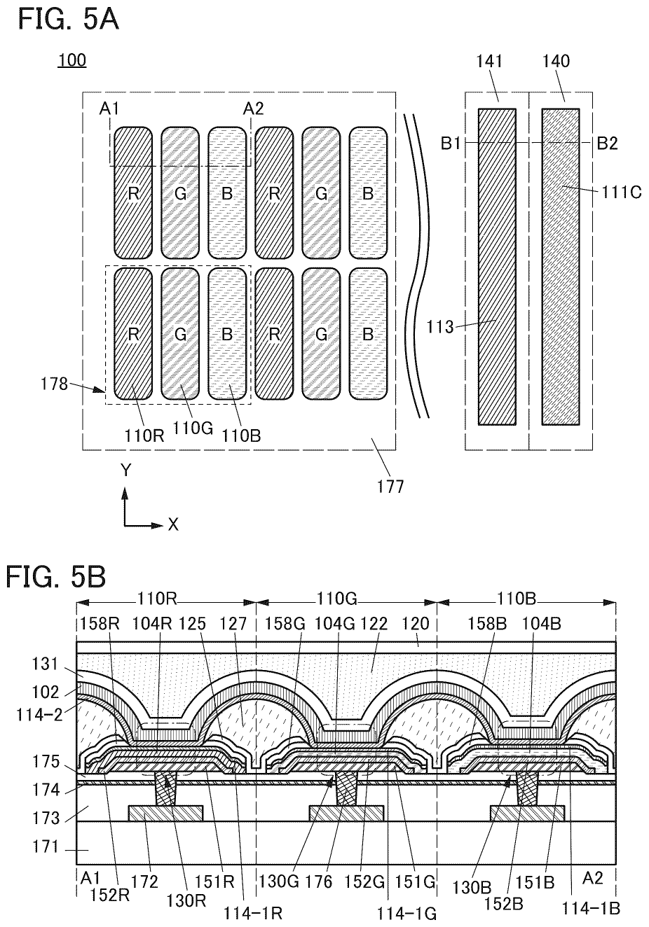

As illustrated in FIG. 5A and FIG. 5B, a plurality of the light-emitting devices 130 are formed over the insulating layer 175 to constitute a display apparatus.

The display apparatus includes a pixel portion 177 in which a plurality of pixels 178 are arranged in a matrix. The pixel 178 includes a subpixel 110R, a subpixel 110G, and a subpixel 110B.

In this specification and the like, for example, matters common to the subpixel 110R, the subpixel 110G, and the subpixel 110B are sometimes described using the collective term “subpixel 110”. In the same manner, in the description common to other components that are distinguished by alphabets, reference numerals without alphabets are sometimes used.

The subpixel 110R emits red light, the subpixel 110G emits green light, and the subpixel 110B emits blue light. Accordingly, an image can be displayed on the pixel portion 177. Note that in this embodiment, subpixels of three colors of red (R), green (G), and blue (B) are given as examples; however, subpixels of a different combination of colors may be employed. The number of subpixels is not limited to three, and four or more of subpixels may be used. Examples of four subpixels include subpixels of four colors of R, G, B, and white (W), subpixels of four colors of R, G, B, and Y, and four subpixels of R, G, B, and infrared light (IR).

In this specification and the like, the row direction is referred to as X direction and the column direction is referred to as Y direction in some cases. The X direction and the Y direction intersect with each other and are perpendicular to each other, for example.

Although FIG. 5A illustrates an example in which subpixels of different colors are arranged in the X direction and subpixels of the same color are arranged in the Y direction, there is no limitation on the arrangement of subpixels in one embodiment of the present invention.

Outside the pixel portion 177, a connection portion 140 is provided and a region 141 may also be provided. The region 141 is provided between the pixel portion 177 and the connection portion 140. A conductive layer 151C is provided in the connection portion 140.

Although FIG. 5 illustrates an example where the region 141 and the connection portion 140 are positioned on the right side of the pixel portion 177, the positions of the region 141 and the connection portion 140 are not particularly limited. The number of the regions 141 and the number of the connection portions 140 can each be one or more.

FIG. 5B is an example of a cross-sectional view taken along a dashed-dotted line A1-A2 in FIG. 5A. As illustrated in FIG. 5A, the display apparatus includes an insulating layer 171, a conductive layer 172 over the insulating layer 171, an insulating layer 173 over the insulating layer 171 and the conductive layer 172, an insulating layer 174 over the insulating layer 173, and the insulating layer 175 over the insulating layer 174. The insulating layer 171 is provided over a substrate (not illustrated). An opening reaching the conductive layer 172 is provided in the insulating layer 175, the insulating layer 174, and the insulating layer 173, and a plug 176 is provided so as to fill the opening.

In the pixel portion 177, the light-emitting device 130 is provided over the insulating layer 175 and the plug 176. A protective layer 131 is provided to cover the light-emitting device 130. A substrate 120 is attached to the protective layer 131 with a resin layer 122. In a region between adjacent light-emitting device 130, an inorganic insulating layer 125 and an insulating layer 127 over the inorganic insulating layer 125 are preferably provided.

Although FIG. 5B illustrates a plurality of cross sections of the inorganic insulating layer 125 and the insulating layer 127, it is preferable that the inorganic insulating layer 125 and the insulating layer 127 be each a continuous layer when the display apparatus is seen from above. In other words, the insulating layer 127 preferably has an opening over a first electrode.

In FIG. 5B, a light-emitting device 130R, a light-emitting device 130G, and a light-emitting device 130B are shown as the light-emitting device 130. The light-emitting device 130R, the light-emitting device 130G, and the light-emitting device 130B emit light of different colors. For example, the light-emitting device 130R can emit red light, the light-emitting device 130G can emit green light, and the light-emitting device 130B can emit blue light. The light-emitting device 130R, the light-emitting device 130G, or the light-emitting device 130B may emit visible light of another color or infrared light.

The display apparatus of one embodiment of the present invention is a top-emission display device where light is emitted in the direction opposite to a substrate over which the light-emitting devices are formed. Note that the display apparatus of one embodiment of the present invention may be of a bottom-emission type.

The light-emitting device 130R has a structure as described in Embodiment 1 or The light-emitting device 130R includes a first electrode (pixel electrode) Embodiment 2. including a conductive layer 151R and a conductive layer 152R, a first layer including a light-emitting layer 104R and a first electron-transport layer 114-1R, a second layer including the second electron-transport layer 114-2, and a second electrode (common electrode) 102 over the second layer. The second layer is preferably positioned closer to the second electrode (common electrode) 102 side than the first layer is, includes at least the second electron-transport layer 114-2, and may include an electron-injection layer. The first electron-transport layer 114-1R may function as a hole-blocking layer.

The light-emitting device 130G has a structure as described in Embodiment 1 or Embodiment 2. The light-emitting device 130G includes a first electrode (pixel electrode) including a conductive layer 151G and a conductive layer 152G, a first layer including a light-emitting layer 104G and a first electron-transport layer 114-1G, a second layer including the second electron-transport layer 114-2, and the second electrode (common electrode) 102 over the second layer. The second layer is preferably positioned closer to the second electrode (common electrode) 102 than the first layer is, includes at least the second electron-transport layer 114-2, and may include an electron-injection layer. The first electron-transport layer 114-1G may function as a hole-blocking layer.

The light-emitting device 130B has a structure as described in Embodiment 1 or Embodiment 2. The light-emitting device 130B includes a first electrode (pixel electrode) including a conductive layer 151B and a conductive layer 152B, a first layer including a light-emitting layer 104B and a first electron-transport layer 114-1B, a second layer including the second electron-transport layer 114-2, and the second electrode (common electrode) 102 over the second layer. The second layer is preferably positioned closer to the second electrode (common electrode) 102 than the first layer is, includes at least the second electron-transport layer 114-2, and may include an electron-injection layer. The first electron-transport layer 114-1B may function as a hole-blocking layer.

One of the pixel electrode (first electrode) and the common electrode (second electrode) of the light-emitting device functions as an anode, and the other thereof functions as a cathode. In this embodiment, description is made on the assumption that the pixel electrode functions as the anode and the common electrode functions as the cathode unless otherwise specified.

The first layers of the light-emitting devices are independent from each other or isolated to have an island shape for each color because a photolithography process is performed on the first electron-transport layer 114-1 that is the closest to the common electrode (second electrode) in the first layer. Note that the first layers in the light-emitting devices do not overlap with each other when processed by photolithography. Providing the island-shaped first layer in each of the light-emitting devices can inhibit leakage current between the adjacent light-emitting devices even in a high-resolution display device. This can prevent crosstalk, so that the display apparatus can achieve extremely high contrast. Specifically, a display apparatus having high current efficiency at low luminance can be obtained. Note that in one embodiment of the present invention, during the manufacture of the light-emitting device, a step involving air exposure is performed with blocking of light whose wavelength is less than 480 nm, i.e., irradiation with light whose wavelength is greater than or equal to 480 nm, and then heating is performed at a temperature higher than or equal to 80° C. and lower than 120° C. for one hour to three hours in a vacuum atmosphere (approx. 1×10⁻⁴ Pa). Thus, even when air exposure is performed on the first electron-transport layer 114-1, the light-emitting device can have favorable initial characteristics and high reliability.

The first layer is preferably provided to cover the top surface and the side surface of the first electrode (pixel electrode) of the light-emitting device 130. Such a structure can easily increase the aperture ratio of the display apparatus as compared with the structure in which an end portion of the first layer is positioned on the inner side of an end portion of the pixel electrode. Covering the side surface of the pixel electrode of the light-emitting device 130 with the first layer inhibits contact between the pixel electrode and the second electrode 102, thereby inhibiting a short circuit in the light-emitting device 130.

In the display apparatus of one embodiment of the present invention, the first electrode (pixel electrode) of the light-emitting device preferably has a stacked-layer structure. For example, in the example illustrated in FIG. 5B, the first electrode of the light-emitting device 130 has a stacked-layer structure including the conductive layer 151 provided on the substrate 171 side and the conductive layer 152 provided on the organic compound layer side.

A metal material can be used for the conductive layer 151, for example. Specifically, it is possible to use a metal such as aluminum (A1), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) and an alloy containing an appropriate combination of any of these metals, for example.

For the conductive layer 152, an oxide containing one or more selected from indium, tin, zinc, gallium, titanium, aluminum, and silicon can be used. For example, it is preferable to use a conductive oxide containing one or more of indium oxide, indium tin oxide, indium zinc oxide, zinc oxide, zinc oxide containing gallium, titanium oxide, indium zinc oxide containing gallium, indium zinc oxide containing aluminum, indium tin oxide containing silicon, indium zinc oxide containing silicon, and the like. In particular, indium tin oxide containing silicon can be suitably used for the conductive layer 152 because of having a high work function, for example, a work function higher than or equal to 4.0 eV.

The conductive layer 151 may have a stacked-layer structure of a plurality of layers containing different materials and the conductive layer 152 may have a stacked-layer structure of a plurality of layers containing different materials. In that case, the conductive layer 151 may include a layer formed using a material that can be used for the conductive layer 152, such as a conductive oxide. Furthermore, the conductive layer 152 may include a layer formed using a material that can be used for the conductive layer 151, such as a metal material. In the case where the conductive layer 151 has a stacked-layer structure of two or more layers, for example, a layer in contact with the conductive layer 152 can be formed using a material that can be used for the conductive layer 152.

The conductive layer 151 preferably has an end portion with a tapered shape. Specifically, the end portion of the conductive layer 151 preferably has a tapered shape with a taper angle of less than 90°. In that case, the conductive layer 152 provided along the side surface of the conductive layer 151 also has a tapered shape. When the side surface of the conductive layer 152 has a tapered shape, coverage with a layer 104 containing a light-emitting substance provided along the side surface of the conductive layer 152 can be improved.

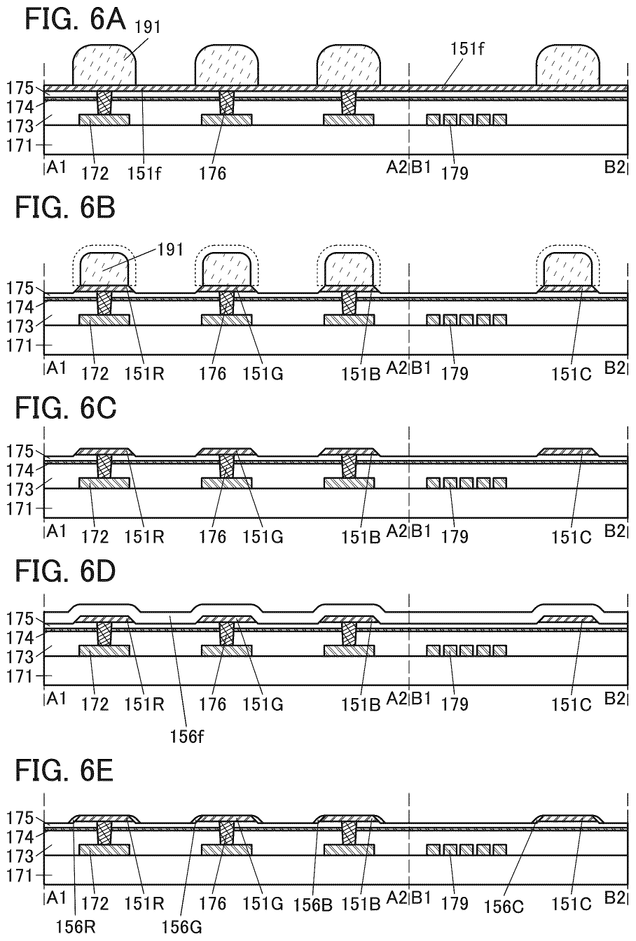

Next, a method for manufacturing the display apparatus having the structure illustrated in FIG. 5A is described with reference to FIG. 6 to FIG. 11.

### Manufacturing Method Example 1

Thin films included in the display apparatus (insulating films, semiconductor films, conductive films, and the like) can be formed by a sputtering method, a chemical vapor deposition (CVD) method, a vacuum evaporation method, a pulsed laser deposition (PLD) method, an ALD method, or the like.

The thin films included in the display apparatus (insulating films, semiconductor films, conductive films, and the like) can be formed by a wet film formation method such as spin coating, dipping, spray coating, inkjetting, dispensing, screen printing, offset printing, a doctor knife method, slit coating, roll coating, curtain coating, or knife coating.

Thin films that form the display apparatus can be processed by, for example, a photolithography method.

As light used for light exposure in a photolithography method, for example, an i-line (with a wavelength of 365 nm), a g-line (with a wavelength of 436 nm), an h-line (with a wavelength of 405 nm), or light in which these lines are mixed can be used. Besides, ultraviolet rays, KrF laser light, ArF laser light, or the like can be used. In addition, light exposure may be performed by liquid immersion exposure technique. As the light used for light exposure, extreme ultraviolet (EUV) light or X-rays may be used. Instead of the light used for light exposure, an electron beam can be used.

For etching of the thin films, a dry etching method, a wet etching method, a sandblasting method, or the like can be used.

First, the insulating layer 171 is formed over a substrate (not illustrated), as illustrated in FIG. 6A. Next, the conductive layer 172 and a conductive layer 179 are formed over the insulating layer 171, and the insulating layer 173 is formed over the insulating layer 171 so as to cover the conductive layer 172 and the conductive layer 179. Then, the insulating layer 174 is formed over the insulating layer 173, and the insulating layer 175 is formed over the insulating layer 174.

As the substrate, a substrate having at least heat resistance high enough to withstand heat treatment performed later can be used. For example, a glass substrate, a quartz substrate, a sapphire substrate, or a ceramic substrate; a single crystal semiconductor substrate or a polycrystalline semiconductor substrate including silicon, silicon carbide, or the like as a material; a compound semiconductor substrate of silicon germanium or the like; or a semiconductor substrate such as an SOI substrate can be used.

Next, openings reaching the conductive layer 172 are formed in the insulating layer 175, the insulating layer 174, and the insulating layer 173, as illustrated in FIG. 6A. Then, the plugs 176 are formed to fill the openings.

Next, a conductive film 151f to be the conductive layer 151R, the conductive layer 151G, the conductive layer 151B, and the conductive layer 151C later is formed over the plugs 176 and the insulating layer 175, as illustrated in FIG. 6A. A metal material can be used for the conductive film 151f, for example.

Next, as illustrated in FIG. 6A, a resist mask 191 is formed over the conductive film 151f. The resist mask 191 can be formed by application of a photosensitive material (photoresist), light exposure, and development.

Subsequently, as illustrated in FIG. 6B, the conductive film 151f in a region not overlapping with the resist mask 191 is removed, for example. Thus, the conductive layer 151 is formed.

Next, as illustrated in FIG. 6C, the resist mask 191 is removed. The resist mask 191 can be removed by ashing using oxygen plasma, for example.

Next, as illustrated in FIG. 6D, an insulating film 156f to be an insulating layer 156R, an insulating layer 156G, an insulating layer 156B, and an insulating layer 156C later is formed over the conductive layer 151R, the conductive layer 151G, the conductive layer 151B, the conductive layer 151C, and the insulating layer 175.

As the insulating film 156f, an inorganic insulating film such as an oxide insulating film, a nitride insulating film, an oxynitride insulating film, or a nitride oxide insulating film, e.g., a silicon oxynitride film, can be used, for example.

Subsequently, as illustrated in FIG. 6E, the insulating film 156f is processed to form the insulating layer 156R, the insulating layer 156G, the insulating layer 156B, and the insulating layer 156C.

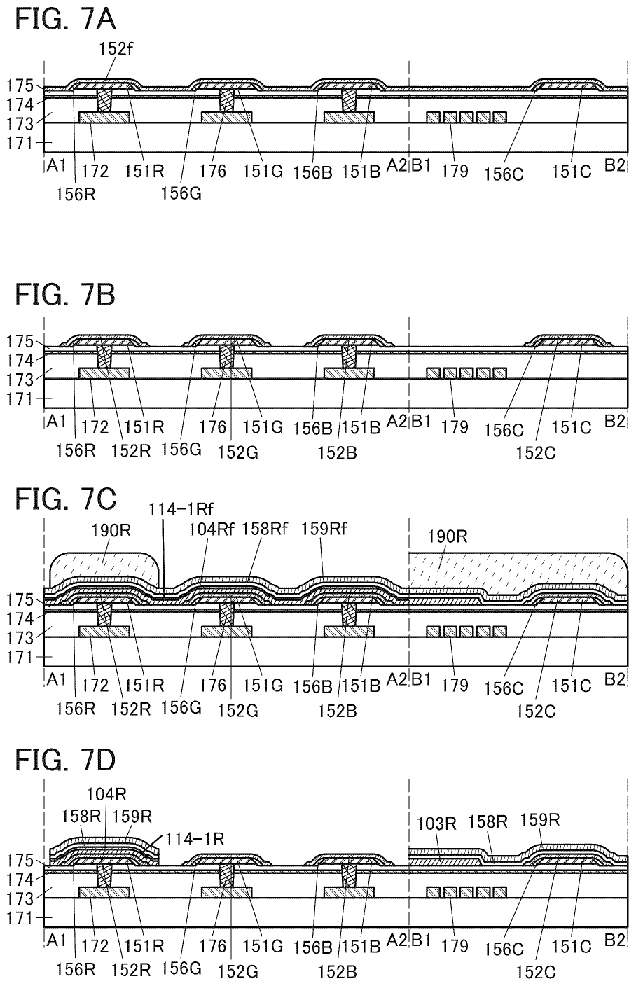

Then, as illustrated in FIG. 7A, a conductive film 152f is formed over the conductive layer 151R, the conductive layer 151G, the conductive layer 151B, the conductive layer 151C, the insulating layer 156R, the insulating layer 156G, the insulating layer 156B, the insulating layer 156C, and the insulating layer 175.

A conductive oxide can be used for the conductive film 152f, for example. The conductive film 152f may have a stacked-layer structure.

Then, as illustrated in FIG. 7B, the conductive film 152f is processed, so that the conductive layer 152R, the conductive layer 152G, the conductive layer 152B, and the conductive layer 152C are formed.

Next, as illustrated in FIG. 7C, a film 104Rf containing an organic compound and a film 114-1Rf containing an organic compound are formed over the conductive layer 152R, the conductive layer 152G, the conductive layer 152B, and the insulating layer 175. Note that as illustrated in FIG. 7C, the film 104Rf containing an organic compound and the film 114-1Rf containing an organic compound are not formed over the conductive layer 152C.

Then, as illustrated in FIG. 7C, a sacrificial film 158Rf and a mask film 159Rf are formed. The sacrificial film 158Rf provided over the film 114-1Rf containing an organic compound can reduce damage to the film 114-1Rf containing an organic compound in the manufacturing process of the display apparatus, increasing the reliability of the light-emitting device.

As the sacrificial film 158Rf, a film that is highly resistant to the processing conditions for the film 114-1Rf containing an organic compound, specifically, a film having high etching selectivity with the film 114-1Rf containing an organic compound is used. As the mask film 159Rf, a film having high etching selectivity with the sacrificial film 158Rf is used.

The sacrificial film 158Rf and the mask film 159Rf are formed at a temperature lower than the upper temperature limits of the film 104Rf containing an organic compound and the film 114-1Rf containing an organic compound. The typical substrate temperatures in formation of the sacrificial film 158Rf and the mask film 159Rf are each higher than or equal to 100° C. and lower than or equal to 200° C., preferably higher than or equal to 100° C. and lower than or equal to 150° C., further preferably higher than or equal to 100° C. and lower than or equal to 120° C. In the light-emitting device of one embodiment of the present invention, a material whose Tg is higher than or equal to 110° C. is used for the film 114-1Rf containing an organic compound.

As the sacrificial film 158Rf and the mask film 159Rf, it is preferable to use a film that can be removed by a wet etching method or a dry etching method.

Note that the sacrificial film 158Rf, which is formed over and in contact with the film 114-1Rf containing an organic compound, is preferably formed by a formation method that causes less damage to the film 114-1Rf containing an organic compound than a formation method for the mask film 159Rf. For example, the sacrificial film 158Rf is preferably formed by an atomic layer deposition (ALD) method or a vapor deposition method rather than a sputtering method.

As the sacrificial film 158Rf and the mask film 159Rf, it is possible to use one or more of a metal film, an alloy film, a metal oxide film, a semiconductor film, an organic insulating film, and an inorganic insulating film, for example.

For the sacrificial film 158Rf and the mask film 159Rf, it is possible to use a metal material such as gold, silver, platinum, magnesium, nickel, tungsten, chromium, molybdenum, iron, cobalt, copper, palladium, titanium, aluminum, yttrium, zirconium, or tantalum or an alloy material containing any of the metal materials, for example. It is particularly preferable to use a low-melting-point material such as aluminum or silver. The use of a metal material capable of blocking ultraviolet rays for one or both of the sacrificial film 158Rf and the mask film 159Rf is preferable, in which case the film 114-1Rf containing an organic compound can be inhibited from being irradiated with ultraviolet rays in exposure for patterning and deteriorating.

For each of the sacrificial film 158Rf and the mask film 159Rf, it is possible to use a metal oxide such as In—Ga—Zn oxide, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or indium tin oxide containing silicon.

Note that an element M (M is one or more of aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used instead of gallium as the described-above metal oxide.

The sacrificial film 158Rf and the mask film 159Rf are preferably formed using a semiconductor material such as silicon or germanium, for example, for excellent compatibility with a semiconductor manufacturing process. Alternatively, a compound containing the above semiconductor material can be used.

As each of the sacrificial film 158Rf and the mask film 159Rf, any of a variety of inorganic insulating films can be used. In particular, an oxide insulating film is preferable because its adhesion to the film 114-1Rf containing an organic compound is higher than that of a nitride insulating film.

Next, as illustrated in FIG. 7C, a resist mask 190R is formed. The resist mask 190R can be formed by application of a photosensitive material (photoresist), light exposure, and development.

The resist mask 190R is provided at a position overlapping with the conductive layer 152R. Note that the resist mask 190R is preferably provided also at a position overlapping with the conductive layer 152C. This can inhibit the conductive layer 152C from being damaged during the manufacturing process of the display apparatus.

Subsequently, as illustrated in FIG. 7D, part of the mask film 159Rf is removed using the resist mask 190R, whereby the mask layer 159R is formed. The mask layer 159R remains over the conductive layer 152R and over the conductive layer 152C. After that, the resist mask 190R is removed. Then, part of the sacrificial film 158Rf is removed using the mask layer 159R as a mask (also referred to as a hard mask), whereby the sacrificial layer 158R is formed.

Using a wet etching method can reduce damage to the film 104Rf containing an organic compound and the film 114-1Rf containing an organic compound in processing the sacrificial film 158Rf and the mask film 159Rf, as compared to the case of using a dry etching method. In the case of using a wet etching method, it is preferable to use a developer, an alkaline aqueous solution such as a tetramethylammonium hydroxide aqueous solution (TMAH), dilute hydrofluoric acid, oxalic acid, phosphoric acid, acetic acid, nitric acid, or an acid aqueous solution such as a chemical solution containing a mixed solution of any of these acids, for example.

In the case of using a dry etching method for processing the sacrificial film 158Rf, deteriorations of the film 104Rf containing an organic compound and the film 114-1Rf containing an organic compound can be inhibited by not using a gas containing oxygen as the etching gas.

The resist mask 190R can be removed by a method similar to that for the resist mask 191.

Next, as illustrated in FIG. 7D, the film 104Rf containing an organic compound and the film 114-1Rf containing an organic compound are processed to form a first layer R (the layer 104R including a light-emitting layer and the first electron-transport layer 114-1R). For example, part of the film 104Rf containing an organic compound and part of the film 114-1Rf containing an organic compound are removed using the mask layer 159R and the sacrificial layer 158R as a hard mask, so that the first layer R (the layer 104R including a light-emitting layer and the first electron-transport layer 114-1R) is formed. The first layer processed in this manner is separated from those in the other light-emitting devices.

Accordingly, as illustrated in FIG. 7D, a stacked-layer structure of the first layer R (the layer 104R including a light-emitting layer and the first electron-transport layer 114-1R), the sacrificial layer 158R, and the mask layer 159R remains over the conductive layer 152R. The conductive layer 152G and the conductive layer 152B are exposed.

The film 104Rf containing an organic compound and the film 114-1Rf containing an organic compound are preferably processed by anisotropic etching. In particular, anisotropic dry etching is preferable. Alternatively, wet etching may be used.

In the case of using a dry etching method, deteriorations of the film 104Rf containing an organic compound and the film 114-1Rf containing an organic compound can be inhibited by not using a gas containing oxygen as the etching gas.

A gas containing oxygen may be used as the etching gas. When the etching gas contains oxygen, the etching rate can be increased. Therefore the etching can be performed under a low-power condition while an adequately high etching rate is maintained. Thus, damage to the film 104Rf containing an organic compound and the film 114-1Rf containing an organic compound can be inhibited. Furthermore, a defect such as attachment of a reaction product generated at the etching can be inhibited.

In the case of using a dry etching method, it is preferable to use a gas containing at least one of H₂, CF₄, C₄F₈, SF₆, CHF₃, Cl₂, H₂O, BCl₃, and a Group 18 element such as He or Ar as the etching gas, for example. Alternatively, a gas containing oxygen and at least one kind of the above is preferably used as the etching gas. Alternatively, an oxygen gas may be used as the etching gas.

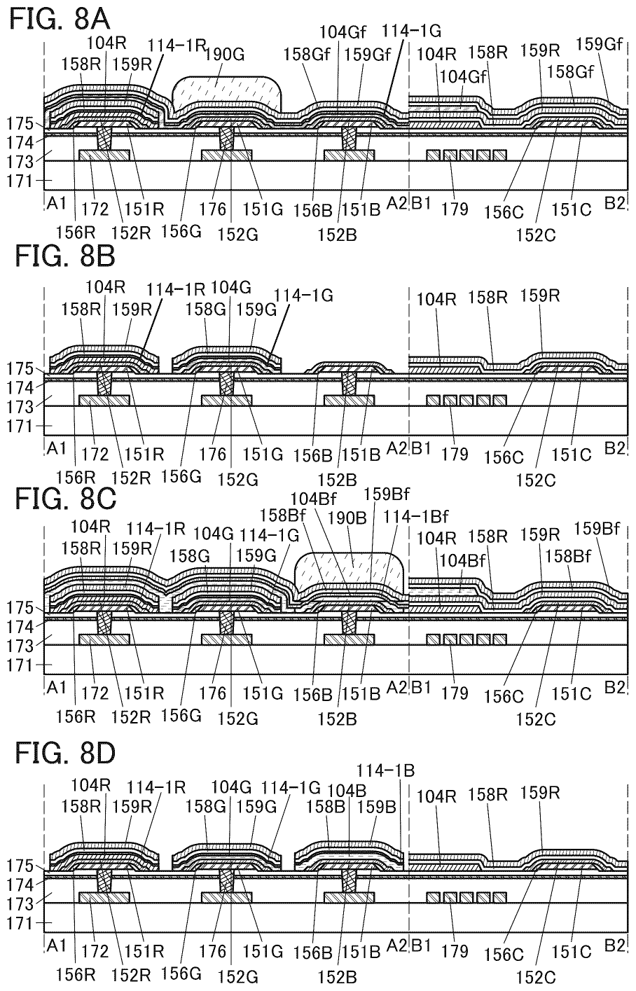

Next, as illustrated in FIG. 8A, a film 104Gf containing an organic compound and a film 114-1Gf containing an organic compound that are to be a first layer G (a layer 104G including a light-emitting layer and a first electron-transport layer 114-1G) are formed.

The film 104Gf containing an organic compound and the film 114-1Gf containing an organic compound can be formed by a method similar to that for forming the film 104Rf containing an organic compound and the film 114-1Rf containing an organic compound.

Subsequently, as illustrated in FIG. 8A, a sacrificial film 158Gf and a mask film 159Gf are formed in this order. After that, a resist mask 190G is formed. The materials and the formation methods of the sacrificial film 158Gf and the mask film 159Gf are similar to conditions applicable to the sacrificial film 158Rf and the mask film 159Rf. The materials and the formation method of the resist mask 190G are similar to conditions applicable to the resist mask 190R. The resist mask 190G is provided at a position overlapping with the conductive layer 152G.

Subsequently, as illustrated in FIG. 8B, part of the mask film 159Gf is removed using the resist mask 190G, whereby the mask layer 159G is formed. The mask layer 159G remains over the conductive layer 152G. After that, the resist mask 190G is removed. Then, part of the sacrificial film 158Gf is removed using the mask layer 159G as a mask, whereby the sacrificial layer 158G is formed. Next, the film 104Gf containing an organic compound and the film 114-1Gf containing an organic compound are processed to form the first layer G (the layer 104G including a light-emitting layer and the first electron-transport layer 114-1G).

Next, as illustrated in FIG. 8C, a film 104Bf containing an organic compound and a film 114-1Bf containing an organic compound are formed.

The film 104Bf containing an organic compound and the film 114-1Bf containing an organic compound can be formed by a method similar to that for forming the film 104Rf containing an organic compound and the film 114-1Rf containing an organic compound.

Subsequently, a sacrificial film 158Bf and a mask film 159Bf are formed in this order as illustrated in FIG. 8C. After that, a resist mask 190B is formed. The materials and the formation methods of the sacrificial film 158Bf and the mask film 159Bf are similar to conditions applicable to the sacrificial film 158Rf and the mask film 159Rf. The materials and the formation method of the resist mask 190B are similar to conditions applicable to the resist mask 190R.

The resist mask 190B is provided at a position overlapping with the conductive layer 152B.

Subsequently, as illustrated in FIG. 8D, part of the mask film 159Bf is removed using the resist mask 190B, whereby the mask layer 159B is formed. The mask layer 159B remains over the conductive layer 152B. After that, the resist mask 190B is removed. Then, part of the sacrificial film 158Bf is removed using the mask layer 159B as a mask, whereby the sacrificial layer 158B is formed. Next, the film 104Bf containing an organic compound and the film 114-1Bf containing an organic compound are processed to form a first layer B (a layer 104B including a light-emitting layer and a first electron-transport layer 114-1B). For example, part of the film 104Bf containing an organic compound and part of the film 114-1Bf containing an organic compound are removed using the mask layer 159B and the sacrificial layer 158B as a hard mask, so that the first layer B (the layer 104B including a light-emitting layer and the first electron-transport layer 114-1B) is formed.

Accordingly, as illustrated in FIG. 8D, a stacked-layer structure of the first layer B (the layer 104B including a light-emitting layer and the first electron-transport layer 114-1B), the sacrificial layer 158B, and the mask layer 159B remains over the conductive layer 152B. The mask layer 159R and the mask layer 159G are exposed.

Note that the side surfaces of the first layer R, the first layer G, and the first layer B are preferably perpendicular or substantially perpendicular to their formation surfaces. For example, the angle between the formation surfaces and these side surfaces is preferably greater than or equal to 60° and less than or equal to 90°.

The distance between two adjacent layers among the first layer R, the first layer G, and the first layer B, which are formed by a photolithography method as described above, can be shortened to less than or equal to 8 μm, less than or equal to 5 μm, less than or equal to 3 μm, less than or equal to 2 μm, or less than or equal to 1 μm. Here, the distance can be specified, for example, by the distance between facing end portions of two adjacent layers among the first layer R, the first layer G, and the first layer B. The distance between the island-shaped organic compound layers is shortened in this manner, whereby a display apparatus with high resolution and a high aperture ratio can be provided. In addition, the distance between the first electrodes of adjacent light-emitting devices can also be shortened to be, for example, less than or equal to 10 μm, less than or equal to 8 μm, less than or equal to 5 μm, less than or equal to 3 μm, or less than or equal to 2 μm. Note that the distance between the first electrodes of adjacent light-emitting devices is preferably greater than or equal to 2 μm and less than or equal to 5 μm.

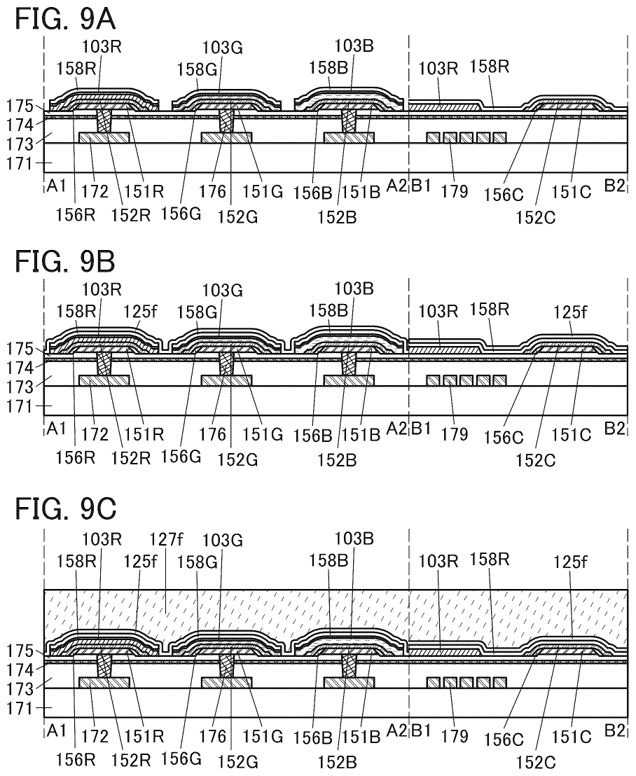

Next, the mask layer 159R, the mask layer 159G, and the mask layer 159B are preferably removed as illustrated in FIG. 9A.

The step of removing the mask layers can be performed by a method similar to that for the step of processing the mask layers. In particular, using a wet etching method can reduce damage to the first layers in removal of the mask layers, as compared to the case of using a dry etching method.

The mask layers may be removed by being dissolved in a polar solvent such as water or alcohol. Examples of alcohol include ethyl alcohol, methyl alcohol, isopropyl alcohol (IPA), and glycerin.

After the mask layers are removed, drying treatment may be performed to remove water adsorbed onto the surface. For example, heat treatment in an inert gas atmosphere or a reduced-pressure atmosphere can be performed. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 120° C. A reduced-pressure atmosphere is preferable because drying at a lower temperature is possible.

Next, an inorganic insulating film 125f is formed as illustrated in FIG. 9B.

Then, as illustrated in FIG. 9C, an insulating film 127f to be the insulating layer 127 later is formed over the inorganic insulating film 125f.

The substrate temperature at the time of forming the inorganic insulating film 125f and the insulating film 127f is preferably higher than or equal to 60° C., higher than or equal to 80° C., higher than or equal to 100° C., or higher than or equal to 120° C. and lower than or equal to 200° C., lower than or equal to 180° C., lower than or equal to 160° C., lower than or equal to 150° C., or lower than or equal to 140° C.

As the inorganic insulating film 125f, an insulating film is preferably formed within the above substrate temperature range to have a thickness greater than or equal to 3 nm, greater than or equal to 5 nm, or greater than or equal to 10 nm and less than or equal to 200 nm, less than or equal to 150 nm, less than or equal to 100 nm, or less than or equal to 50 nm.

The inorganic insulating film 125f is preferably formed by an ALD method, for example. The use of an ALD method is preferable, in which case damage by the deposition is reduced and a film with good coverage can be deposited. As the inorganic insulating film 125f, an aluminum oxide film is preferably formed by an ALD method, for example.

The insulating film 127f is preferably formed by the aforementioned wet film formation method. The insulating film 127f is preferably formed by spin coating using a photosensitive material, for example, and preferably formed using specifically a photosensitive resin composition containing an acrylic resin.

Then, part of the insulating film 127f is exposed to visible light or ultraviolet rays. The insulating layer 127 is formed in regions that are interposed between any two of the conductive layer 152R, the conductive layer 152G, and the conductive layer 152B and around the conductive layer 152C.

The width of the insulating layer 127 formed later can be controlled in accordance with the exposed region of the insulating film 127f. In this embodiment, processing is performed such that the insulating layer 127 includes a portion overlapping with the top surface of the conductive layer 151.

Light used for the exposure preferably includes the i-line (wavelength: 365 nm). The light used for light exposure may include at least one of the g-line (wavelength: 436 nm) and the h-line (wavelength: 405 nm).

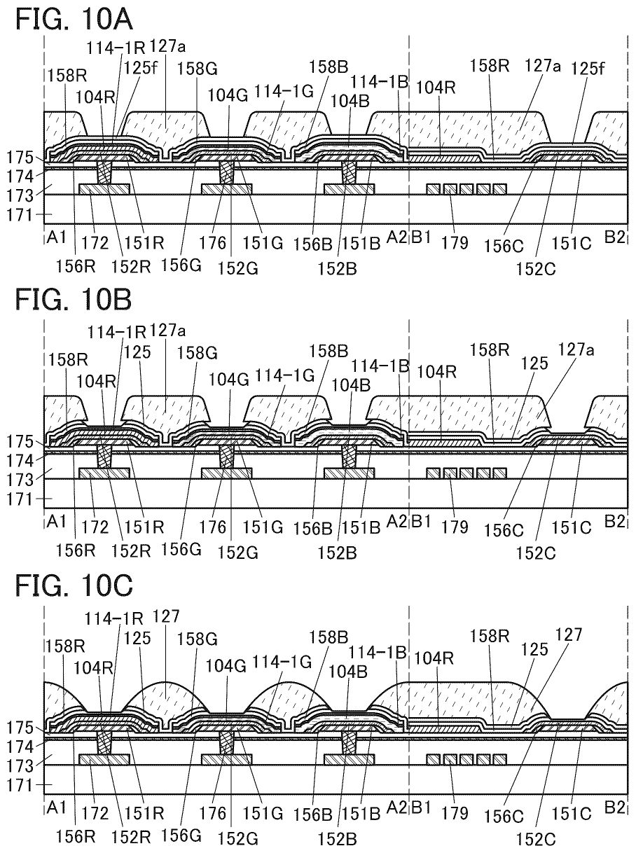

Next, as illustrated in FIG. 10A, development is performed to remove the exposed region of the insulating film 127f, so that an insulating layer 127a is formed.

Next, as illustrated in FIG. 10B, etching treatment is performed with the insulating layer 127a as a mask to remove part of the inorganic insulating film 125f and reduce the thickness of part of the sacrificial layer 158R, the sacrificial layer 158G, and the sacrificial layer 158B. Thus, the inorganic insulating layer 125 is formed under the insulating layer 127a. Moreover, the surfaces of the thin portions in the sacrificial layer 158R, the sacrificial layer 158G, and the sacrificial layer 158B are exposed. Note that the etching treatment using the insulating layer 127a as a mask may be hereinafter referred to as first etching treatment.

The first etching treatment can be performed by dry etching or wet etching. Note that the inorganic insulating film 125f is preferably formed using a material similar to that of the sacrificial layer 158R, the sacrificial layer 158G, and the sacrificial layer 158B, in which case the first etching treatment can be performed collectively.

In the case of performing dry etching, a chlorine-based gas is preferably used. As the chlorine-based gas, one of Cl₂, BCl₃, SiCl₄, CCl₄, and the like or a mixture of two or more of them can be used. Moreover, one of an oxygen gas, a hydrogen gas, a helium gas, an argon gas, and the like or a mixture of two or more of the gases can be added to the chlorine-based gas as appropriate. By the dry etching, the thin regions of the sacrificial layer 158R, the sacrificial layer 158G, and the sacrificial layer 158B can be formed with favorable in-plane uniformity.

As a dry etching apparatus, a dry etching apparatus including a high-density plasma source can be used. As the dry etching apparatus including a high-density plasma source, an inductively coupled plasma (ICP) etching apparatus can be used, for example. Alternatively, a capacitively coupled plasma (CCP) etching apparatus including parallel plate electrodes can be used.

The first etching treatment is preferably performed by wet etching. Employing a wet etching method can reduce damage to the first layer R, the first layer G, and the first layer B as compared with the case of employing a dry etching method. Wet etching can be performed using an alkaline solution, for example. For instance, TMAH, which is an alkaline solution, can be used for wet etching of an aluminum oxide film. Alternatively, an acid solution containing fluoride can also be used. In that case, paddle wet etching can be performed. Note that the inorganic insulating film 125f is preferably formed using a material similar to that of the sacrificial layer 158R, the sacrificial layer 158G, and the sacrificial layer 158B, in which case the etching treatment can be performed collectively.

In the first etching treatment, the etching treatment is stopped when the sacrificial layer 158R, the sacrificial layer 158G, and the sacrificial layer 158B are thinned before the sacrificial layers are completely removed. The corresponding parts of the sacrificial layer 158R, the sacrificial layer 158G, and the sacrificial layer 158B remain over the first layer R, the first layer G, and the first layer B in this manner, whereby the first layer R, the first layer G, and the first layer B can be prevented from being damaged by treatment in a later step.

Next, light exposure is preferably performed on the entire substrate so that the insulating layer 127a is irradiated with visible light or ultraviolet rays. The energy density for the light exposure is preferably greater than 0 mJ/cm² and less than or equal to 800 mJ/cm², further preferably greater than 0 mJ/cm² and less than or equal to 500 mJ/cm². Performing such light exposure after the development can sometimes increase the degree of transparency of the insulating layer 127a. In addition, it is sometimes possible to lower the substrate temperature required for subsequent heat treatment for changing the shape of the insulating layer 127a into a tapered shape.

Here, when a barrier insulating layer against oxygen (such as an aluminum oxide film) is provided as each of the sacrificial layer 158R, the sacrificial layer 158G, and the sacrificial layer 158B, diffusion of oxygen into the first layer R, the first layer G, and the first layer B can be inhibited.

Then, heat treatment (also referred to as post-baking) is performed. The heat treatment can change the insulating layer 127a into the insulating layer 127 with a tapered side surface (FIG. 10C). The heat treatment is performed at a temperature lower than the upper temperature limit of the organic compound layer. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 130° C. The heating atmosphere may be either an air atmosphere or an inert gas atmosphere. Alternatively, the heating atmosphere may be either an atmospheric pressure atmosphere or a reduced-pressure atmosphere. Accordingly, adhesion between the insulating layer 127 and the inorganic insulating layer 125 can be improved, and corrosion resistance of the insulating layer 127 can be increased.

When the sacrificial layer 158R, the sacrificial layer 158G, and the sacrificial layer 158B are not completely removed by the first etching treatment and the sacrificial layer 158R, the sacrificial layer 158G, and the sacrificial layer 158B with reduced thicknesses remain, the first layer R, the first layer G, and the first layer B can be prevented from being damaged and deteriorating in the heat treatment. Thus, the reliability of the light-emitting device can be increased.

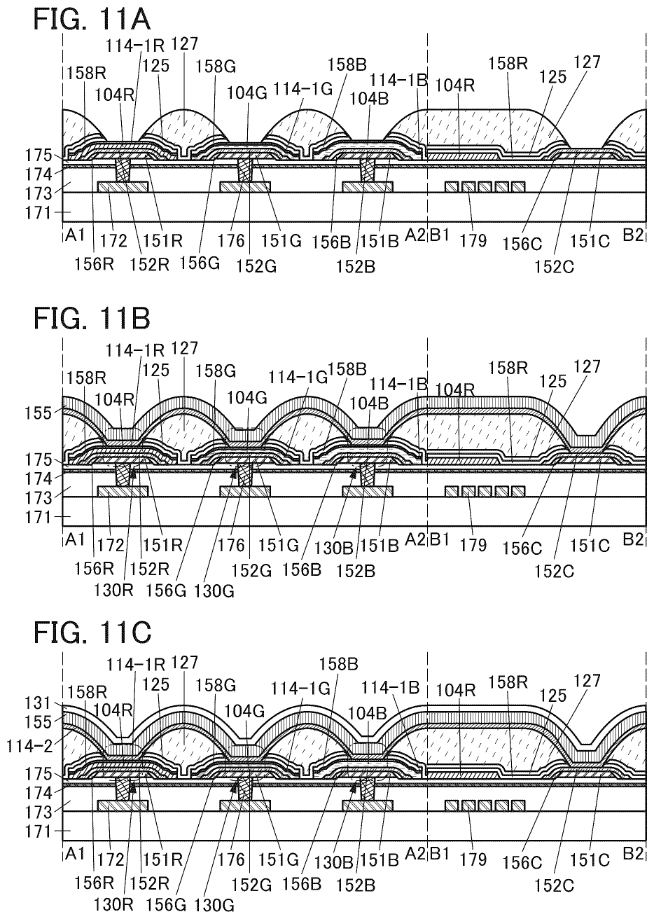

Next, as illustrated in FIG. 11A, etching treatment is performed with the insulating layer 127 as a mask to remove part of the sacrificial layer 158R, the sacrificial layer 158G, and the sacrificial layer 158B. Thus, openings are formed in the sacrificial layer 158R, the sacrificial layer 158G, and the sacrificial layer 158B, and the top surfaces of the first electron-transport layer 114-1R, the first electron-transport layer 114-1G, the first electron-transport layer 114-1B, and the conductive layer 152C are exposed. Note that this etching treatment may be hereinafter referred to as second etching treatment.

The end portion of the inorganic insulating layer 125 is covered with the insulating layer 127. FIG. 11A illustrate an example where part of the end portion of the sacrificial layer 158G (specifically, a tapered portion formed by the first etching treatment) is covered with the insulating layer 127 and the tapered portion formed by the second etching treatment is exposed.

The second etching treatment is performed by wet etching. Employing a wet etching method can reduce damage to the first layer R, the first layer G, and the first layer B as compared with the case of employing a dry etching method. Wet etching can be performed using an alkaline solution or an acidic solution, for example. An aqueous solution is preferably used in order that the first layer is not dissolved.

Heat treatment is performed in a vacuum atmosphere (approx. lower than or equal to 1×19⁻⁴ Pa) under a condition where the first electron-transport layer 114-1R, the first electron-transport layer 114-1G, and the first electron-transport layer 114-1B are exposed by the second etching treatment. The heat treatment may be performed at a temperature higher than or equal to 80° C. and lower than 120° C. for one hour to three hours. Thus, atmospheric components diffusing in the first layers due to the air exposure during the photolithography process, and the like, are removed.

Note that in one embodiment of the present invention, until the above heating step from the time just before the light-emitting devices are exposed to the air atmosphere, at least processing of the film 104Rf containing an organic compound and the film 114-1Rf containing an organic compound is performed in an environment where light whose wavelength is less than 480 nm is blocked (e.g., where yellow light is used for irradiation of light whose wavelength is greater than or equal to 480 nm). The atmospheric components diffusing in the film 104f containing an organic compound and the film 114-1f containing an organic compound, and the like cause the degradation of the light-emitting devices when being irradiated with light with a short wavelength less than 480 nm; however, in one embodiment of the present invention, irradiation of light with a short wavelength less than 480 nm is not performed. Thus, a light-emitting device having favorable initial characteristics and high reliability can be manufactured.

Next, as illustrated in FIG. 11B, the second layer (the second electron-transport layer 114-2) and a common electrode 155 are formed over the first layer R, the first layer G, and the first layer B, the conductive layer 152C, and the insulating layer 127. The second layer can be formed by a vacuum evaporation method. The second layer may further include an electron-injection layer. The second layer is formed as a layer shared by a plurality of light-emitting devices after a photolithography process is completed. Thus, since the second layer is not subjected to the air exposure or high-temperature heat treatment, the range of materials that can be selected is wide and the degree of freedom is high. Thus, the second layer can be formed using a material that is difficult to be used in a photolithography process, such as NBPhen or Alq₃; accordingly, a highly reliable and inexpensive light-emitting apparatus with high resolution can be provided.

Next, the protective layer 131 is formed over the common electrode 155, as illustrated in FIG. 11C. The protective layer 131 can be formed by a vacuum evaporation method, a sputtering method, a CVD method, an ALD method, or the like.

Subsequently, the substrate 120 is attached onto the protective layer 131 with the resin layer 122, whereby the display apparatus can be manufactured. In the method of manufacturing the display apparatus of one embodiment of the present invention, the insulating layer 156 is formed to include a region overlapping with the side surface of the conductive layer 151 and the conductive layer 152 is formed to cover the conductive layer 151 and the insulating layer 156 as described above. This can increase the yield of the display apparatus and inhibit generation of a defect.

As described above, in the method of manufacturing a display apparatus of one embodiment of the present invention, the island-shaped first layer R, the island-shaped first layer G, and the island-shaped first layer B are formed not by using a fine metal mask but by processing a film formed over the entire surface; thus, the island-shaped layers can be formed to have a uniform thickness. Accordingly, a high-resolution apparatus device or a display apparatus with a high aperture ratio can be achieved. Furthermore, even when the resolution or the aperture ratio is high and the distance between subpixels is extremely short, the first layer R, the first layer B, and the first layer G of adjacent subpixels can be inhibited from being in contact with each other. As a result, generation of a leakage current between the subpixels can be inhibited. This can prevent crosstalk, so that the display apparatus can achieve extremely high contrast.

### Embodiment 4

In this embodiment, display apparatuses of embodiments of the present invention will be described.

The display apparatus of this embodiment can be a high-resolution display apparatus. Accordingly, the display apparatus in this embodiment can be used for display portions of information terminals (wearable devices) such as watch-type and bracelet-type information terminals and display portions of wearable devices capable of being worn on a head, such as a VR device like a head-mounted display (HMD) and a glasses-type AR device.

The display apparatus of this embodiment can be a high-definition display apparatus or a large-sized display apparatus. Accordingly, the display apparatus of this embodiment can be used for display portions of electronic devices such as a digital camera, a digital video camera, a digital photo frame, a mobile phone, a portable game console, a portable information terminal, and an audio reproducing device, in addition to display portions of electronic devices with a relatively large screen, such as a television device, a desktop or laptop personal computer, a monitor of a computer and the like, digital signage, and a large game machine such as a pachinko machine.

### [Display Module]

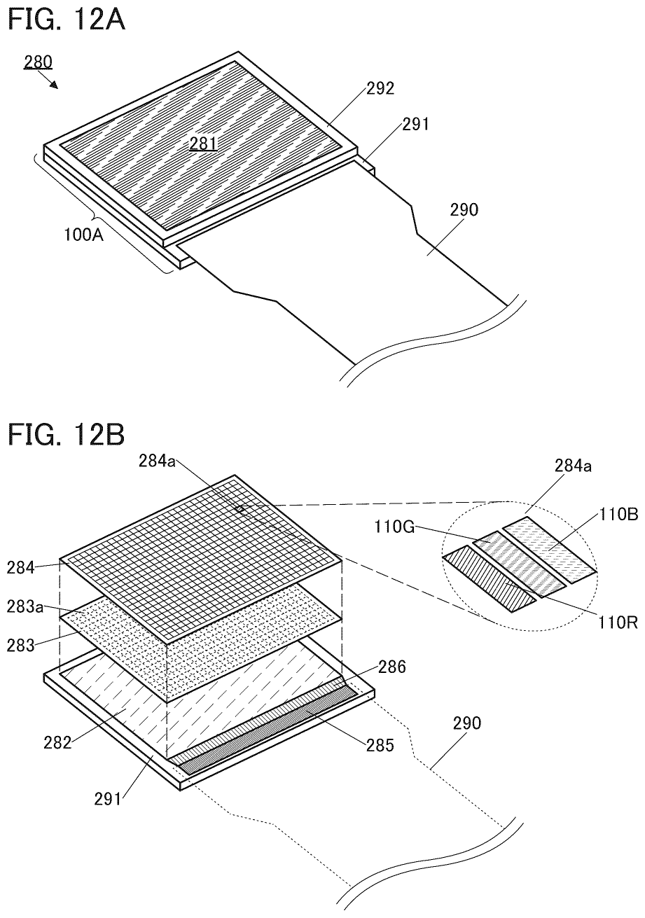

FIG. 12A is a perspective view of a display module 280. The display module 280 includes a display apparatus 100A and an FPC 290. Note that the display apparatus included in the display module 280 is not limited to the display apparatus 100A and may be any of a display apparatus 100B and a display apparatus 100C described later.

The display module 280 includes a substrate 291 and a substrate 292. The display module 280 includes a display portion 281. The display portion 281 is a region of the display module 280 where an image is displayed, and is a region where light from pixels provided in a pixel portion 284 described later can be seen.

FIG. 12B is a perspective view schematically illustrating a structure on the substrate 291 side. Over the substrate 291, a circuit portion 282, a pixel circuit portion 283 over the circuit portion 282, and the pixel portion 284 over the pixel circuit portion 283 are stacked. A terminal portion 285 to be connected to the FPC 290 is provided in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side of FIG. 12B. The pixel 284a can employ any of the structures described in the above embodiments. FIG. 12B illustrates an example where the pixel 284a has a structure similar to that of the pixel 178 illustrated in FIG. 5.

The pixel circuit portion 283 includes a plurality of pixel circuits 283a arranged periodically.

One pixel circuit 283a is a circuit that controls driving of a plurality of elements included in one pixel 284a.

The circuit portion 282 includes a circuit for driving the pixel circuits 283a in the pixel circuit portion 283. For example, one or both of a gate line driver circuit and a source line driver circuit are preferably included. In addition, at least one of an arithmetic circuit, a memory circuit, a power supply circuit, and the like may be included.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; thus, the aperture ratio (the effective display area ratio) of the display portion 281 can be significantly high.

Such a display module 280 has an extremely high resolution, and thus can be suitably used for a VR device such as an HMD or a glasses-type AR device. For example, even with a structure where the display portion of the display module 280 is seen through a lens, pixels of the extremely-high-resolution display portion 281 included in the display module 280 are prevented from being seen when the display portion is enlarged by the lens, so that display providing a high sense of immersion can be performed. Without being limited thereto, the display module 280 can be suitably used for electronic devices including a relatively small display portion.

[Display Apparatus 100a]

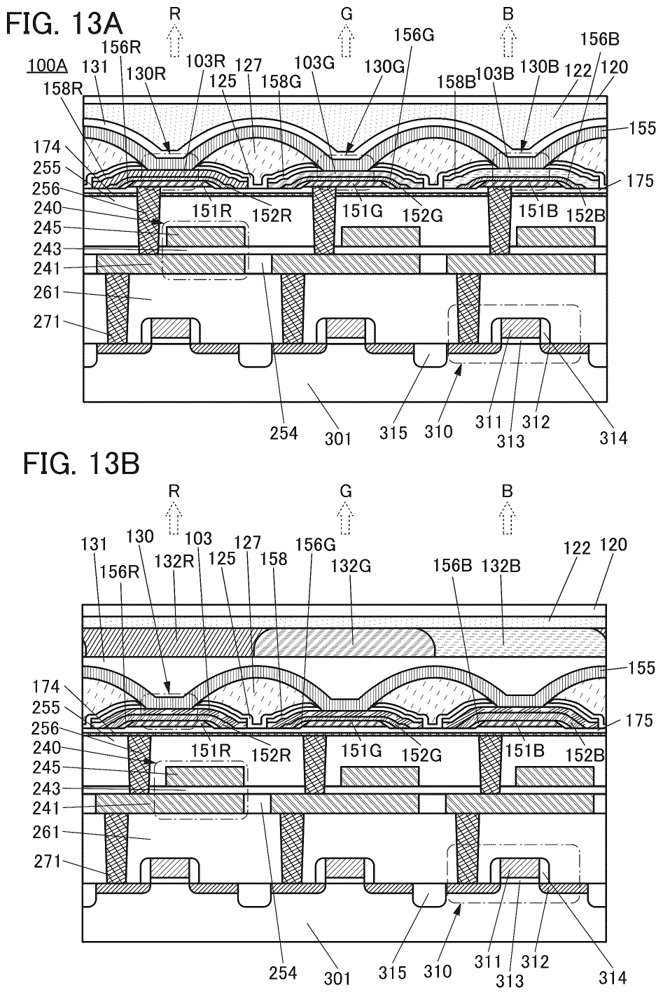

The display apparatus 100A illustrated in FIG. 13A includes a substrate 301, the light-emitting device 130R, the light-emitting device 130G, the light-emitting device 130B, a capacitor 240, and a transistor 310.

The substrate 301 corresponds to the substrate 291 in FIG. 12A and FIG. 12B. The transistor 310 is a transistor including a channel formation region in the substrate 301. As the substrate 301, a semiconductor substrate such as a single crystal silicon substrate can be used, for example. The transistor 310 includes part of the substrate 301, a conductive layer 311, low-resistance regions 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as one of a source and a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 positioned therebetween. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255 is provided to cover the capacitor 240, the insulating layer 174 is provided over the insulating layer 255, and the insulating layer 175 is provided over the insulating layer 174. The light-emitting device 130R, the light-emitting device 130G, and the light-emitting device 130B are provided over the insulating layer 175. An insulator is provided in a region between adjacent light-emitting devices.

The insulating layer 156R is provided to include a region overlapping with the side surface of the conductive layer 151R, the insulating layer 156G is provided to include a region overlapping with the side surface of the conductive layer 151G, and the insulating layer 156B is provided to include a region overlapping with the side surface of the conductive layer 151B. The conductive layer 152R is provided to cover the conductive layer 151R and the insulating layer 156R. The conductive layer 152G is provided to cover the conductive layer 151G and the insulating layer 156G. The conductive layer 152B is provided to cover the conductive layer 151B and the insulating layer 156B. The sacrificial layer 158R is positioned over the first layer R. The sacrificial layer 158G is positioned over the first layer G. The sacrificial layer 158B is positioned over the first layer B.

The conductive layer 151R, the conductive layer 151G, and the conductive layer 151B are each electrically connected to one of the source and the drain of the transistor 310 through a plug 256 embedded in the insulating layer 243, the insulating layer 255, the insulating layer 174, and the insulating layer 175, the conductive layer 241 embedded in the insulating layer 254, and the plug 271 embedded in the insulating layer 261. A variety of conductive materials can be used for the plugs.

The protective layer 131 is provided over the light-emitting device 130R, the light-emitting device 130G, and the light-emitting device 130B. A substrate 120 is attached to the protective layer 131 with a resin layer 122. Embodiment 3 can be referred to for details of the light-emitting devices 130 and the components thereover up to the substrate 120. The substrate 120 corresponds to the substrate 292 in FIG. 12A.

FIG. 13B illustrates a modification example of the display apparatus 100A illustrated in FIG. 13A. The display apparatus illustrated in FIG. 13B includes the coloring layer 132R, the coloring layer 132G, and the coloring layer 132B, and each of the light-emitting devices 130 includes a region overlapping with one of the coloring layer 132R, the coloring layer 132G, and the coloring layer 132B. In the display apparatus illustrated in FIG. 13B, the light-emitting device 130 can emit white light, for example. For example, the coloring layer 132R can transmit red light, the coloring layer 132G can transmit green light, and the coloring layer 132B can transmit blue light.

[Display Apparatus 100b]

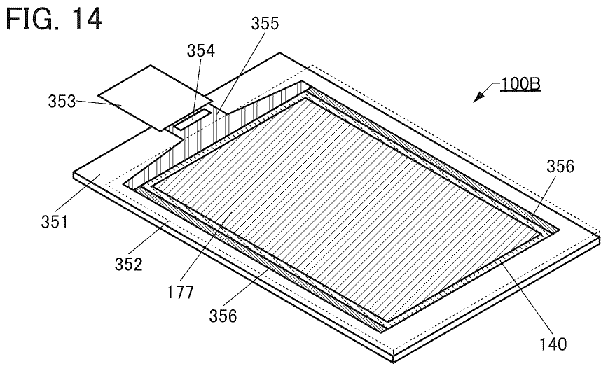

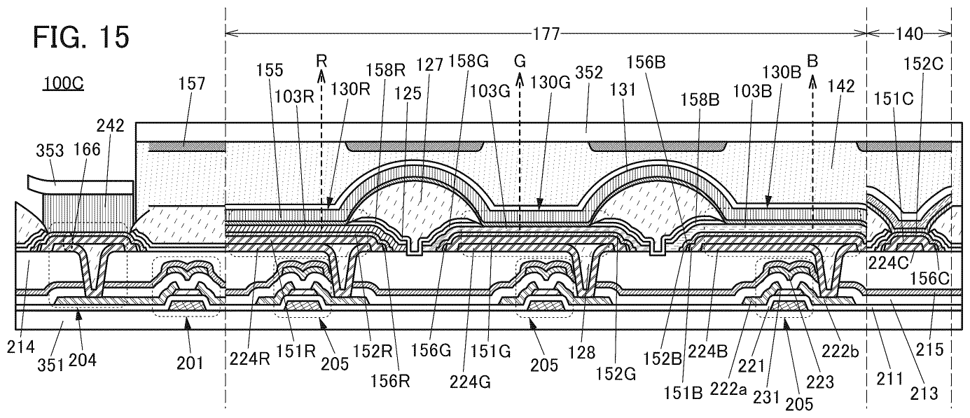

FIG. 14 is a perspective view of the display apparatus 100B, and FIG. 15 is a cross-sectional view of the display apparatus 100B.

In the display apparatus 100B, a substrate 352 and a substrate 351 are bonded to each other. In FIG. 14, the substrate 352 is denoted by a dashed line.

The display apparatus 100B includes the pixel portion 177, the connection portion 140, a circuit 356, a wiring 355, and the like. FIG. 14 illustrates an example where an IC 354 and an FPC 353 are mounted on the display apparatus 100B. Thus, the structure illustrated in FIG. 14 can be regarded as a display module including the display apparatus 100B, the integrated circuit (IC), and the FPC. Here, a display apparatus in which a substrate is equipped with a connector such as an FPC or mounted with an IC is referred to as a display module.

The connection portion 140 is provided outside the pixel portion 177. The number of the connection portions 140 can be one or more. In the connection portion 140, a common electrode of a light-emitting device is electrically connected to a conductive layer, so that a potential can be supplied to the common electrode.

As the circuit 356, a scan line driver circuit can be used, for example.

The wiring 355 has a function of supplying a signal and power to the pixel portion 177 and the circuit 356. The signal and power are input to the wiring 355 from the outside through the FPC 353 or from the IC 354.

FIG. 14 illustrates an example where the IC 354 is provided over the substrate 351 by a COG (Chip On Glass) method, a COF (Chip on Film) method, or the like. An IC including a scan line driver circuit, a signal line driver circuit, or the like can be used as the IC 354, for example. Note that the display apparatus 100B and the display module are not necessarily provided with an IC. The IC may be mounted on the FPC by a COF method, for example.

FIG. 15 illustrates cross section examples of part of a region including the FPC 353, part of the circuit 356, part of the pixel portion 177, part of the connection portion 140, and part of a region including an end portion of the display apparatus 100B.

[Display Apparatus 100c]

The display apparatus 100C illustrated in FIG. 15 includes a transistor 201, a transistor 205, the light-emitting device 130R emitting red light, the light-emitting device 130G emitting green light, the light-emitting device 130B emitting blue light, and the like between the substrate 351 and the substrate 352.

Embodiment 1 can be referred to for the details of the light-emitting device 130R, the light-emitting device 130G, and the light-emitting device 130B.

The light-emitting device 130R includes a conductive layer 224R, the conductive layer 151R over the conductive layer 224R, and the conductive layer 152R over the conductive layer 151R. The light-emitting device 130G includes a conductive layer 224G, the conductive layer 151G over the conductive layer 224G, and the conductive layer 152G over the conductive layer 151G. The light-emitting device 130B includes a conductive layer 224B, the conductive layer 151B over the conductive layer 224B, and the conductive layer 152B over the conductive layer 151B.

The conductive layer 224R is connected to a conductive layer 222b included in the transistor 205 through the opening provided in an insulating layer 214. The edge portion of the conductive layer 151R is positioned outward from the edge portion of the conductive layer 224R. The insulating layer 156R is provided to include a region that is in contact with the side surface of the conductive layer 151R, and the conductive layer 152R is provided to cover the conductive layer 151R and the insulating layer 156R.

The conductive layer 224G, the conductive layer 151G, the conductive layer 152G, and the insulating layer 156G in the light-emitting device 130G are not described in detail because they are respectively similar to the conductive layer 224R, the conductive layer 151R, the conductive layer 152R, and the insulating layer 156R in the light-emitting device 130R; the same applies to the conductive layer 224B, the conductive layer 151B, the conductive layer 152B, and the insulating layer 156B in the light-emitting device 130B.

The conductive layer 224R, the conductive layer 224G, and the conductive layer 224B each have a depression portion covering an opening provided in the insulating layer 214. A layer 128 is embedded in the depressed portions.

The layer 128 has a planarization function for the depressed portions of the conductive layer 224R, the conductive layer 224G, and the conductive layer 224B. Over the conductive layer 224R, the conductive layer 224G, the conductive layer 224B, and the layer 128, the conductive layer 151R, the conductive layer 151G, and the conductive layer 151B that are respectively electrically connected to the conductive layer 224R, the conductive layer 224G, and the conductive layer 224B are provided. Thus, regions overlapping with the depressed portions of the conductive layer 224R, the conductive layer 224G, and the conductive layer 224B can also be used as the light-emitting regions, increasing the aperture ratio of the pixels.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. The layer 128 can be formed using an organic insulating material usable for the insulating layer 127, for example.

The protective layer 131 is provided over the light-emitting device 130R, the light-emitting device 130G, and the light-emitting device 130B. The protective layer 131 and the substrate 352 are bonded to each other with an adhesive layer 142. The substrate 352 is provided with a light-blocking layer 157. A solid sealing structure, a hollow sealing structure, or the like can be employed to seal the light-emitting device 130. In FIG. 15, a solid sealing structure is employed in which a space between the substrate 352 and the substrate 351 is filled with the adhesive layer 142. Alternatively, a hollow sealing structure where the space is filled with an inert gas (e.g., nitrogen or argon) may be employed. Here, the adhesive layer 142 may be provided not to overlap with the light-emitting device. The space may be filled with a resin different from that of the frame-like adhesive layer 142.

FIG. 15 illustrates an example in which the connection portion 140 includes a conductive layer 224C obtained by processing the same conductive film as the conductive layer 224R, the conductive layer 224G, and the conductive layer 224B, the conductive layer 151C obtained by processing the same conductive film as the conductive layer 151R, the conductive layer 151G, and the conductive layer 151B, and the conductive layer 152C obtained by processing the same conductive film as the conductive layer 152R, the conductive layer 152G, and the conductive layer 152B. FIG. 15 illustrates an example in which the insulating layer 156C is provided to include a region overlapping with the side surface of the conductive layer 151C.

The display apparatus 100B has a top-emission structure. Light from the light-emitting device is emitted toward the substrate 352. For the substrate 352, a material having a high visible-light-transmitting property is preferably used. In the case where the light-emitting device emits infrared or near-infrared light, a material with a high transmitting property with respect to infrared or near-infrared light is preferably used. The pixel electrode contains a material that reflects visible light, and the counter electrode (the common electrode 155) contains a material that transmits visible light.

An insulating layer 211, an insulating layer 213, an insulating layer 215, and the insulating layer 214 are provided in this order over the substrate 351. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or two or more.

An inorganic insulating film is preferably used as each of the insulating layer 211, the insulating layer 213, and the insulating layer 215.

An organic insulating layer is suitable as the insulating layer 214 functioning as a planarization layer.

Each of the transistor 201 and the transistor 205 includes a conductive layer 221 functioning as a gate, the insulating layer 211 functioning as a gate insulating layer, a conductive layer 222a and a conductive layer 222b functioning as a source and a drain, a semiconductor layer 231, the insulating layer 213 functioning as a gate insulating layer, and a conductive layer 223 functioning as a gate.

A connection portion 204 is provided in a region of the substrate 351 where the substrate 352 does not overlap. In the connection portion 204, the wiring 355 is electrically connected to the FPC 353 through a conductive layer 166 and a connection layer 242. As an example, the conductive layer 166 has a stacked-layer structure of a conductive film obtained by processing the same conductive film as the conductive layer 224R, the conductive layer 224G, and the conductive layer 224B; a conductive film obtained by processing the same conductive film as the conductive layer 151R, the conductive layer 151G, and the conductive layer 151B; and a conductive film obtained by processing the same conductive film as the conductive layer 152R, the conductive layer 152G, and the conductive layer 152B. On the top surface of the connection portion 204, the conductive layer 166 is exposed. Thus, the connection portion 204 and the FPC 353 can be electrically connected to each other through the connection layer 242.

A light-blocking layer 157 is preferably provided on the surface of the substrate 352 on the substrate 351 side. The light-blocking layer 157 can be provided over a region between adjacent light-emitting devices, in the connection portion 140, in the circuit 356, and the like. A variety of optical members can be arranged on the outer surface of the substrate 352.

A material that can be used for the substrate 120 can be used for the substrate 351 and the substrate 352.

A material that can be used for the resin layer 122 can be used for the adhesive layer 142.

As the connection layer 242, an anisotropic conductive film (ACF), an anisotropic conductive paste (ACP), or the like can be used.

[Display Apparatus 100d]

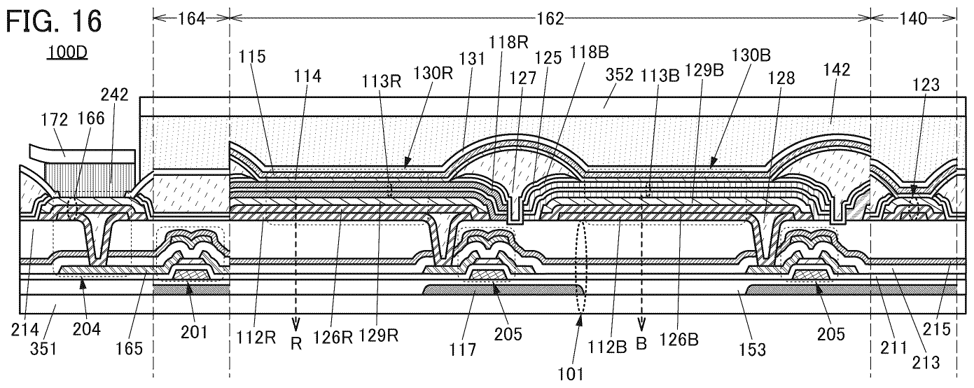

A display apparatus 100D illustrated in FIG. 16 is different from the display apparatus 100A illustrated in FIG. 15 mainly in having a bottom-emission structure.

Light from the light-emitting device is emitted toward the substrate 351. For the substrate 351, a material having a high visible-light-transmitting property is preferably used. By contrast, there is no limitation on the light-transmitting property of a material used for the substrate 352.

A light-blocking layer is preferably formed between the substrate 351 and the transistor 201 and between the substrate 351 and the transistor 205. FIG. 16 illustrates an example where a light-blocking layer is provided over the substrate 351, an insulating layer 153 is provided over the light-blocking layer, and the transistors 201 and 205 and the like are provided over the insulating layer 153.

The light-emitting device 130R includes a conductive layer 112R, a conductive layer 126R over the conductive layer 112R, and a conductive layer 129R over the conductive layer 126R.

The light-emitting device 130B includes a conductive layer 112B, a conductive layer 126B over the conductive layer 112B, and a conductive layer 129B over the conductive layer 126B.

A material having a high visible-light-transmitting property is used for each of the conductive layers 112R, 112B, 126R, 126B, 129R, and 129B. A material that reflects visible light is preferably used for the common electrode 155.

Although not illustrated in FIG. 16, the light-emitting device 130G is also provided.

Although FIG. 16 and the like illustrate an example where the top surface of the layer 128 includes a flat portion, there is no particular limitation on the shape of the layer 128.

[Display Apparatus 100e]

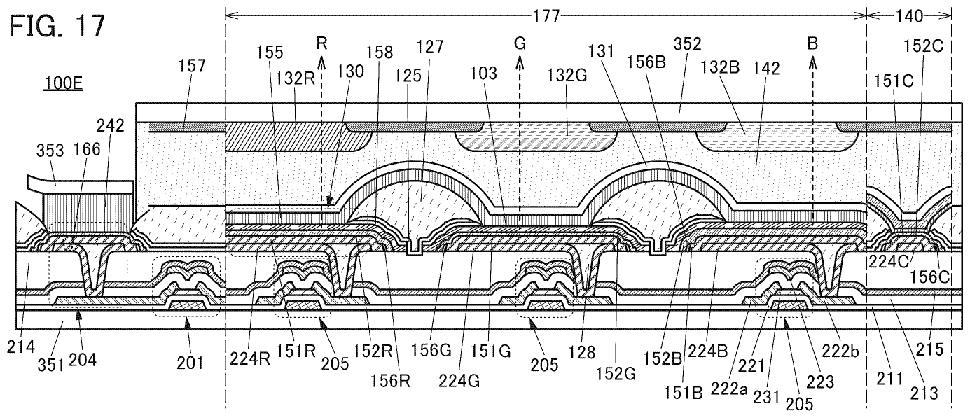

A display apparatus 100E illustrated in FIG. 17 is a modification example of the display apparatus 100B illustrated in FIG. 15 and differs from the display apparatus 100B mainly in including the coloring layer 132R, the coloring layer 132G, and the coloring layer 132B.

In the display apparatus 100E, the light-emitting device 130 includes a region overlapping with one of the coloring layer 132R, the coloring layer 132G, and the coloring layer 132B. The coloring layer 132R, the coloring layer 132G, and the coloring layer 132B can be provided on a surface of the substrate 352 on the substrate 351 side. The edge portions of the coloring layer 132R, the coloring layer 132G, and the coloring layer 132B can overlap the light-blocking layer 157.

In the display apparatus 100E, the light-emitting device 130 can emit white light, for example. For example, the coloring layer 132R can transmit red light, the coloring layer 132G can transmit green light, and the coloring layer 132B can transmit blue light. Note that in the display apparatus 100E, the coloring layer 132R, the coloring layer 132G, and the coloring layer 132B may be provided between the protective layer 131 and the adhesive layer 142.

Although FIG. 15, FIG. 17, and the like illustrate an example where the top surface of the layer 128 includes a flat portion, there is no particular limitation on the shape of the layer 128.

This embodiment can be combined with the other embodiments or examples as appropriate. In this specification, in the case where a plurality of structure examples are shown in one embodiment, the structure examples can be combined as appropriate.

### Embodiment 5

In this embodiment, electronic devices of one embodiment of the present invention will be described.

Electronic devices of this embodiment each include the display apparatus of one embodiment of the present invention in a display portion. The display apparatus of one embodiment of the present invention exhibits high display performance and can be easily increased in resolution and definition. Thus, the display apparatus of one embodiment of the present invention can be used for a display portion of a variety of electronic devices.

Examples of the electronic devices include electronic devices with a relatively large screen, such as a television device, a desktop or notebook personal computer, a monitor of a computer or the like, digital signage, and a large game machine such as a pachinko machine; a digital camera; a digital video camera; a digital photo frame; a mobile phone; a portable game console; a portable information terminal; and an audio reproducing device.

In particular, the display apparatus of one embodiment of the present invention can have a high resolution, and thus can be suitably used for an electronic device having a relatively small display portion. Examples of such an electronic device include a watch-type or a bracelet-type information terminal device (wearable device), and a wearable device worn on a head, such as a device for VR such as a head-mounted display, a glasses-type device for AR, and a device for MR.

The electronic device in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, odor, or infrared rays).

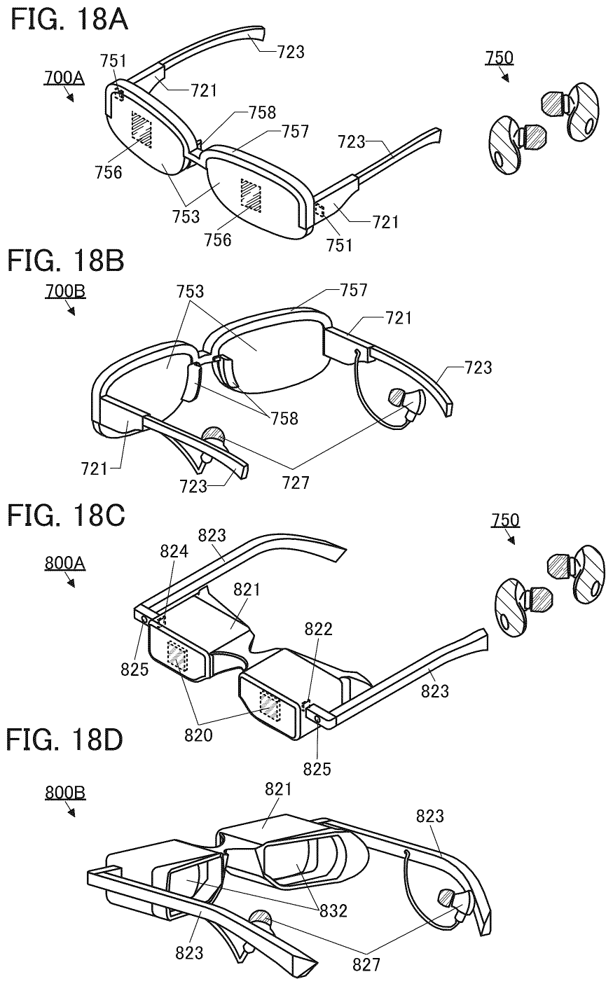

Examples of a wearable device that can be worn on a head are described with reference to FIG. 18A to FIG. 18D.

An electronic device 700A illustrated in FIG. 18A and an electronic device 700B illustrated in FIG. 18B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display apparatus of one embodiment of the present invention can be used for the display panel 751. Thus, a highly reliable electronic device is obtained.

The electronic device 700A and the electronic device 700B can each project images displayed on the display panels 751 onto display regions 756 of the optical members 753. Since the optical members 753 have a light-transmitting property, a user can see images displayed on the display regions, which are superimposed on transmission images seen through the optical members 753.

In the electronic device 700A and the electronic device 700B, a camera capable of capturing images of the front side may be provided as the image capturing portion. Furthermore, when the electronic device 700A and the electronic device 700B are provided with an acceleration sensor such as a gyroscope sensor, the orientation of the user's head can be sensed and an image corresponding to the orientation can be displayed on the display regions 756.

The communication portion includes a wireless communication device, and a picture signal, for example, can be supplied by the wireless communication device. Instead of or in addition to the wireless communication device, a connector that can be connected to a cable for supplying a video signal and a power supply potential may be provided.

The electronic device 700A and the electronic device 700B are provided with a battery so that they can be charged wirelessly and/or by wire.

A touch sensor module may be provided in the housing 721.

Any of various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

An electronic device 800A illustrated in FIG. 18C and an electronic device 800B illustrated in FIG. 18D each include a pair of display portions 820, a housing 821, a communication portion 822, a pair of wearing portions 823, a control portion 824, a pair of image capturing portions 825, and a pair of lenses 832.

A display apparatus of one embodiment of the present invention can be used in the display portions 820. Thus, a highly reliable electronic device is obtained.

The display portions 820 are positioned inside the housing 821 so as to be seen through the lenses 832. When the pair of display portions 820 display different images, three-dimensional display using parallax can be performed.

The electronic device 800A and the electronic device 800B preferably include a mechanism for adjusting the lateral positions of the lenses 832 and the display portions 820 so that the lenses 832 and the display portions 820 are positioned optimally in accordance with the positions of the user's eyes.

The electronic device 800A or the electronic device 800B can be mounted on the user's head with the wearing portions 823.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

The electronic device 800A may include a vibration mechanism that functions as bone-conduction earphones.

The electronic device 800A and the electronic device 800B may each include an input terminal. To the input terminal, a cable for supplying, a video signal from a video output device or the like, power for charging a battery provided in the electronic device, and the like can be connected.

The electronic device of one embodiment of the present invention may have a function of performing wireless communication with earphones 750.

The electronic device may include an earphone portion. The electronic device 700B in FIG. 18B includes earphone portions 727. Part of a wiring that connects the earphone portion 727 and the control portion may be positioned inside the housing 721 or the wearing portion 723.

Similarly, the electronic device 800B illustrated in FIG. 18D includes earphone portions 827. For example, the earphone portion 827 and the control portion 824 can be connected to each other by wire.

As described above, both the glasses-type device (e.g., the electronic device 700A and the electronic device 700B) and the goggles-type device (e.g., the electronic device 800A and the electronic device 800B) are preferable as the electronic device of one embodiment of the present invention.

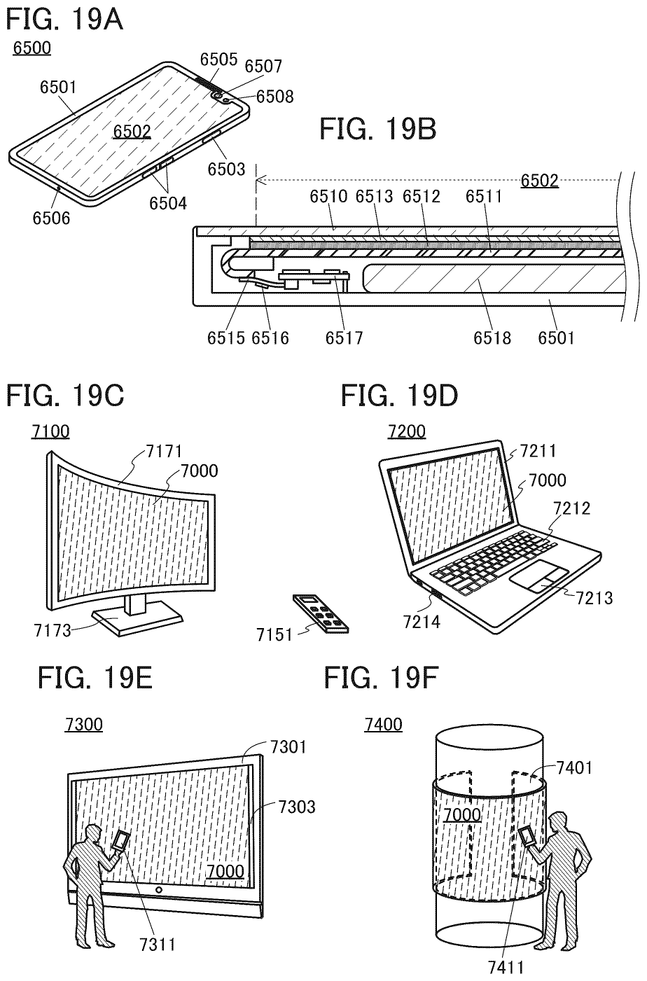

An electronic device 6500 illustrated in FIG. 19A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used in the display portion 6502. Thus, a highly reliable electronic device is obtained.

FIG. 19B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic device can be achieved. Since the display panel 6511 is extremely thin, the battery 6518 with high capacity can be mounted without an increase in the thickness of the electronic device. Moreover, part of the display panel 6511 is folded back so that a connection portion with the FPC 6515 is provided on the back side of a pixel portion, whereby an electronic device with a narrow bezel can be achieved.

FIG. 19C illustrates an example of a television device. In a television device 7100, a display portion 7000 is incorporated in a housing 7171. Here, the housing 7171 is supported by a stand 7173.

The display apparatus of one embodiment of the present invention can be used in the display portion 7000. Thus, a highly reliable electronic device is obtained.

Operation of the television device 7100 illustrated in FIG. 19C can be performed with an operation switch provided in the housing 7171 and a separate remote control 7151.

FIG. 19D illustrates an example of a laptop personal computer. A laptop personal computer 7200 includes a housing 7211, a keyboard 7212, a pointing device 7213, an external connection port 7214, and the like. In the housing 7211, the display portion 7000 is incorporated.

The display apparatus of one embodiment of the present invention can be used in the display portion 7000. Thus, a highly reliable electronic device is obtained.

FIG. 19E and FIG. 19F illustrate examples of digital signage.

Digital signage 7300 illustrated in FIG. 19E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 19F is digital signage 7400 attached to a cylindrical pillar 7401. The digital signage 7400 includes the display portion 7000 provided along a curved surface of the pillar 7401.

The display apparatus of one embodiment of the present invention can be used for the display portion 7000 illustrated in each of FIG. 19E and FIG. 19F. Thus, a highly reliable electronic device is obtained.

The larger display portion 7000 can provide a larger amount of information at a time. The larger display portion 7000 attracts more attention, so that the effectiveness of the advertisement can be increased, for example.

As illustrated in FIG. 19E and FIG. 19F, it is preferable that the digital signage 7300 or the digital signage 7400 can work with an information terminal 7311 or an information terminal 7411 such as a smartphone a user has through wireless communication.

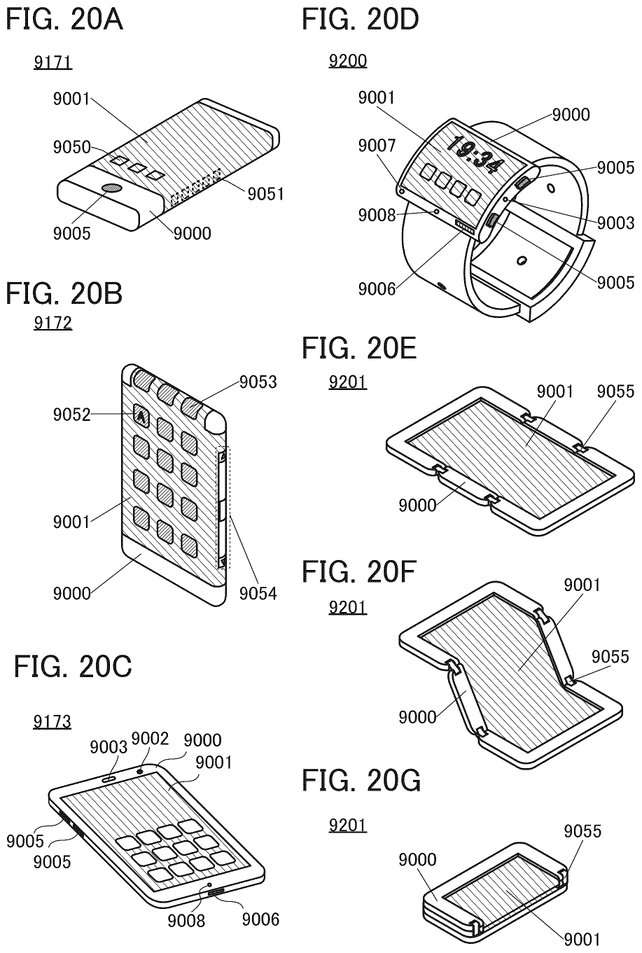

Electronic devices illustrated in FIG. 20A to FIG. 20G include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

The electronic devices illustrated in FIG. 20A to FIG. 20G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with use of a variety of software (programs), a wireless communication function, and a function of reading out and processing a program or data stored in a recording medium.

The details of the electronic devices illustrated in FIG. 20A to FIG. 20G are described below.

FIG. 20A is a perspective view illustrating a portable information terminal 9171. For example, the portable information terminal 9171 can be used as a smartphone. Note that the portable information terminal 9171 may include the speaker 9003, the connection terminal 9006, the sensor 9007, or the like. The portable information terminal 9171 can display characters and image information on its plurality of surfaces. FIG. 20A illustrates an example where three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 20B is a perspective view illustrating a portable information terminal 9172. The portable information terminal 9172 has a function of displaying information on three or more surfaces of the display portion 9001. Here, an example in which information 9052, information 9053, and information 9054 are displayed on different surfaces is illustrated. For example, a user can check the information 9053 displayed in a position that can be observed from above the portable information terminal 9172, with the portable information terminal 9172 put in a breast pocket of his/her clothes.

FIG. 20C is a perspective view illustrating a tablet terminal 9173. The tablet terminal 9173 is capable of executing a variety of applications such as mobile phone calls, e-mailing, viewing and editing texts, music reproduction, Internet communication, and a computer game. The tablet terminal 9173 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 20D is a perspective view illustrating a watch-type portable information terminal 9200. For example, the portable information terminal 9200 can be used as a Smartwatch (registered trademark). The display surface of the display portion 9001 is curved, and an image can be displayed on the curved display surface. Furthermore, intercommunication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 20E to FIG. 20G are perspective views illustrating a foldable portable information terminal 9201. FIG. 20E is a perspective view of an opened state of the portable information terminal 9201, FIG. 20G is a perspective view of a folded state thereof, and FIG. 20F is a perspective view of a state in the middle of change from one of FIG. 20E and FIG. 20G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with the other embodiments or examples as appropriate. In this specification, in the case where a plurality of structure examples are shown in one embodiment, the structure examples can be combined as appropriate.

### Example 1

This example shows results of examining characteristics of light-emitting devices under process conditions such that air exposure and heating in a vacuum atmosphere were performed on surfaces of a light-emitting layer, a first electron-transport layer (hole-blocking layer), and a second electron-transport layer in an environment not irradiated with light whose wavelength is less than 480 nm during processing. Note that a light-emitting device (light-emitting device B0) subjected to neither air exposure nor heating in a vacuum atmosphere was also fabricated for comparison.

Structural formulae of compounds mainly used in this example are shown below.

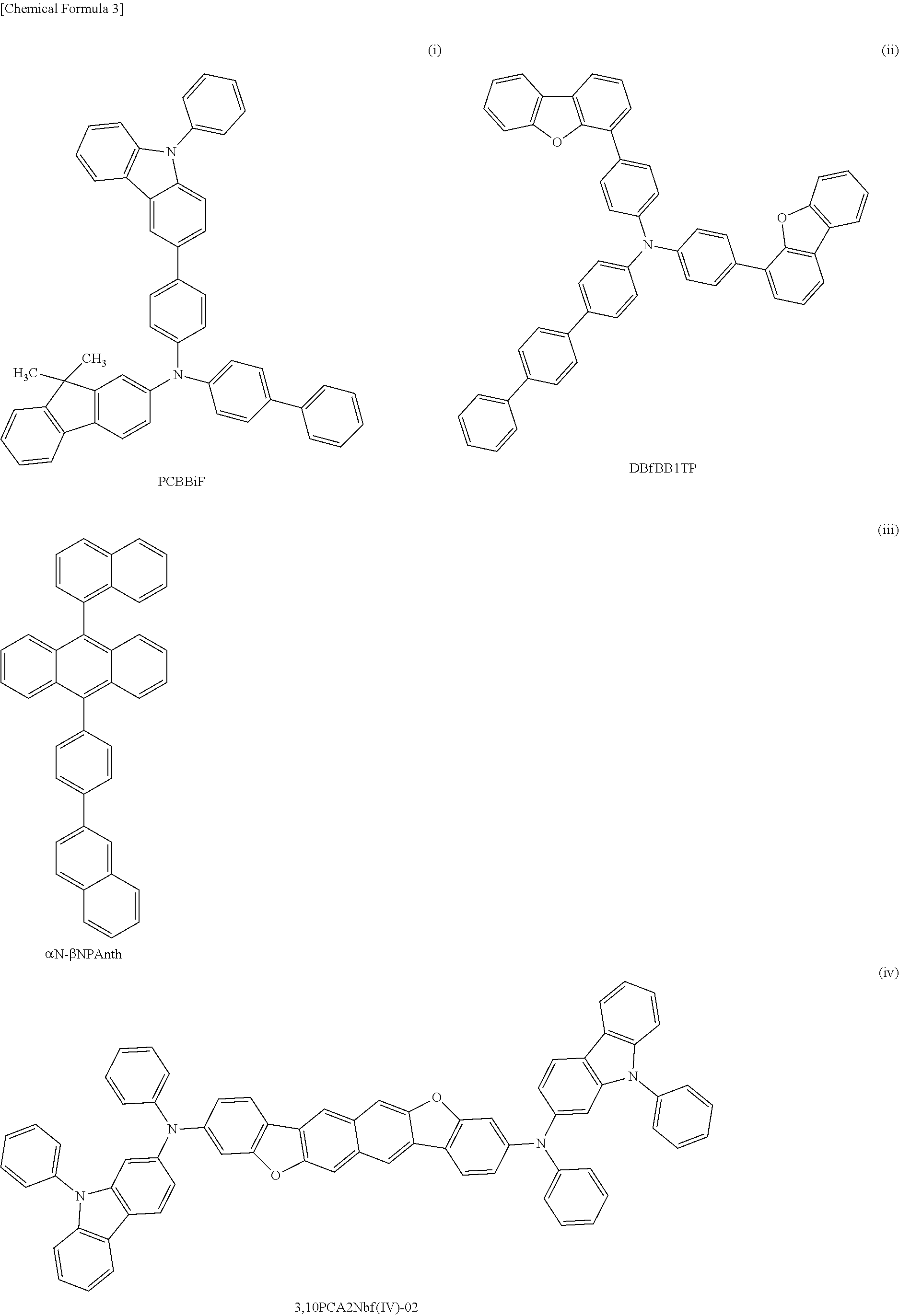

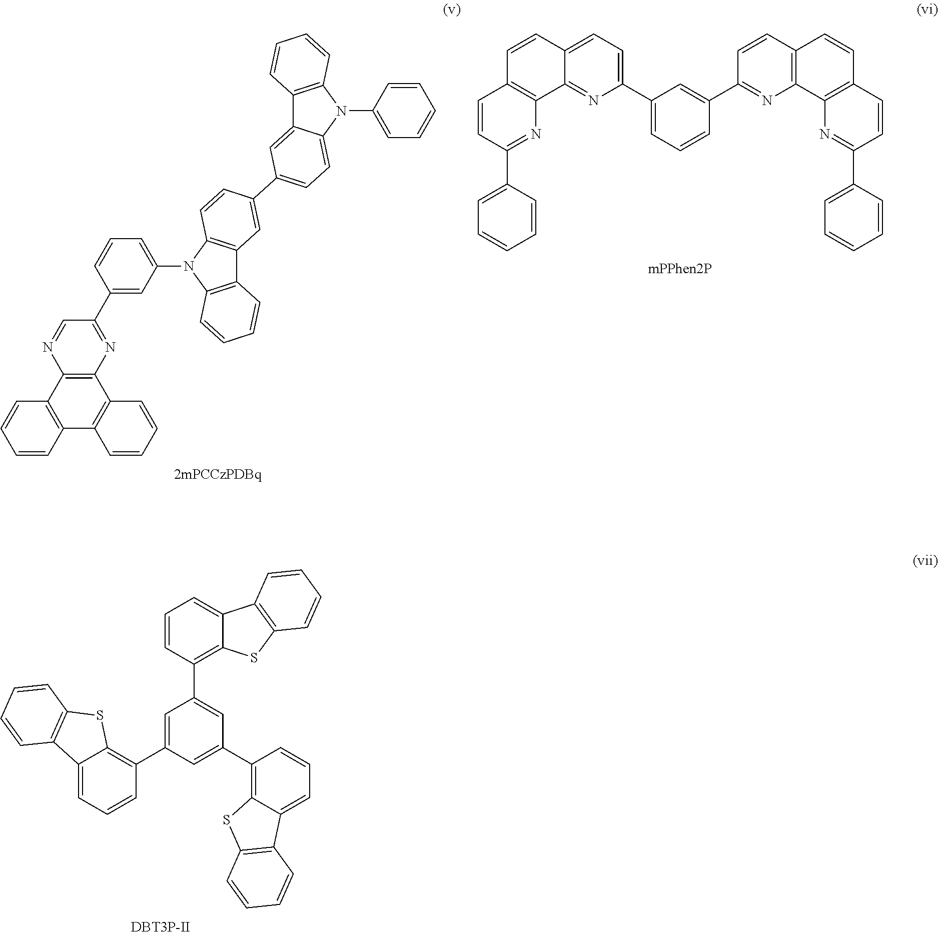

### (Fabrication Method of Light-Emitting Device B0)

First, 100-nm-thick alloy of silver, palladium, and copper (APC: Ag—Pd—Cu) and 10-nm-thick indium tin oxide containing silicon oxide (ITSO) were stacked over a glass substrate sequentially from the substrate side by a sputtering method as a reflective electrode and a transparent electrode, respectively, whereby the first electrode 101 with a size of 2 mm×2 mm was formed. Note that the transparent electrode functions as an anode, and the transparent electrode and the reflective electrode can be collectively regarded as the first electrode 101.

Then, pretreatment for formation of the light-emitting device over the substrate was performed by washing the substrate surface with water.

After that, the substrate was transferred into a vacuum evaporation apparatus in which the pressure was reduced to approximately 1×10⁻⁴ Pa, vacuum baking was performed at 170° C. for 60 minutes in a heating chamber of the vacuum evaporation apparatus, and then the substrate was cooled down for approximately 30 minutes.

Then, the substrate was fixed to a substrate holder provided in the vacuum evaporation apparatus such that the surface over which the first electrode 101 was formed faced downward. Over an inorganic insulating film and the first electrode 101, the hole-injection layer 111 was formed by co-evaporation of N-(1,1′-biphenyl-4-yl)-N-[4-(9-phenyl-9H-carbazol-3-yl)phenyl]-9,9-dimethyl-9H-fluoren-2-amine (abbreviation: PCBBiF) represented by Structural Formula (i) above and a fluorine-containing electron-acceptor material with a molecular weight of 672 (OCHD-003) to have a thickness of 10 nm and a weight ratio of 1:0.03 (=PCBBiF: OCHD-003).

Over the hole-injection layer 111, a first hole-transport layer with a thickness of 96 nm was formed by evaporation of PCBBiF, and then a second hole-transport layer was formed by evaporation of N,N-bis[4-(dibenzofuran-4-yl)phenyl]-4-amino-p-terphenyl (abbreviation: DBfBB1TP) represented by Structure Formula (ii) above to have a thickness of 10 nm, whereby a hole-transport layer 112 was formed. Note that the second hole-transport layer also functions as an electron-blocking layer.

Then, over the hole-transport layer, the light-emitting layer 113 was formed by co-evaporation of 9-(1-naphthyl)-10-[4-(2-naphthyl)phenyl]anthracene (abbreviation: αN-BNPAnth) represented by Structural Formula (iii) above and 3,10-bis[N-(9-phenyl-9H-carbazol-2-yl)-N-phenylamino]naphtho[2,3-b;6,7-b′]bisbenzofuran (abbreviation: 3,10PCA2Nbf (IV)-02) represented by Structural Formula (iv) above to have a thickness of 25 nm and a weight ratio of 1:0.015 (=aN-BNPAnth: 3,10PCA2Nbf (IV)-02).

After that, a first electron-transport layer was formed to a thickness of 20 nm by evaporation of 2-{3-[3-(N-phenyl-9H-carbazol-3-yl)-9H-carbazol-9-yl]phenyl}dibenzo[f,h]quinoxaline (abbreviation: 2mPCCzPDBq) represented by Structural Formula (v) above, and a second electron-transport layer was formed to a thickness of 15 nm by evaporation of 2,2′-(1,3-phenylene)bis(9-phenyl-1,10-phenanthroline) (abbreviation: mPPhen2P) represented by Structural Formula (vi) above, whereby the electron-transport layer 114 was formed. Note that the first electron-transport layer also functions as a hole-blocking layer.

After the electron-injection layer 115 was formed to have a thickness of 1 nm by evaporation of lithium fluoride (LiF), and the second electrode 102 was formed by co-evaporation of silver (Ag) and magnesium (Mg) to have a thickness of 15 nm and a volume ratio of 1:0.1, whereby the light-emitting device of one embodiment of the present invention was fabricated. Over the second electrode 102, a cap layer with a thickness of 70 nm was formed by evaporation of 4,4′,4″-(benzene-1,3,5-triyl)tri(dibenzothiophene) (abbreviation: DBT3P-II) represented by Structural Formula (vii) above, so that light extraction efficiency was improved.

Then, the light-emitting device was sealed using a glass substrate in a glove box containing a nitrogen atmosphere so as not to be exposed to the air (a UV curable sealing material was applied to surround the element, only the sealing material was irradiated with UV while the light-emitting device was prevented from being irradiated with the UV, and heat treatment was performed at 80° C. under an atmospheric pressure for one hour), so that a light-emitting device B0 was fabricated.

### (Fabrication Method of Light-Emitting Device B100_1 to Light-Emitting Device B100_3)

A light-emitting device B100_1 was fabricated in the following manner: the light-emitting layer 113 was formed through the fabrication method of the light-emitting device B0 and then left in an air atmosphere for one hour; heating was performed at 100° C. (under a condition lower than 100° C. after the substrate temperature reached 90° C.) in a vacuum atmosphere (approx. 1×10⁻⁴ Pa) for one hour; and then the rest layers were formed.

A light-emitting device B100_2 was fabricated in the following manner: the first electron-transport layer (hole-blocking layer) was formed through the fabrication method of the light-emitting device B0 and then left in an air atmosphere for one hour; heating was performed at 100° C. (under a condition lower than 100° C. after the substrate temperature reached 90° C.) in a vacuum atmosphere (approx. 1×10⁻⁴ Pa) for one hour; and then the rest layers were formed.

A light-emitting device B100_3 was fabricated in the following manner: the second electron-transport layer was formed through the fabrication method of the light-emitting device B0 and then left in an air atmosphere for one hour; heating was performed at 100° C. (under a condition lower than 100° C. after the substrate temperature reached 90° C.) in a vacuum atmosphere (approx. 1×10⁻⁴ Pa) for one hour; and then the rest layers were formed.

### (Fabrication Method of Light-Emitting Device B80_1 to Light-Emitting Device B80_3)

A light-emitting device B80_1 was fabricated in the following manner: the light-emitting layer 113 was formed through the fabrication method of the light-emitting device B0 and then left in an air atmosphere for one hour; heating was performed at 80° C. (under a condition lower than 80° C. after the substrate temperature reached 70° C.) in a vacuum atmosphere (approx. 1×10⁻⁴ Pa) for two hours; and then the rest layers were formed.

A light-emitting device B80_2 was fabricated in the following manner: the first electron-transport layer (hole-blocking layer) was formed through the fabrication method of the light-emitting device B0 and then left in an air atmosphere for one hour; heating was performed at 80° C. (under a condition lower than 80° C. after the substrate temperature reached 70° C.) in a vacuum atmosphere (approx. 1×10⁻⁴ Pa) for two hours; and then the rest layers were formed.

A light-emitting device 80_3 was fabricated in the following manner: the second electron-transport layer was formed through the fabrication method of the light-emitting device B0 and then left in an air atmosphere for one hour; heating was performed at 80° C. (under a condition lower than 80° C. after the substrate temperature reached 70° C.) in a vacuum atmosphere (approx. 1×10⁻⁴ Pa) for two hours; and then the rest layers were formed.

Device structures of the light-emitting device B0, the light-emitting device B100_1 to the light-emitting device B100_3, and the light-emitting device B80_1 to the light-emitting device B80_3 are shown below.

TABLE 1

| | | Thickness | Light-emitting device B | | | | | | |
|---|---|---|---|---|---|---|---|---|---|
| | | (nm) | 0 | 100_1 | 100_2 | 100_3 | 80_1 | 80_2 | 80_3 |
| Cap layer | | 80 | DBT3P-II | | | | | | |
| Second electrode | | 25 | Ag:Mg (1:0.1) | | | | | | |
| Electron-injection layer | | 1 | LiF | | | | | | |
| Air exposure/heat treatment | | | — | — | — | 100° C. | — | — | 80° C. |
| Electron-transport layer 2 | | 15 | mPPhen2P | | | | | | |
| Air exposure/heat treatment | | | — | — | 100° C. | — | — | 80° C. | — |
| Electron-transport layer 1 | | 20 | 2mPCCzPDBq | | | | | | |
| (hole-blocking layer) | | | | | | | | | |
| Air exposure/heat treatment | | | — | 100° C. | — | — | 80° C. | — | — |
| Light-emitting layer | | 25 | αN-βNPAnth:3,10PCA2Nbf(IV)-02(1:0.015) | | | | | | |
| Hole | 2 | 10 | DBfBB1TP | | | | | | |
| transport | (Electron-blocking layer) | | | | | | | | |

| layer | 1 | 96 | PCBBiF |
|---|---|---|---|
| Hole-injection layer | | 10 | PCBBiF:OCHD-003(1:0.03) |
| First | Transparent | 10 | ITSO |
| electrode | electrode | | |
| | Reflective | 100 | APC |
| | electrode | | |

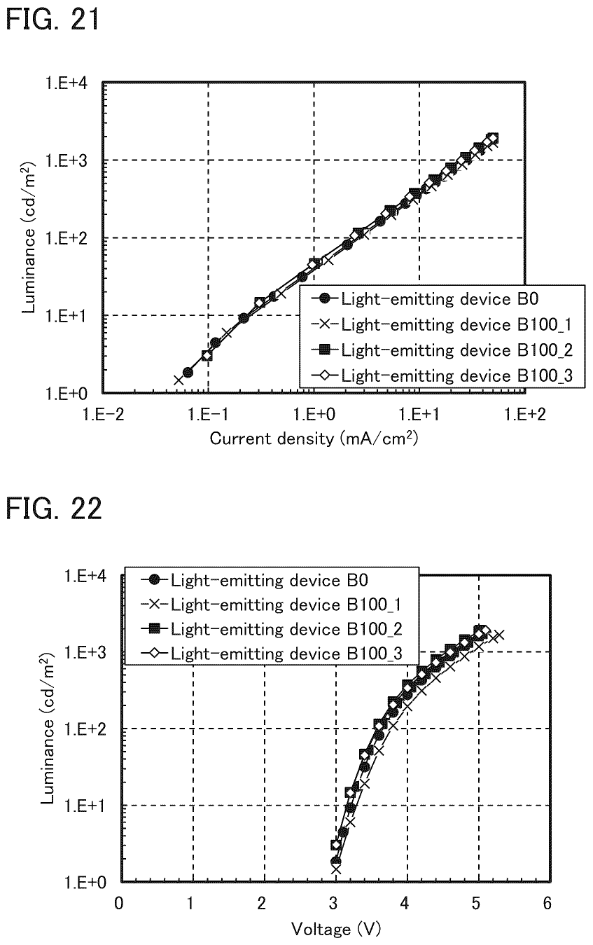

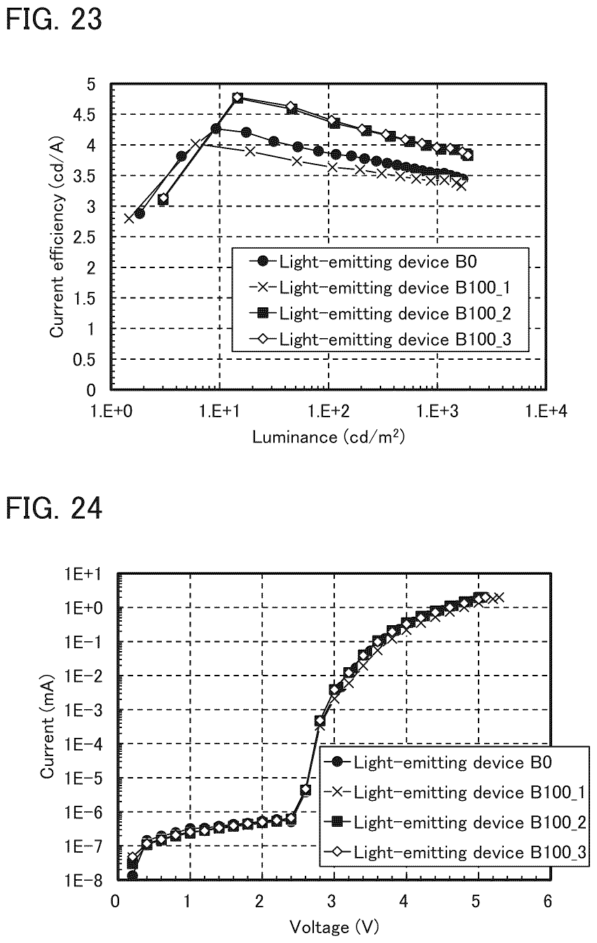

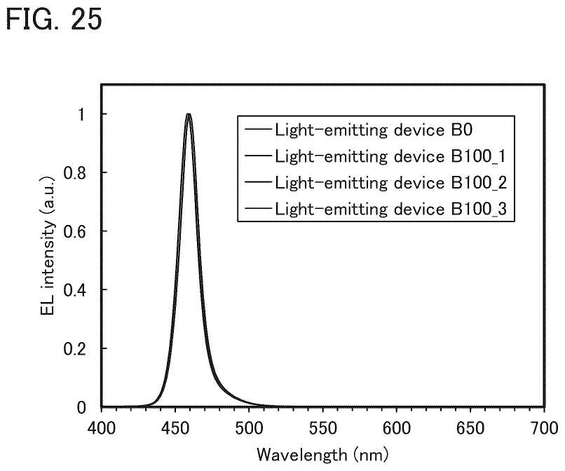

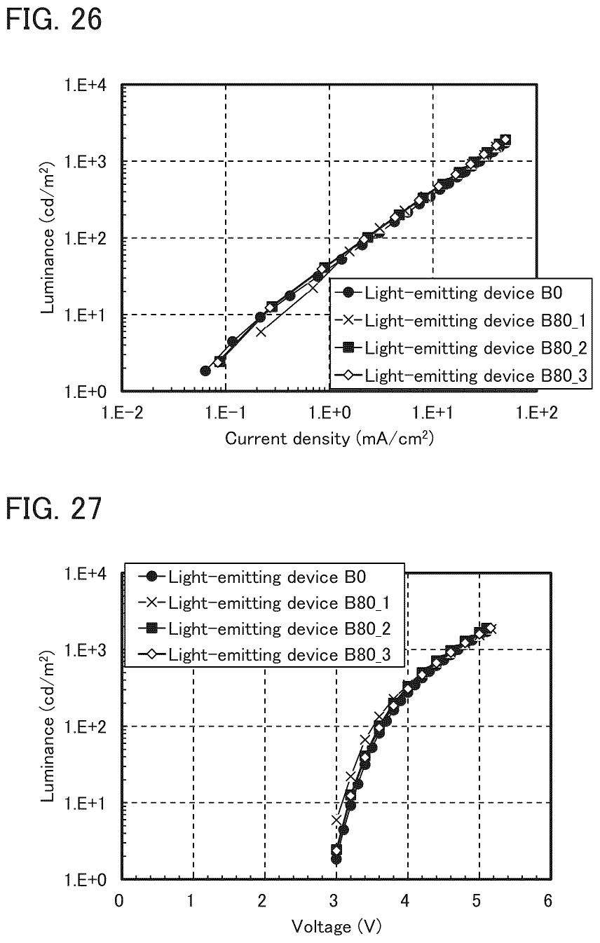

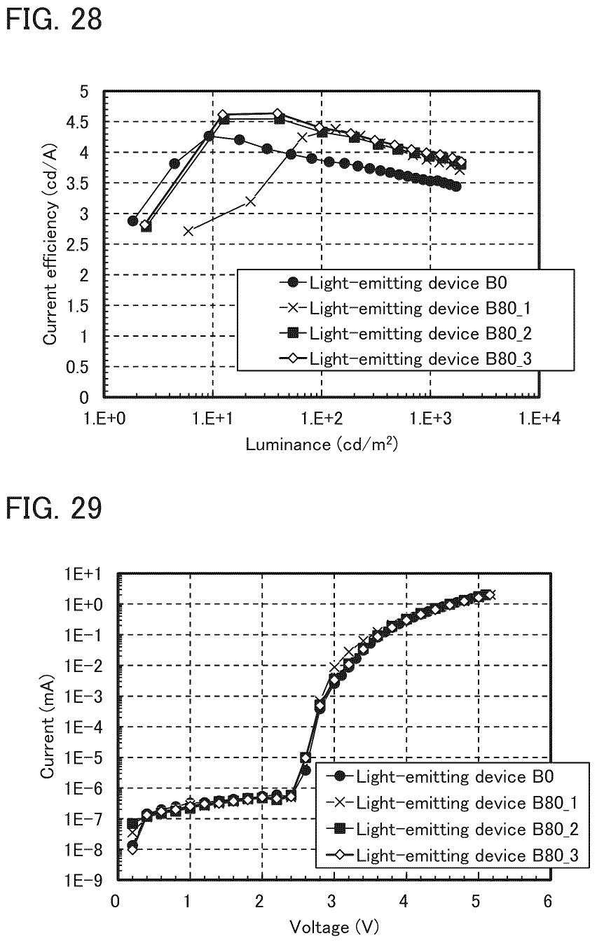

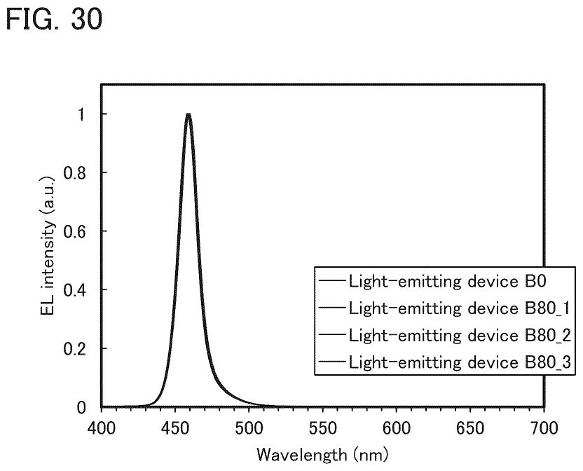

FIG. 21 shows the luminance-current density characteristics of the light-emitting device B0 and the light-emitting device B100_1 to the light-emitting device B100_3. FIG. 22 shows the luminance-voltage characteristics thereof. FIG. 23 shows the current efficiency-luminance characteristics thereof. FIG. 24 shows the current density-voltage characteristics thereof. FIG. 25 shows the emission spectra thereof. FIG. 26 shows the luminance-current density characteristics of the light-emitting device B0 and the light-emitting device B80_1 to the light-emitting device B80_3. FIG. 27 shows the luminance-voltage characteristics thereof. FIG. 28 shows the current efficiency-luminance characteristics thereof. FIG. 29 shows the current-voltage characteristics thereof. FIG. 30 shows the emission spectra thereof. Note that the luminance, CIE chromaticity, and emission spectra were measured at normal temperature with a spectroradiometer (SR-ULIR manufactured by TOPCON CORPORATION).

According to FIG. 21 to FIG. 30, it was found that, when undergoing heating in a vacuum atmosphere, the light-emitting devices subjected to the air exposure in an environment not irradiated with light less than 480 nm exhibited characteristics almost equivalent to or slightly preferable to those of the light-emitting device B0 not subjected to the air exposure. Note that a reduction in the current efficiency was observed in the light-emitting device B100_1 and the light-emitting device B80_1, each of which underwent the air exposure on the light-emitting layer.

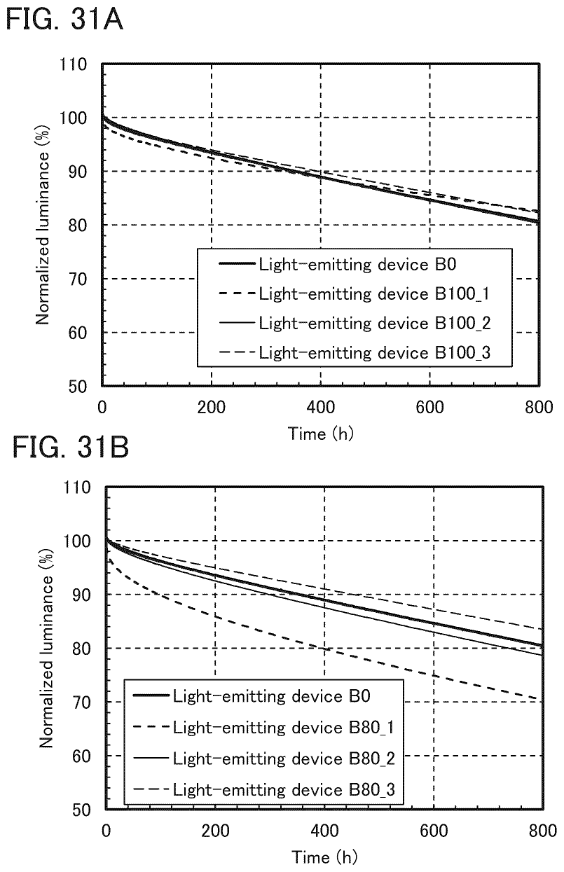

FIG. 31A and FIG. 31B show the results of measuring luminance as a function of driving time in constant-current driving at a current density of 50 mA/cm².

As described above, the light-emitting devices subjected to the air exposure in an environment not irradiated with light lower than 480 nm can have favorable initial characteristics and high reliability when undergoing heating at 80° C. for 2 hours or longer or heating at 100° C. for one hour or longer in a vacuum atmosphere. Note that it was also found that the light-emitting device subjected to the air exposure on the surface of the light-emitting layer was not limited thereto, and one or both of the initial characteristics and reliability were degraded. The above results revealed that an air exposure process (typically a photolithography process) on a hole-blocking layer was available. Thus, a material that is sensitive to heat (e.g., NBPhen) or a material containing metal (e.g., Alq₃) can be used for an electron-transport layer, so that a light-emitting device that is inexpensive and has stable characteristics can be provided.

### Example 2

This example shows results of examining characteristics of light-emitting devices under process conditions such that air exposure and heating in a vacuum atmosphere were performed on surfaces of a light-emitting layer, a first electron-transport layer (hole-blocking layer), and a second electron-transport layer in an environment not irradiated with light whose wavelength is less than 480 nm during processing. Note that a light-emitting device (light-emitting devices G0) subjected to neither air exposure nor heating in a vacuum atmosphere was also fabricated for comparison.

Structural formulae of compounds mainly used in this example are shown below.

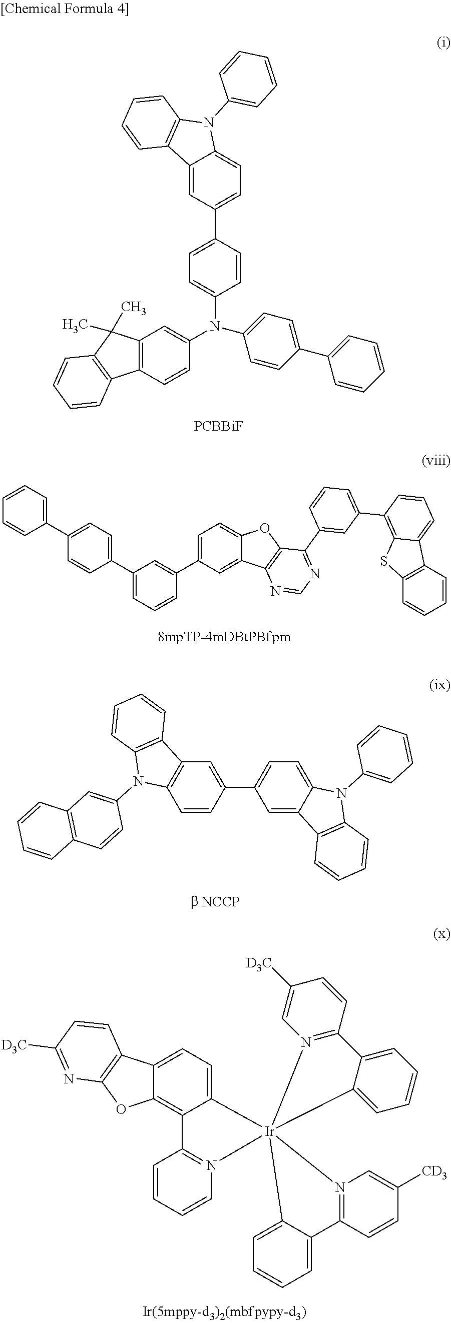

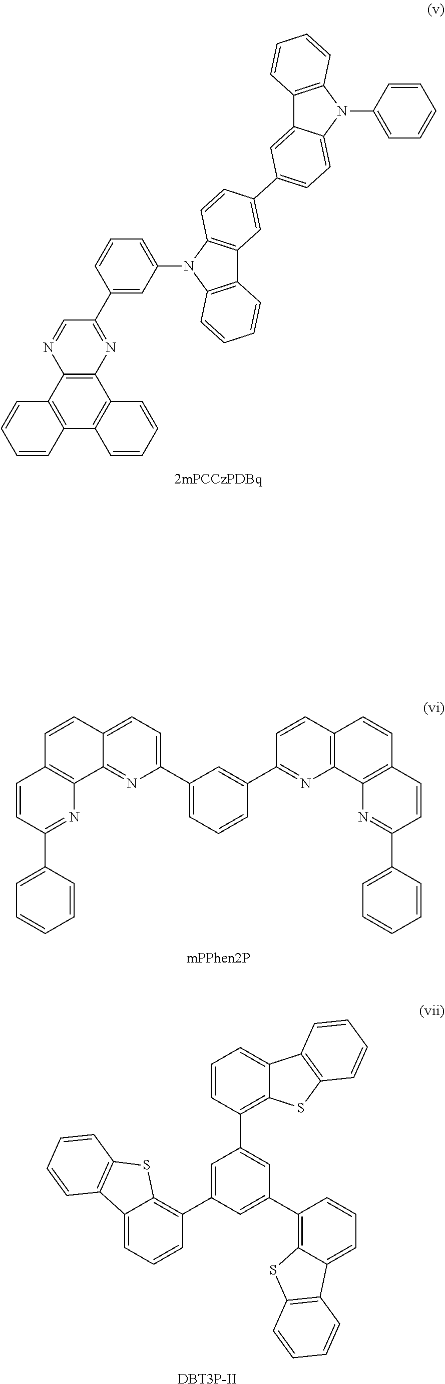 [SMILES: c1ccc(-n2c3ccccc3c3cc(-c4ccc5c(c4)c4ccccc4n5-c4cccc(-c5cnc6c7ccccc7c7ccccc7c6n5)c4)ccc32)cc1 ; c1ccc(-c2ccc3ccc4ccc(-c5cccc(-c6ccc7ccc8ccc(-c9ccccc9)nc8c7n6)c5)nc4c3n2)cc1 ; c1ccc2c(c1)sc1c(-c3cc(-c4cccc5c4sc4ccccc45)cc(-c4cccc5c4sc4ccccc45)c3)cccc12 ; "DBT3P-II"]

### (Fabrication Method of Light-Emitting Device G0)

First, 100-nm-thick alloy of silver, palladium, and copper (APC: Ag—Pd—Cu) and 10-nm-thick indium tin oxide containing silicon oxide (ITSO) were stacked over a glass substrate sequentially from the substrate side by a sputtering method as a reflective electrode and a transparent electrode, respectively and processed into a size of 2 mm×2 mm, whereby the first electrode 101 was formed.

After that, the substrate was transferred into a vacuum evaporation apparatus in which the pressure was reduced to approximately 1×10⁻⁴ Pa, vacuum baking was performed at 170° C. for 60 minutes in a heating chamber of the vacuum evaporation apparatus, and then the substrate was cooled down for approximately 30 minutes.

Then, the substrate was fixed to a substrate holder provided in the vacuum evaporation apparatus such that the surface over which the first electrode 101 was formed faced downward. Over an insulating film and the first electrode 101, the hole-injection layer 111 was formed by co-evaporation of N-(1,1′-biphenyl-4-yl)-N-[4-(9-phenyl-9H-carbazol-3-yl)phenyl]-9,9-dimethyl-9H-fluoren-2-amine (abbreviation: PCBBiF) represented by Structural Formula (i) above and a fluorine-containing electron-acceptor material with a molecular weight of 672 (OCHD-003) to have a thickness of 10 nm and a weight ratio of 1:0.03 (=PCBBiF: OCHD-003).

Over the hole-injection layer 111, a first hole-transport layer was formed to have a thickness of 10 nm by evaporation of PCBBiF.

Then, over the first hole-transport layer, the first light-emitting layer 113 was formed to have a thickness of 40 nm by co-evaporation of 8-(1,1′: 4′,1″-terphenyl-3-yl)-4-[3-(dibenzothiophen-4-yl)phenyl]-[1]benzofuro[3,2-d]pyrimidine (abbreviation: 8mpTP-4mDBtPBfpm) represented by Structural Formula (viii) above, 9-(2-naphthyl)-9′-phenyl-9H,9′H-3,3′-bicarbazole (abbreviation: βNCCP) represented by Structural Formula (ix) above, and [2-d₃-methyl-8-(2-pyridinyl-κN)benzofuro[2,3-b]pyridine-κC]bis[2-(5-d₃-methyl-2-pyridinyl-κN₂)phenyl-«C]iridium(III) (abbreviation: Ir(5mppy-d₃)₂(mbfpypy-d₃)) represented by Structural Formula (x) above.

After that, a first electron-transport layer was formed by evaporation of 2-{3-[3-(N-phenyl-9H-carbazol-3-yl)-9H-carbazol-9-yl]phenyl}dibenzo[f,h]quinoxaline (abbreviation: 2mPCCzPDBq) represented by Structural Formula (v) above to have a thickness of 10 nm, and a second electron-transport layer was formed by evaporation of 2,2′-(1,3-phenylene)bis(9-phenyl-1,10-phenanthroline) (abbreviation: mPPhen2P) represented by Structural Formula (vi) above to have a thickness of 15 nm, so that the electron-transport layer 114 was formed. Note that the first electron-transport layer also functions as an hole-blocking layer.

After that, the electron-injection layer 115 was formed with a thickness of 1 nm by evaporation of lithium fluoride (LiF), and then the second electrode 102 was formed by co-evaporation of silver (Ag) and magnesium (Mg) to have a thickness of 25 nm and a volume ratio of 1:0.1. In this manner, the light-emitting device of one embodiment of the present invention was fabricated. Over the second electrode 102, a cap layer with a thickness of 80 nm was formed by evaporation of 4,4′,4″-(benzene-1,3,5-triyl)tri(dibenzothiophene) (abbreviation: DBT3P-II) represented by Structural Formula (vii) above, so that light extraction efficiency was improved.

The light-emitting device was sealed using a glass substrate in a glove box containing a nitrogen atmosphere so as not to be exposed to the air (a UV curable sealing material was applied to surround the elements, only the sealing material was irradiated with UV while the light-emitting device was prevented from being irradiated with the UV, and heat treatment was performed at 80° C. under an atmospheric pressure for one hour), so that a light-emitting device G0 was fabricated.

### (Fabrication Method of Light-Emitting Device G100_1 to Light-Emitting Device G100_3)

A light-emitting device G100_1 was fabricated in the following manner: the light-emitting layer 113 was formed through the fabrication method of the light-emitting device G0 and then left in an air atmosphere for one hour; heating was performed at 100° C. (under a condition lower than 100° C. after the substrate temperature reached 90° C.) in a vacuum atmosphere (approx. 1×10⁻⁴ Pa) for one hour; and then the rest layers were formed.

A light-emitting device G100_2 was fabricated in the following manner: the first electron-transport layer (hole-blocking layer) was formed through the fabrication method of the light-emitting device G0 and then left in an air atmosphere for one hour; heating was performed at 100° C. (under a condition lower than 100° C. after the substrate temperature reached 90° C.) in a vacuum atmosphere (approx. 1×10⁻⁴ Pa) for one hour; and then the rest layers were formed.

A light-emitting device G100_3 was fabricated in the following manner: the second electron-transport layer was formed through the fabrication method of the light-emitting device G0 and then left in an air atmosphere for one hour; heating was performed at 100° C. (under a condition lower than 100° C. after the substrate temperature reached 90° C.) in a vacuum atmosphere (approx. 1×10⁻⁴ Pa) for one hour; and then the rest layers were formed.

### (Fabrication Method of Light-Emitting Device G80_1 to Light-Emitting Device G80_3)

A light-emitting device G80_1 was fabricated in the following manner: the light-emitting layer 113 was formed through the fabrication method of the light-emitting device G0 and then left in an air atmosphere for one hour; heating was performed at 80° C. (under a condition lower than 80° C. after the substrate temperature reached 70° C.) in a vacuum atmosphere (approx. 1×10⁻⁴ Pa) for two hours; and then the rest layers were formed.

A light-emitting device G80_2 was fabricated in the following manner: the first electron-transport layer (hole-blocking layer) was formed through the fabrication method of the light-emitting device G0 and then left in an air atmosphere for one hour; heating was performed at 80° C. (under a condition lower than 80° C. after the substrate temperature reached 70° C.) in a vacuum atmosphere (approx. 1×10⁻⁴ Pa) for two hours; and then the rest layers were formed.

A light-emitting device G80_3 was fabricated in the following manner: the second electron-transport layer was formed through the fabrication method of the light-emitting device G0 and then left in an air atmosphere for one hour; heating was performed at 80° C. (under a condition lower than 80° C. after the substrate temperature reached 70° C.) in a vacuum atmosphere (approx. 1×10⁻⁴ Pa) for two hours; and then the rest layers were formed.

### (Fabrication Method of Light-Emitting Device G0_1 to Light-Emitting Device G0_3)

A light-emitting device G0_1 was fabricated in the following manner: the light-emitting layer 113 was formed through the fabrication method of the light-emitting device G0 and then left in an air atmosphere for one hour; and then the rest layers were formed.

A light-emitting device G0_2 was fabricated in the following manner: the first electron-transport layer (hole-blocking layer) was formed through the fabrication method of the light-emitting device G0 and then left in an air atmosphere for one hour; and then the rest layers were formed.

A light-emitting device G0_3 was fabricated in the following manner: the second electron-transport layer was formed through the fabrication method of the light-emitting device G0 and then left in an air atmosphere for one hour; and then the rest layers were formed.

Device structures of the light-emitting device G0, the light-emitting device G100_1 to the light-emitting device G100_3, the light-emitting device G80_1 to the light-emitting device G80_3, and the light-emitting device G0_1 to the light-emitting device G0_3 are shown below.

TABLE 2

| | Thickness | Light-emitting device G | | | | | | | | | |
|---|---|---|---|---|---|---|---|---|---|---|---|
| | (nm) | 0 | 100_1 | 100_2 | 100_3 | 80_1 | 80_2 | 80_3 | 0_1 | 0_2 | 0_3 |
| Cap layer | 80 | DBT3P-II | | | | | | | | | |
| Second electrode | 25 | Ag:Mg (1:0.1) | | | | | | | | | |
| Electron-injection layer | 1 | LiF | | | | | | | | | |
| Air exposure/heat treatment | | — | — | — | 100° C. | — | — | 80° C. | — | — | ◯ |
| Electron-transport layer 2 | 15 | mPPhen2P | | | | | | | | | |
| Air exposure/heat treatment | | — | — | 100° C. | — | — | 80° C. | — | — | ◯ | — |
| Electron-transport layer 1 | 10 | 2mPCCzPDBq | | | | | | | | | |
| (hole-blocking layer) | | | | | | | | | | | |

| | | | | | | | | | | |
|---|---|---|---|---|---|---|---|---|---|---|
| Air exposure/heat treatment | — | 100° C. | — | — | 80° C. | — | — | ◯ | — | — |

| Light-emitting layer | | 40 | 8mpTP-4mDBtPBfpm:βNCCP:Ir(5mppy- |
|---|---|---|---|
| | | | d3)₂(mbfpypy-d3) |
| | | | (0.6:0.4:0.1) |
| Hole-transport layer | | 10 | PCBBiF |
| Hole-injection layer | | 10 | PCBBiF:OCHD-003 (1:0.03) |
| First | Transparent | 10 | ITSO |
| electrode | electrode | | |
| | Reflective | 100 | APC |
| | electrode | | |

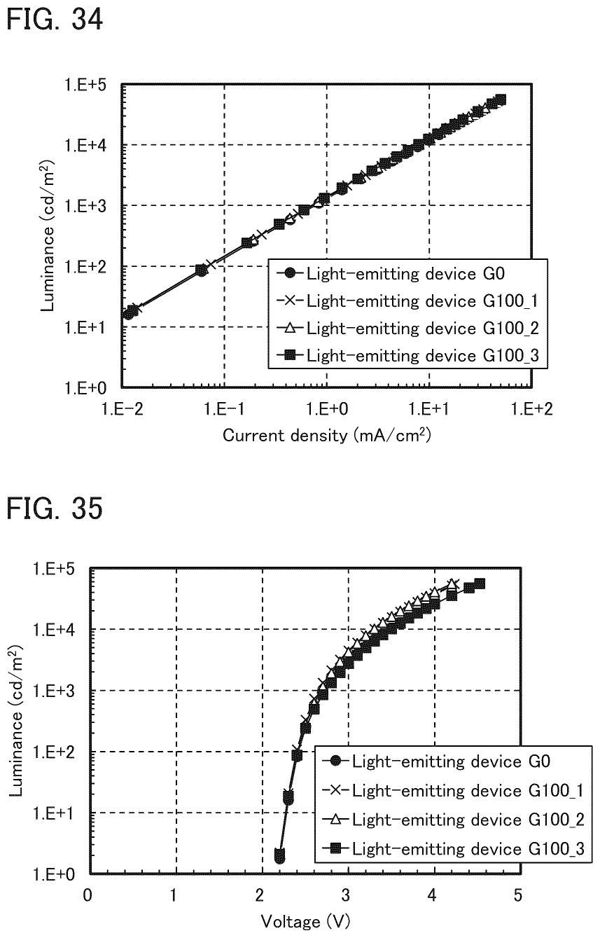

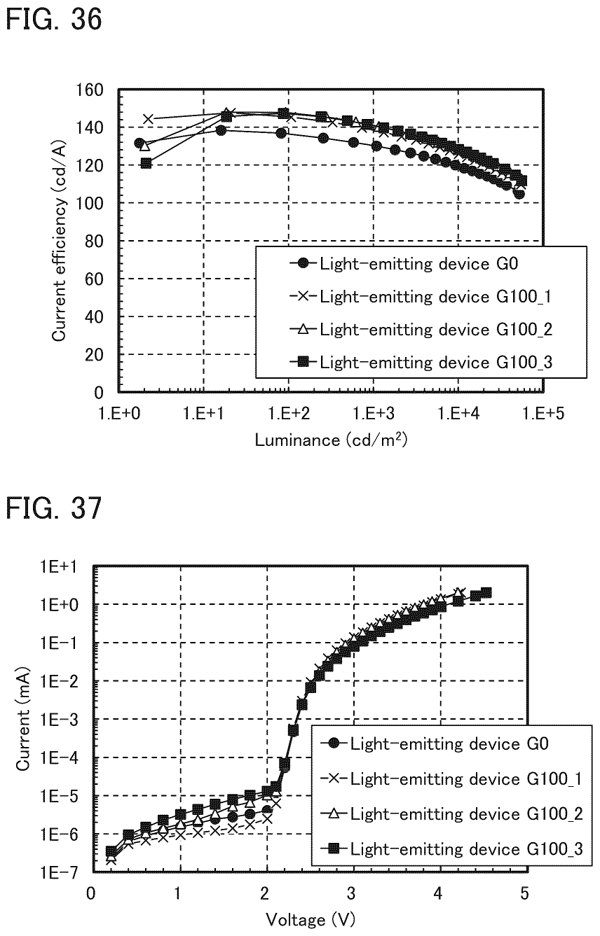

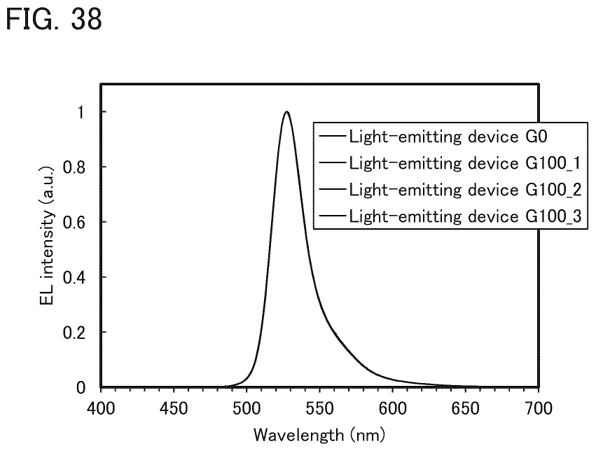

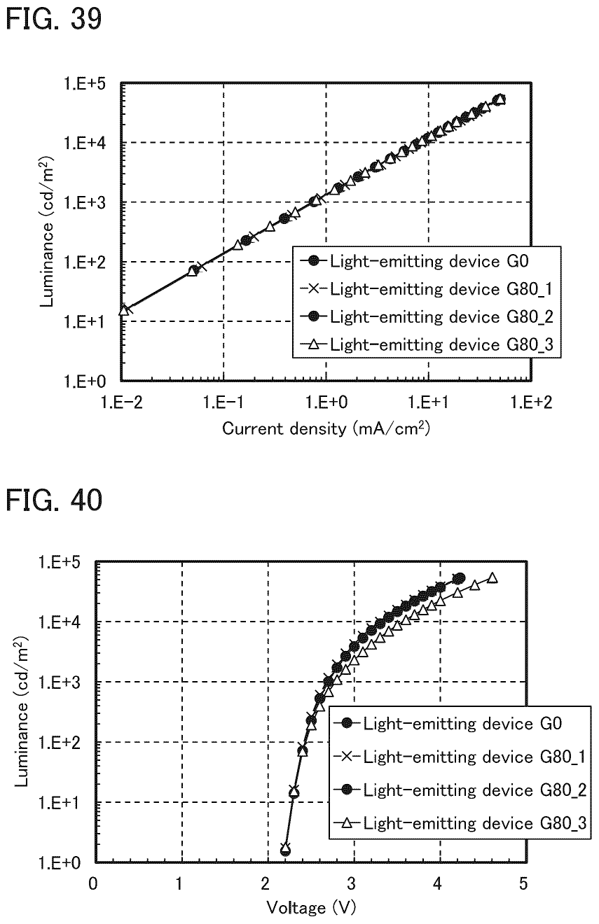

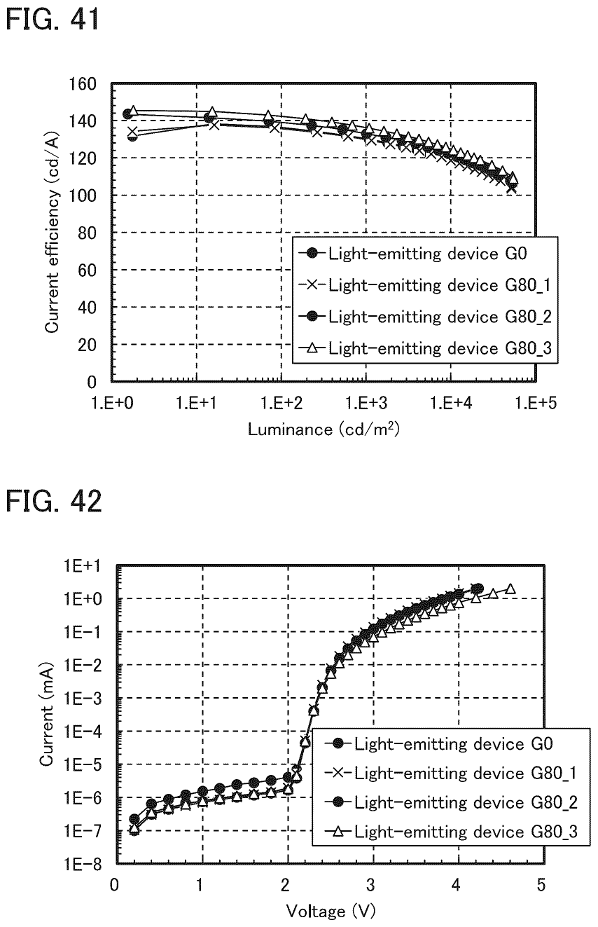

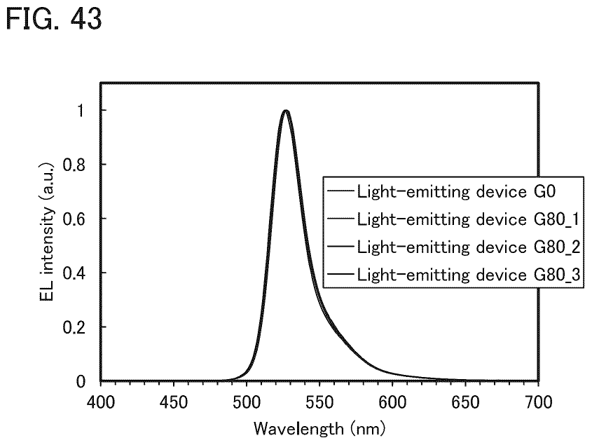

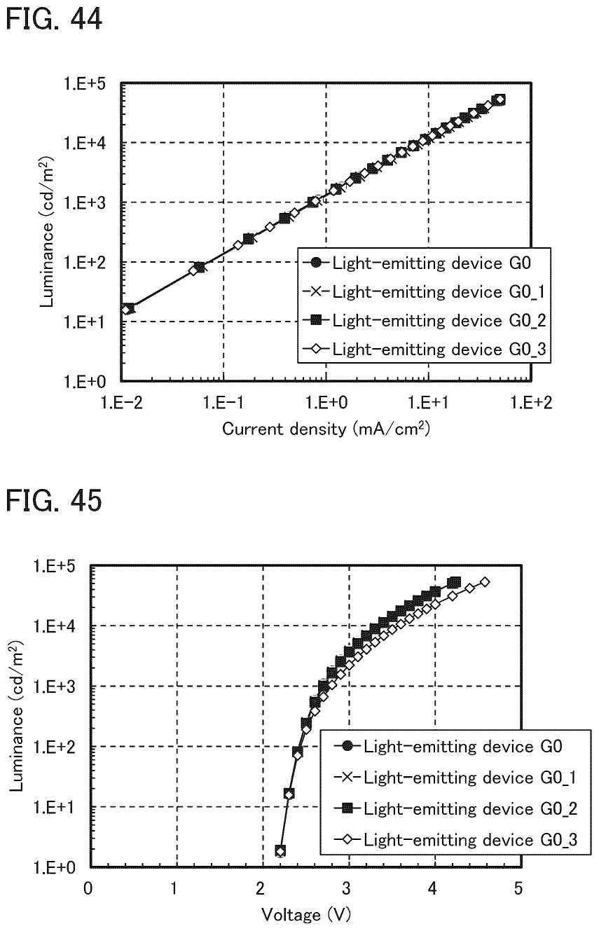

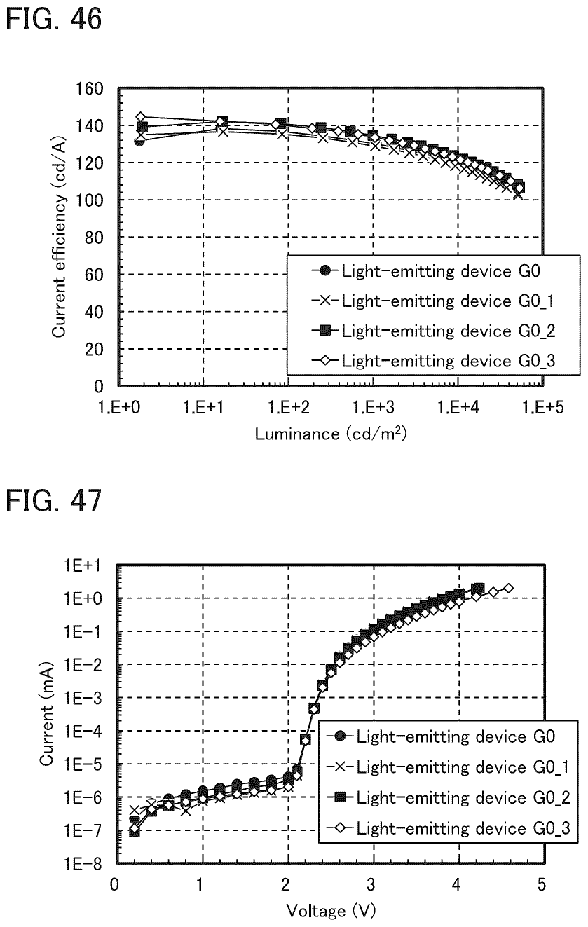

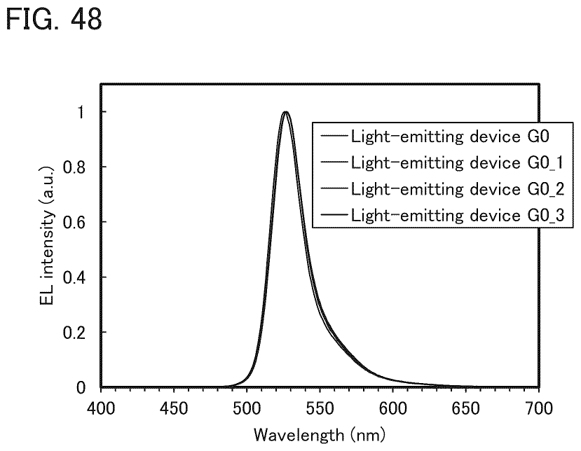

FIG. 34 shows the luminance-current density characteristics of the light-emitting device G0 and the light-emitting device G100_1 to the light-emitting device G100_3. FIG. 35 shows the luminance-voltage characteristics thereof. FIG. 36 shows the current efficiency-luminance characteristics thereof. FIG. 37 shows the current-voltage characteristics thereof. FIG. 38 shows the emission spectra thereof. FIG. 39 shows the luminance-current density characteristics of the light-emitting device G0 and the light-emitting device G80_1 to the light-emitting device G80_3. FIG. 40 shows the luminance-voltage characteristics thereof. FIG. 41 shows the current efficiency-luminance characteristics thereof. FIG. 42 shows the current-voltage characteristics thereof. FIG. 43 shows the emission spectra thereof. FIG. 44 shows the luminance-current density characteristics of the light-emitting device G0 and the light-emitting device G0_1 to the light-emitting device G0_3. FIG. 45 shows the luminance-voltage characteristics thereof. FIG. 46 shows the current efficiency-luminance characteristics thereof. FIG. 47 shows the current-voltage characteristics thereof. FIG. 48 shows the emission spectra thereof. Note that the luminance, CIE chromaticity, and emission spectra were measured at normal temperature with a spectroradiometer (SR-ULIR manufactured by TOPCON CORPORATION).

According to FIG. 34 to FIG. 48, it was found that, when undergoing heating in a vacuum atmosphere, the light-emitting devices subjected to the air exposure in an environment not irradiated with light less than 480 nm exhibited characteristics almost equivalent to or slightly preferable to those of the light-emitting device G0 not subjected to the air exposure.

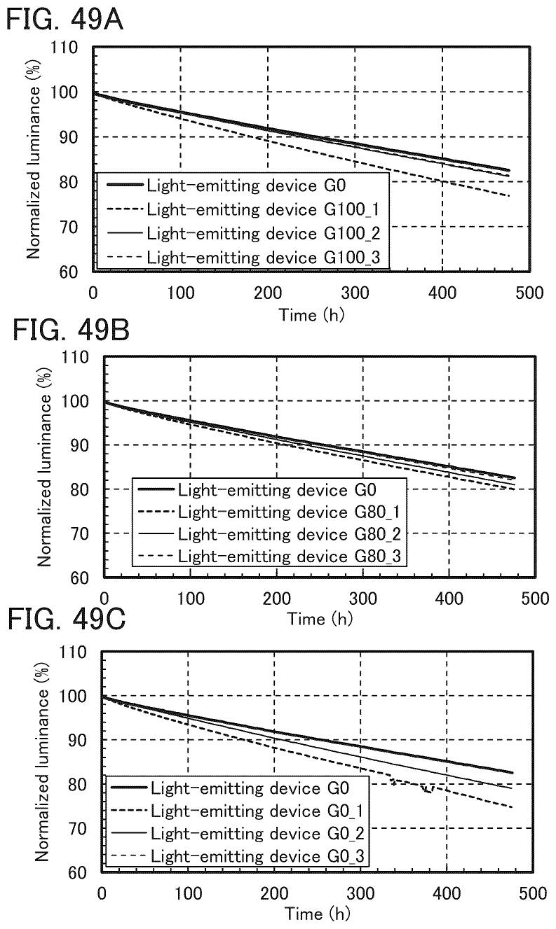

FIG. 49A to FIG. 49C show changes in luminance over driving time in constant-current driving at a current density of 50 mA/cm².

As described above, the light-emitting devices subjected to the air exposure in an environment not irradiated with light lower than 480 nm can have favorable initial characteristics and high reliability when undergoing heating at 80° C. for 2 hours or longer or heating at 100° C. for 1 hour or longer in a vacuum atmosphere. Note that it was also found that the light-emitting device subjected to the air exposure on the surface of the light-emitting layer was not limited thereto, and one or both of the initial characteristics and reliability were degraded.

The above results revealed that an air exposure process (typically a photolithography process) performed on a hole-blocking layer did not cause significant degradation of characteristics. Thus, a material that is sensitive to heat (e.g., NBPhen) or a material containing metal (e.g., Alq₃) can be used for an electron-transport layer, so that a light-emitting device that is inexpensive and has stable characteristics can be provided.

### Example 3

This example shows results of examining characteristics of light-emitting devices under process conditions such that air exposure and heating in a vacuum atmosphere were performed on surfaces of a light-emitting layer, a first electron-transport layer (hole-blocking layer), and a second electron-transport layer in an environment not irradiated with light whose wavelength is less than 480 nm during processing. Note that a light-emitting device (light-emitting devices R0) subjected to neither air exposure nor heating in a vacuum atmosphere was also fabricated for comparison.

Structural formulae of compounds mainly used in this example are shown below.

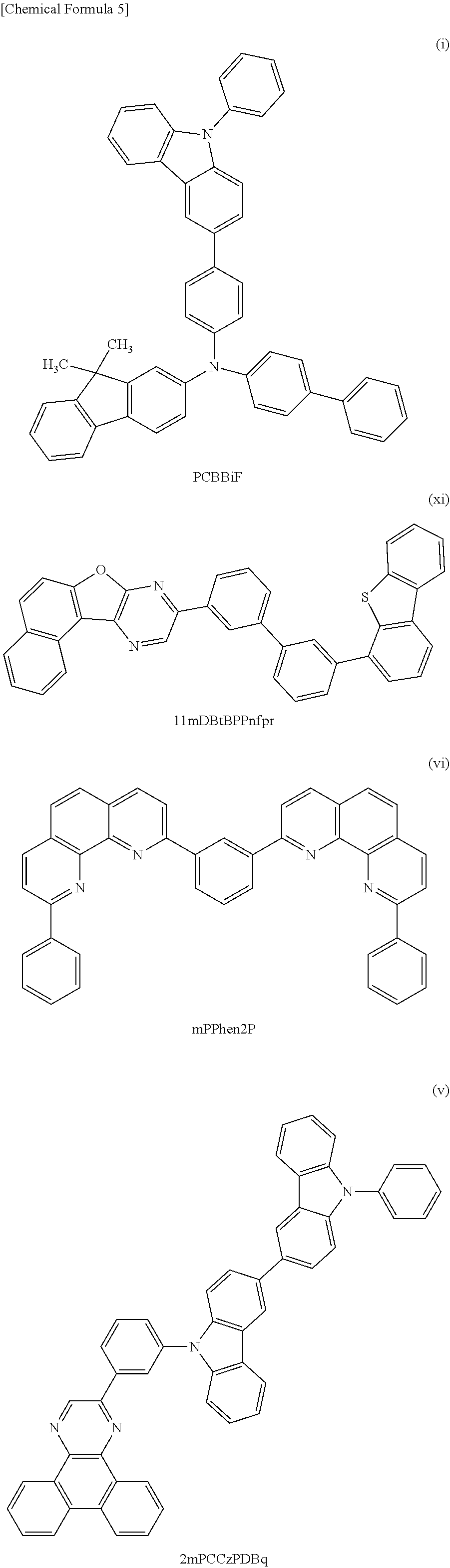

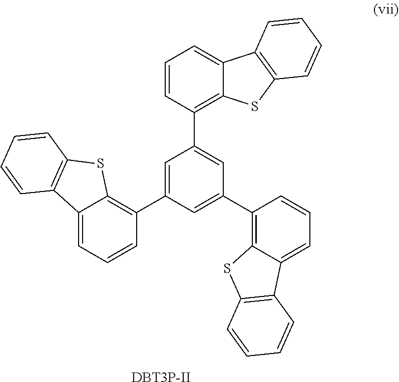 [SMILES: c1ccc2c(c1)sc1c(-c3cc(-c4cccc5c4sc4ccccc45)cc(-c4cccc5c4sc4ccccc45)c3)cccc12 ; "DBT3P-II"]

### (Fabrication Method of Light-Emitting Device R0)

First, 100-nm-thick alloy of silver, palladium, and copper (APC: Ag—Pd—Cu) and 10-nm-thick indium tin oxide containing silicon oxide (ITSO) were stacked over a glass substrate sequentially from the substrate side by a sputtering method as a reflective electrode and a transparent electrode, respectively and processed into a size of 2 mm×2 mm, whereby the first electrode 101 was formed.

After that, the substrate was transferred into a vacuum evaporation apparatus in which the pressure was reduced to approximately 1×10⁻⁴ Pa, vacuum baking was performed at 180° C. for 120 minutes in a heating chamber of the vacuum evaporation apparatus, and then the substrate was cooled down for approximately 30 minutes.

Then, the substrate was fixed to a substrate holder provided in the vacuum evaporation apparatus such that the surface over which the first electrode 101 was formed faced downward. Over an inorganic insulating film and the first electrode 101, the hole-injection layer 111 was formed by co-evaporation of N-(1,1′-biphenyl-4-yl)-N-[4-(9-phenyl-9H-carbazol-3-yl)phenyl]-9,9-dimethyl-9H-fluoren-2-amine (abbreviation: PCBBiF) represented by Structural Formula (i) above and a fluorine-containing electron-acceptor material with a molecular weight of 672 (OCHD-003) to have a thickness of 10 nm and a weight ratio of 1:0.03 (=PCBBiF: OCHD-003).

Over the hole-injection layer 111, a first hole-transport layer was formed to have a thickness of 25 nm by evaporation of PCBBiF.

Next, over the hole-transport layer, the light-emitting layer 113 was formed by co-evaporation of 11-[3′-(dibenzothiophen-4-yl) biphenyl-3-yl]phenanthro[9′,10′:4,5]furo[2,3-b]pyrazine (abbreviation: 11mDBtBPPnfpr) represented by Structure Formula (xi) above, PCBBiF, and a phosphorescent dopant OCPG-006 to have a thickness of 40 nm and a weight ratio of 0.7:0.3:0.05 (=11mDBtBPPnfpr:PCBBiF:OCPG-006).

Next, a first electron-transport layer was formed to have a thickness of 20 nm by evaporation of 2-{3-[3-(N-phenyl-9H-carbazol-3-yl)-9H-carbazol-9-yl]phenyl}dibenzo[f,h]quinoxaline (abbreviation: 2mPCCzPDBq) represented by Structure Formula (v) above, and then a second electron-transport layer was formed to have a thickness of 20 nm by evaporation of 2,2′-(1,3-phenylene)bis(9-phenyl-1,10-phenanthroline) (abbreviation: mPPhen2P) represented by Structure Formula (vi) above, whereby the electron-transport layer 114 was formed. Note that the first electron-transport layer also functions as a hole-blocking layer.

After that, the electron-injection layer 115 was formed with a thickness of 1 nm by evaporation of lithium fluoride (LiF), and then the second electrode 102 was formed by co-evaporation of silver (Ag) and magnesium (Mg) to have a thickness of 25 nm and a volume ratio of 1:0.1. In this manner, the light-emitting device of one embodiment of the present invention was fabricated. Over the second electrode 102, a cap layer with a thickness of 80 nm was formed by evaporation of 4,4′,4″-(benzene-1,3,5-triyl)tri(dibenzothiophene) (abbreviation: DBT3P-II) represented by Structural Formula (vii) above, so that light extraction efficiency was improved.

The light-emitting device was sealed using a glass substrate in a glove box containing a nitrogen atmosphere so as not to be exposed to the air (a UV curable sealing material was applied to surround the elements, only the sealing material was irradiated with UV while the light-emitting device was prevented from being irradiated with the UV, and heat treatment was performed at 80° C. under an atmospheric pressure for one hour), so that a light-emitting device R0 was fabricated.

### (Fabrication Method of Light-Emitting Device R100_1 to Light-Emitting Device R100_3)

A light-emitting device R100_1 was fabricated in the following manner: the light-emitting layer 113 was formed through the fabrication method of the light-emitting device R0 and then left in an air atmosphere for one hour; heating was performed at 100° C. (under a condition lower than 100° C. after the substrate temperature reached 90° C.) in a vacuum atmosphere (approx. 1×10⁻⁴ Pa) for one hour; and then the rest layers were formed.

A light-emitting device R100_2 was fabricated in the following manner: the first electron-transport layer (hole-blocking layer) was formed through the fabrication method of the light-emitting device R0 and then left in an air atmosphere for one hour; heating was performed at 100° C. (under a condition lower than 100° C. after the substrate temperature reached 90° C.) in a vacuum atmosphere (approx. 1×10⁻⁴ Pa) for one hour; and then the rest layers were formed.

A light-emitting device R100_3 was fabricated in the following manner: the second electron-transport layer was formed through the fabrication method of the light-emitting device R0 and then left in an air atmosphere for one hour; heating was performed at 100° C. (under a condition lower than 100° C. after the substrate temperature reached 90° C.) in a vacuum atmosphere (approx. 1×10⁻⁴ Pa) for one hour; and then the rest layers were formed.

### (Fabrication Method of Light-Emitting Device R80_1 to Light-Emitting Device R80_3)

A light-emitting device R80_1 was fabricated in the following manner: the light-emitting layer 113 was formed through the fabrication method of the light-emitting device R0 and then left in an air atmosphere for one hour; heating was performed at 80° C. (under a condition lower than 80° C. after the substrate temperature reached 70° C.) in a vacuum atmosphere (approx. 1×10⁻⁴ Pa) for two hours; and then the rest layers were formed.

A light-emitting device R80_2 was fabricated in the following manner: the first electron-transport layer (hole-blocking layer) was formed through the fabrication method of the light-emitting device R0 and then left in an air atmosphere for one hour; heating was performed at 80° C. (under a condition lower than 80° C. after the substrate temperature reached 70° C.) in a vacuum atmosphere (approx. 1×10⁻⁴ Pa) for two hours; and then the rest layers were formed.

A light-emitting device R80_3 was fabricated in the following manner: the second electron-transport layer was formed through the fabrication method of the light-emitting device R0 and then left in an air atmosphere for one hour; heating was performed at 80° C. (under a condition lower than 80° C. after the substrate temperature reached 70° C.) in a vacuum atmosphere (approx. 1×10⁻⁴ Pa) for two hours; and then the rest layers were formed.

### (Fabrication Method of Light-Emitting Device R0_1 to Light-Emitting Device R0_3)

A light-emitting device R0_1 was fabricated in the following manner: the light-emitting layer 113 was formed through the fabrication method of the light-emitting device R0 and then left in an air atmosphere for one hour; and then the rest layers were formed.

A light-emitting device R0_2 was fabricated in the following manner: the first electron-transport layer (hole-blocking layer) was formed through the fabrication method of the light-emitting device R0 and then left in an air atmosphere for one hour; and then the rest layers were formed.

A light-emitting device R0_3 was fabricated in the following manner: the second electron-transport layer was formed through the fabrication method of the light-emitting device R0 and then left in an air atmosphere for one hour; and then the rest layers were formed.

Device structures of the light-emitting device R0, the light-emitting device R100_1 to the light-emitting device R100_3, the light-emitting device R80_1 to the light-emitting device R80_3, and the light-emitting device R0_1 to the light-emitting device R0_3 are shown below.

TABLE 3

| | Thicknes | Light-emitting device R | | | | | | | | | |
|---|---|---|---|---|---|---|---|---|---|---|---|
| | (nm) | 0 | 100_1 | 100_2 | 100_3 | 80_1 | 80_2 | 80_3 | 0_1 | 0_2 | 0_3 |
| Cap layer | 80 | DBT3P-II | | | | | | | | | |
| Second electrode | 25 | Ag:Mg (1:0.1) | | | | | | | | | |
| Electron-injection layer | 1 | LiF | | | | | | | | | |
| Air exposure/heat treatment | | — | — | — | 100° C. | — | — | 80° C. | — | — | ◯ |
| Electron-transport layer 2 | 20 | mPPhen2P | | | | | | | | | |
| Air exposure/heat treatment | | — | — | 100° C. | — | — | 80° C. | — | — | ◯ | — |
| Electron-transport layer 1 | 20 | 2mPCCzPDBq | | | | | | | | | |
| (hole-blocking layer) | | | | | | | | | | | |

| | | | | | | | | | | |
|---|---|---|---|---|---|---|---|---|---|---|
| Air exposure/heat treatment | — | 100° C. | — | — | 80° C. | — | — | ◯ | — | — |

| Light-emitting layer | | 40 | 11mDBtBPPnfpr:PCBBiF:OCPG-006 |
|---|---|---|---|
| | | | (0.7:0.3:0.05) |
| Hole-transport layer | | 10 | PCBBiF |
| Hole-injection layer | | 10 | PCBBiF:OCHD-003 (1:0.03) |
| First | Transparent | 10 | ITSO |
| electrode | electrode | | |
| | Reflective | 100 | APC |
| | electrode | | |

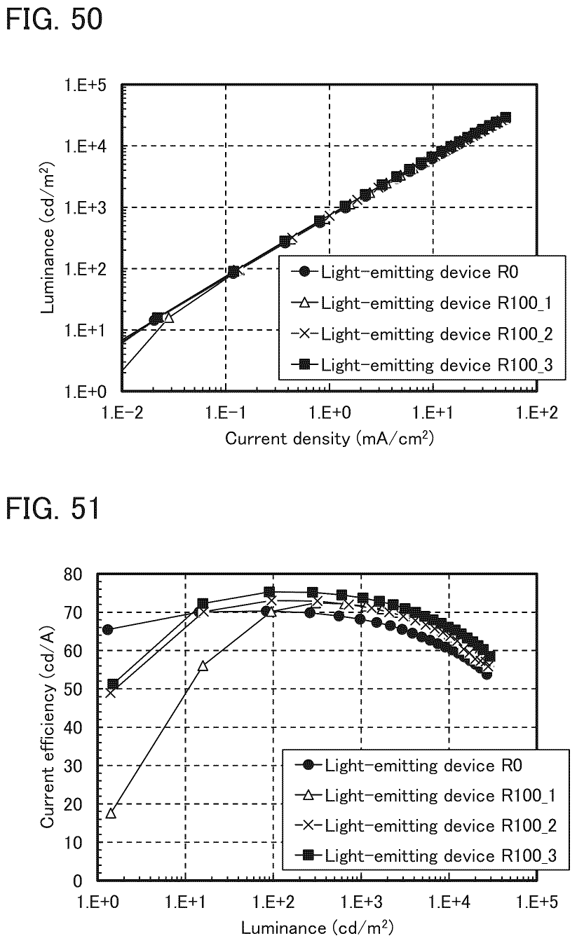

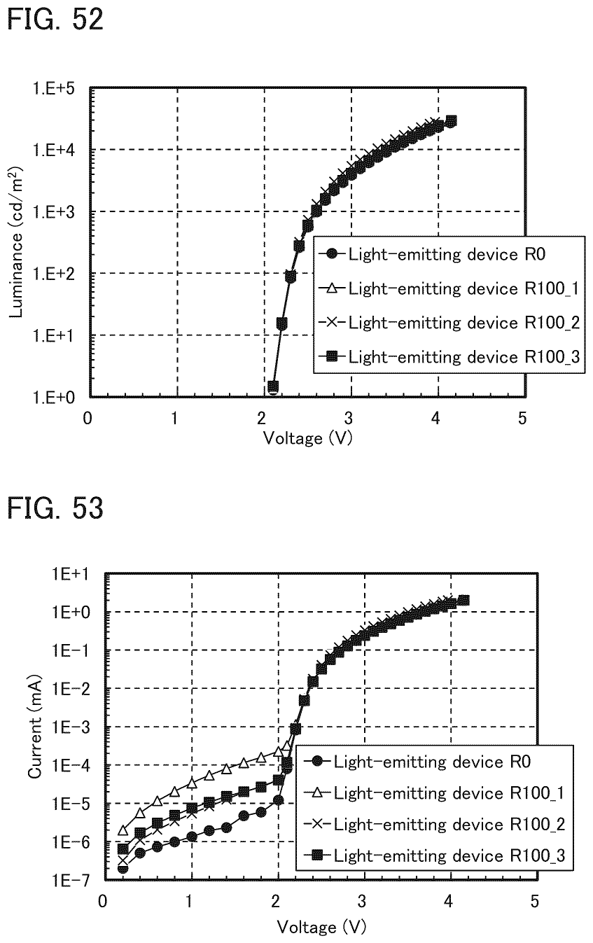

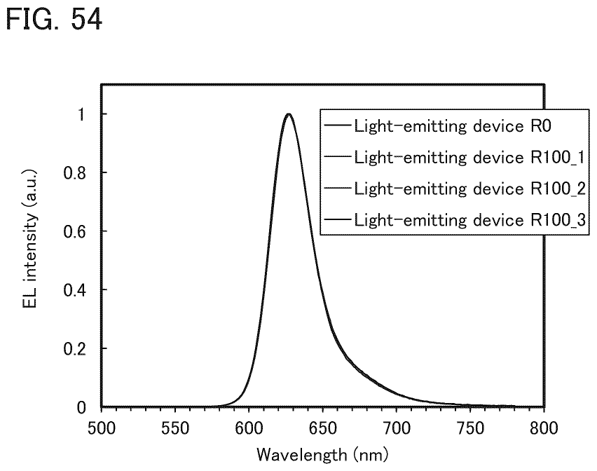

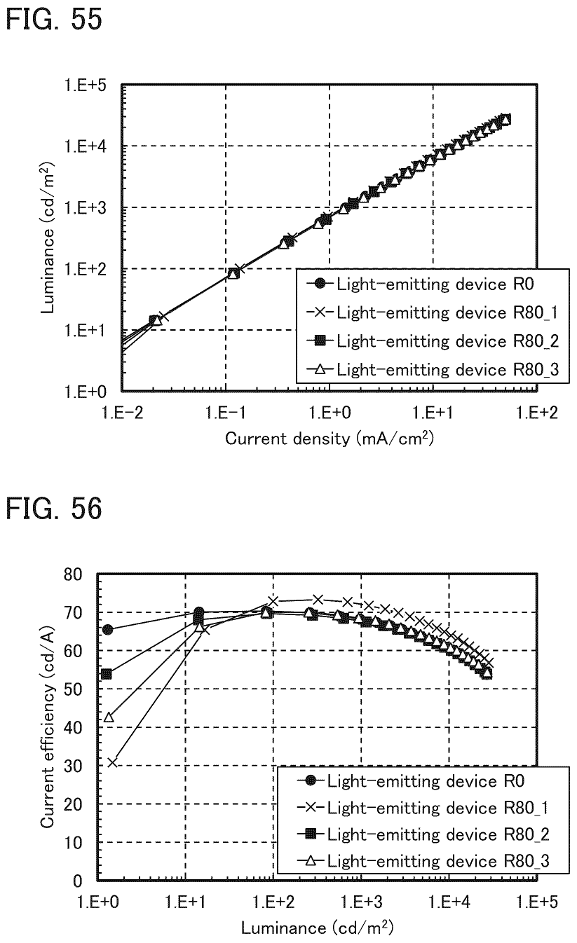

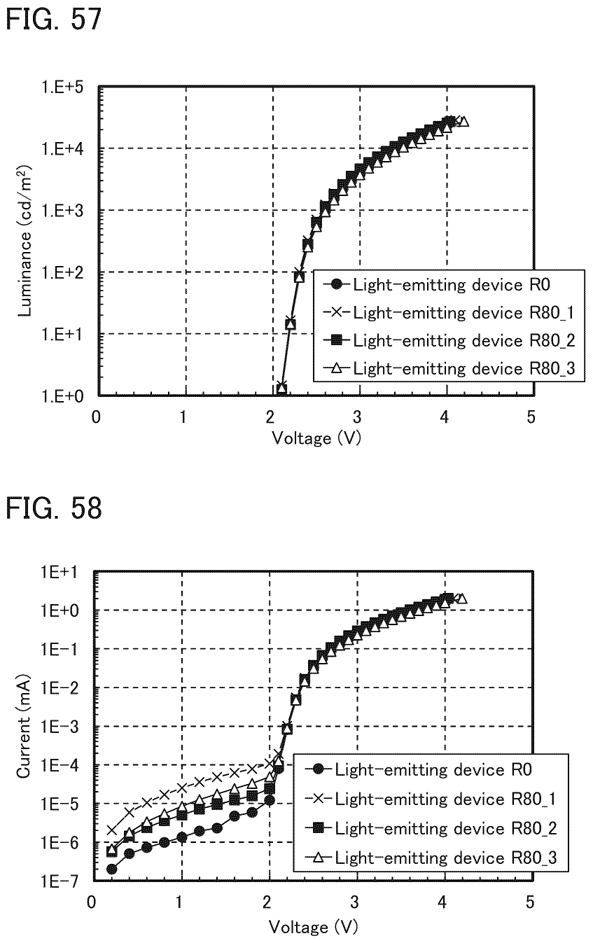

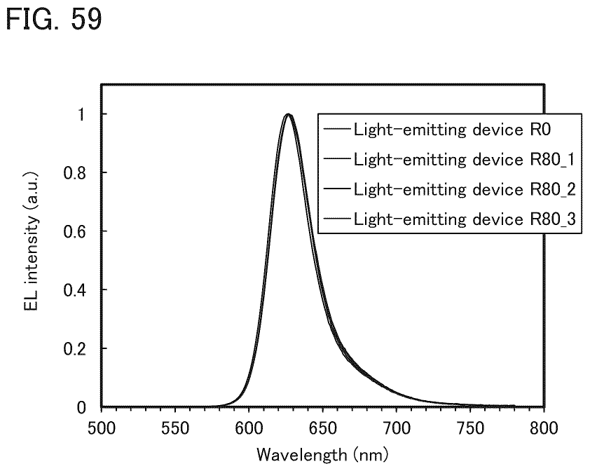

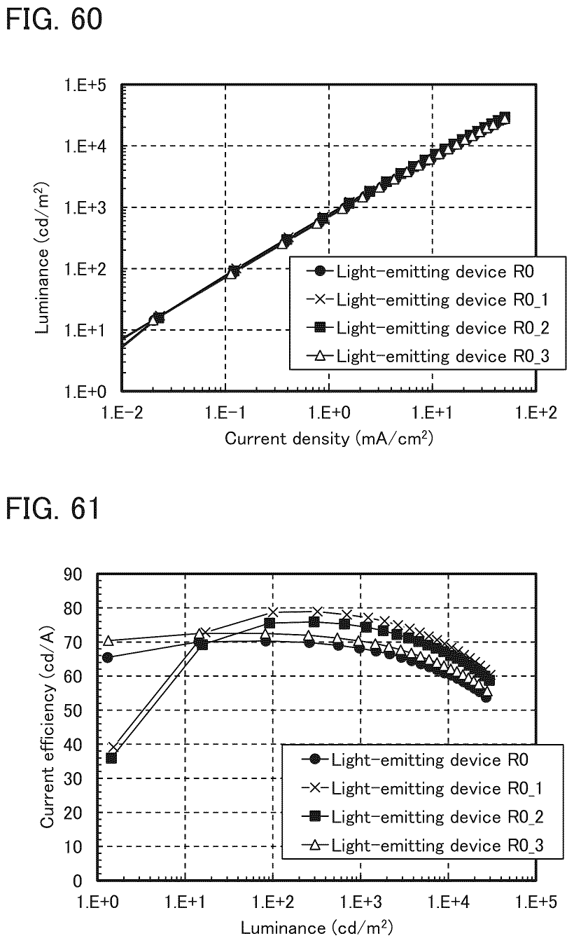

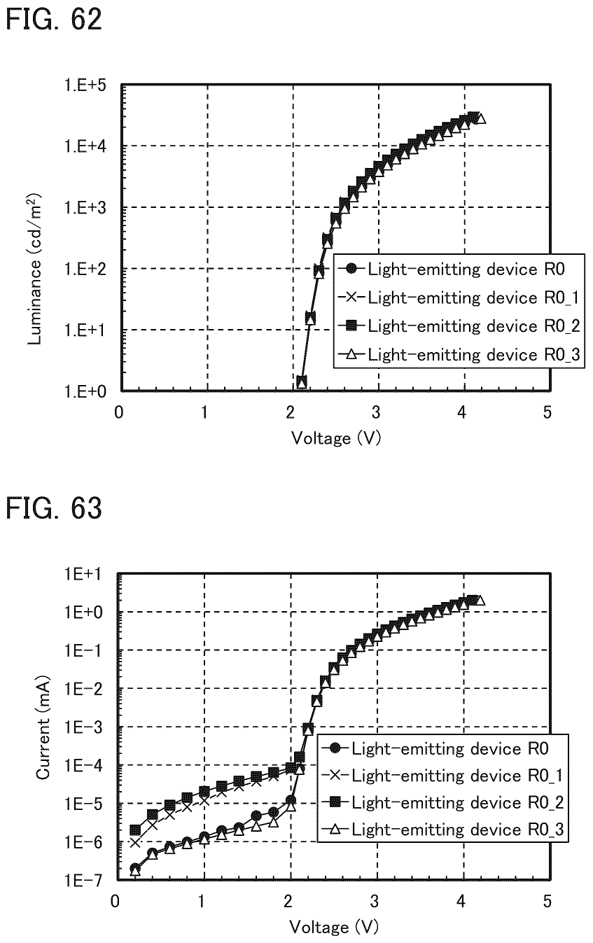

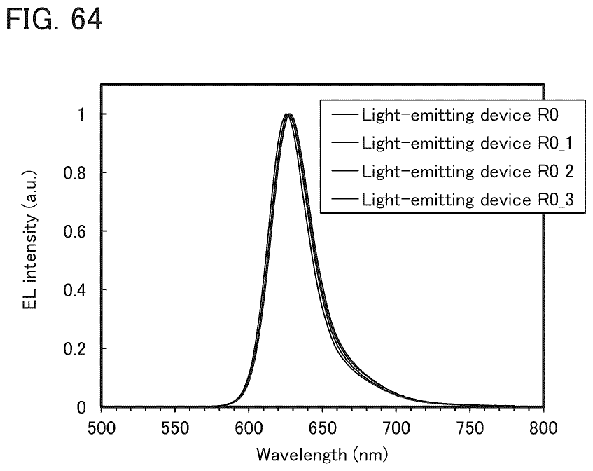

FIG. 50 shows the luminance-current density characteristics of the light-emitting device R0 and the light-emitting device R100_1 to the light-emitting device R100_3. FIG. 51 shows the current efficiency-luminance characteristics thereof. FIG. 52 shows the luminance-voltage characteristics thereof. FIG. 53 shows the current-voltage characteristics thereof. FIG. 54 shows the emission spectra thereof. FIG. 55 shows luminance-current density characteristics of the light-emitting device R0 and the light-emitting device R80_1 to the light-emitting device R80_3. FIG. 56 shows current efficiency-luminance characteristics thereof. FIG. 57 shows luminance-voltage characteristics thereof. FIG. 58 shows current-voltage characteristics thereof. FIG. 59 shows electroluminescence spectra thereof. FIG. 60 shows the luminance-current density characteristics of the light-emitting device R0 and the light-emitting device R0_1 to the light-emitting device R0_3. FIG. 61 shows the current efficiency-luminance characteristics thereof. FIG. 62 shows the luminance-voltage characteristics thereof. FIG. 63 shows current-voltage characteristics thereof. FIG. 64 shows electroluminescence spectra thereof. Note that the luminance, CIE chromaticity, and emission spectra were measured at normal temperature with a spectroradiometer (SR-ULIR manufactured by TOPCON CORPORATION).

According to FIG. 50 to FIG. 64, it was found that, when undergoing heating in a vacuum atmosphere, the light-emitting devices subjected to the air exposure in an environment not irradiated with light less than 480 nm exhibited characteristics almost equivalent to or slightly preferable to those of the light-emitting device R0 not subjected to the air exposure. Note that a reduction in the current efficiency was observed in the light-emitting device R100_1 and the light-emitting device R80_1, each of which underwent the air exposure on the light-emitting layer.

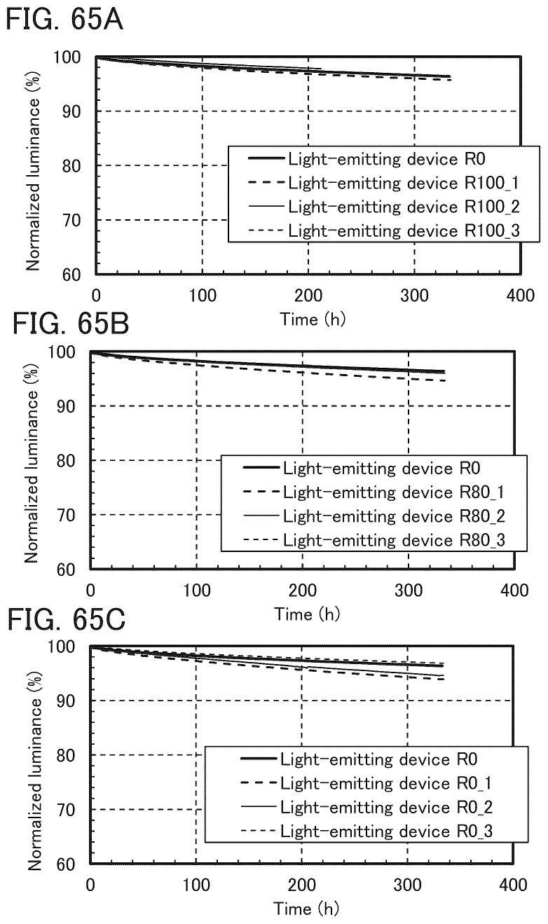

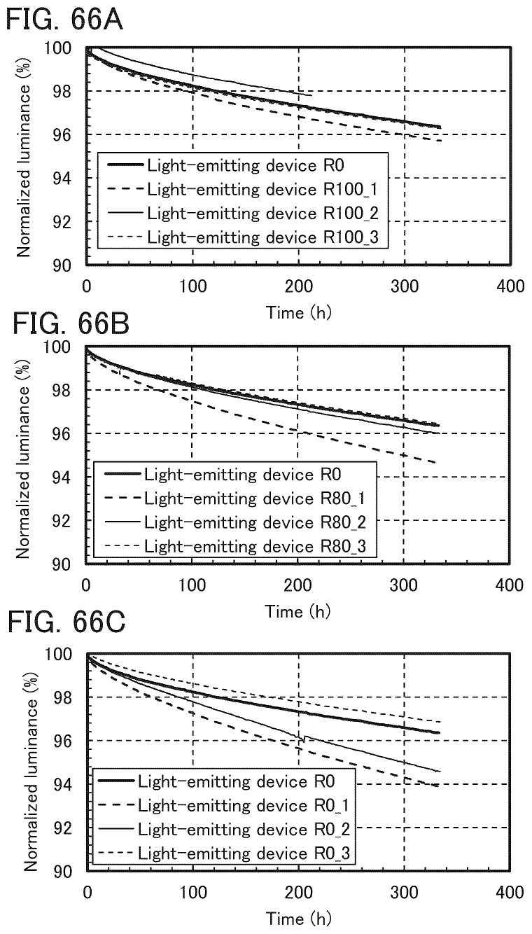

Next, FIG. 65A to FIG. 65C and FIG. 66A to FIG. 66C show changes in luminance over driving time in constant-current driving at a current density of 50 mA/cm², of the light-emitting device R0, the light-emitting device R100_1 to the light-emitting device R100_3, the light-emitting device R80_1 to the light-emitting device R80_3, and the light-emitting device R0_1 to the light-emitting device R0_3. Note that FIG. 66 shows graphs obtained by increasing the scale of the vertical axis of FIG. 65.

As described above, the light-emitting devices subjected to the air exposure in an environment not irradiated with light lower than 480 nm can have favorable initial characteristics and high reliability when undergoing heating at 80° C. for 2 hours or longer or heating at 100° C. for 1 hour or longer in a vacuum atmosphere. Note that it was also found that the light-emitting device subjected to the air exposure on the surface of the light-emitting layer was not limited thereto, and one or both of the initial characteristics and reliability were degraded.

The above results revealed that an air exposure process (typically a photolithography process) on a hole-blocking layer was available. Thus, a material that is sensitive to heat (e.g., NBPhen) or a material containing metal (e.g., Alq₃) can be used for an electron-transport layer, so that a light-emitting device that is inexpensive and has stable characteristics can be provided.

### REFERENCE NUMERALS

100A: display apparatus, 100B: display apparatus, 100C: display apparatus, 100D: display apparatus, 100E: display apparatus, 100: insulator, 101a: first electrode, 101b: first electrode, 101c: first electrode, 101d: first electrode, 101: first electrode, 102: second electrode, 103a: EL layer, 103B: EL layer, 103b: EL layer, 103Bf: EL film, 103c: EL layer, 103d: EL layer, 103G: EL layer, 103Gf: EL film, 103R: EL layer, 103Rf: EL film, 103: EL layer, 104: layer, 104R: layer, 104G: layer, 104B: layer, 105: layer, 110B: subpixel, 110G: subpixel, 110R: subpixel, 110: subpixel, 111a: hole-injection layer, 111b: hole-injection layer, 111c: hole-injection layer, 111d: hole-injection layer, 111: hole-injection layer, 112: hole-transport layer, 112a: hole-transport layer, 112b: hole-transport layer, 112c_2: hole-transport layer, 112d_2: hole-transport layer, 112c_1: hole-transport layer, 112d_1: hole-transport layer, 112B: conductive layer, 112R: conductive layer, 113: light-emitting layer, 113a: light-emitting layer, 113b: light-emitting layer, 113c_1: light-emitting layer, 113c_2: light-emitting layer, 113d_1: light-emitting layer, 113d_2: light-emitting layer, 114: electron-transport layer, 114a: electron-transport layer, 114b: electron-transport layer, 114c_1: electron-transport layer, 114d_1: electron-transport layer, 114-2: electron-transport layer, 114-1c_2: electron-transport layer, 114-1d_2: electron-transport layer, 114-2_2: electron-transport layer, 115: electron-injection layer, 116: charge-generation layer, 116c: charge-generation layer, 116d: charge-generation layer, 117: P-type layer, 117c: P-type layer, 117d: P-type layer, 118c: electron-relay layer, 118d: electron-relay layer, 118: electron-relay layer, 119: N-type layer, 119c: N-type layer, 119d: N-type layer, 120: substrate, 122: resin layer, 125f: inorganic insulating film, 125: inorganic insulating layer, 126R: conductive layer, 126G: conductive layer, 126B: conductive layer, 127a: insulating layer, 127f: insulating film, 127: insulating layer, 128: layer, 129R: conductive layer, 129G: conductive layer, 129B: conductive layer, 130a: light-emitting device, 130B: light-emitting device, 130b: light-emitting device, 130c: light-emitting device, 130d: light-emitting device, 130G: light-emitting device, 130R: light-emitting device, 130: light-emitting device, 131: protective layer, 132B: coloring layer, 132G: coloring layer, 132R: coloring layer, 140: connection portion, 141: region, 142: adhesive layer, 151B: conductive layer, 151C: conductive layer, 151cf: conductive film, 151f: conductive film, 151G: conductive layer, 151R: conductive layer, 151: conductive layer, 152B: conductive layer, 152C: conductive layer, 152f: conductive film, 152G: conductive layer, 152R: conductive layer, 152: conductive layer, 153: insulating layer, 155: common electrode, 156B: insulating layer, 156C: insulating layer, 156f: insulating film, 156G: insulating layer, 156R: insulating layer, 156: insulating layer, 157: light-blocking layer, 158B: sacrificial layer, 158Bf: sacrificial film, 158G: sacrificial layer, 158Gf: sacrificial film, 158R: sacrificial layer, 158Rf: sacrificial film, 159B: mask layer, 159Bf: mask film, 159G: mask layer, 159Gf: mask film, 159R: mask layer, 159Rf: mask film, 166: conductive layer, 171: insulating layer, 172: conductive layer, 173: insulating layer, 174: insulating layer, 175: insulating layer, 176: plug, 177: pixel portion, 178: pixel, 179: conductive layer, 190B: resist mask, 190G: resist mask, 190R: resist mask, 191: resist mask, 201: transistor, 204: connection portion, 205: transistor, 211: insulating layer, 213: insulating layer, 214: insulating layer, 215: insulating layer, 221: conductive layer, 222a: conductive layer, 222b: conductive layer, 223: conductive layer, 224B: conductive layer, 224C: conductive layer, 224G: conductive layer, 224R: conductive layer, 231: semiconductor layer, 240: capacitor, 241: conductive layer, 242: connection layer, 243: insulating layer, 245: conductive layer, 254: insulating layer, 255: insulating layer, 256: plug, 261: insulating layer, 271: plug, 280: display module, 281: display portion, 282: circuit portion, 283a: pixel circuit, 283: pixel circuit portion, 284a: pixel, 284: pixel portion, 285: terminal portion, 286: wiring portion, 290: FPC, 291: substrate, 292: substrate, 301: substrate, 310: transistor, 311: conductive layer, 312: low-resistance region, 313: insulating layer, 314: insulating layer, 315: element isolation layer, 351: substrate, 352: substrate, 353: FPC, 354: IC, 355: wiring, 356: circuit, 501: first electrode, 502: second electrode, 513: charge-generation layer, 700A: electronic device, 700B: electronic device, 721: housing, 723: wearing portion, 727: earphone portion, 750: earphone, 751: display panel, 753: optical member, 756: display region, 757: frame, 758: nose pad, 800A: electronic device, 800B: electronic device, 820: display portion, 821: housing, 822: communication portion, 823: wearing portion, 824: control portion, 825: image capturing portion, 827: earphone portion, 832: lens, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7151: remote control, 7171: housing, 7173: stand, 7200: laptop personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9171: portable information terminal, 9172: portable information terminal, 9173: tablet terminal, 9200: portable information terminal, 9201: portable information terminal

1. A light-emitting device comprising:
a first electrode, a second electrode, a first layer between the first electrode and the second electrode, and a second layer between the first layer and the second electrode,
wherein the light-emitting device is one of a plurality of light-emitting devices over an insulating surface,
wherein the first electrode is separated from adjacent first electrodes in the plurality of light-emitting devices,
wherein the second electrode is shared by the plurality of light-emitting devices,
wherein the first layer is separated from adjacent first layers in the plurality of light-emitting devices,
wherein the second layer is shared by the plurality of light-emitting devices,
wherein the first layer comprises a light-emitting layer comprising a light-emitting substance and a first electron-transport layer,
wherein the second layer comprises a second electron-transport layer,
wherein the first electron-transport layer is between the light-emitting layer and the second electron-transport layer,
wherein the first electron-transport layer comprises a first compound having an electron-transport property and a glass transition temperature higher than or equal to 110° C., and
wherein the second electron-transport layer comprises a second compound having an electron-transport property.

2. The light-emitting device according to claim 1,
wherein the first electron-transport layer has a thickness greater than or equal to 5 nm and less than or equal to 30 nm.

3. A light-emitting device comprising:
a first electrode, a second electrode, a first layer between the first electrode and the second electrode, and a second layer between the first layer and the second electrode,
wherein the light-emitting device is one of a plurality of light-emitting devices over an insulating surface,
wherein the first electrode is separated from adjacent first electrodes in the plurality of light-emitting devices,
wherein the second electrode is shared by the plurality of light-emitting devices,
wherein the first layer is separated from adjacent first layers in the plurality of light-emitting devices,
wherein the second layer is a continuous layer shared by the plurality of light-emitting devices,
wherein the first layer comprises a light-emitting layer comprising a light-emitting substance and a first electron-transport layer,
wherein the second layer comprises a second electron-transport layer and an electron-injection layer,
wherein the first electron-transport layer is between the light-emitting layer and the second electron-transport layer,
wherein the electron-injection layer is between the second electron-transport layer and the second electrode,
wherein the first electron-transport layer comprises a first compound having an electron-transport property and a glass transition temperature higher than or equal to 110° C.,
wherein the second electron-transport layer comprises a second compound having an electron-transport property, and
wherein the electron-injection layer comprises an alkali metal, an alkaline earth metal, or a compound of any of the alkali metal and the alkaline earth metal.

4. The light-emitting device according to claim 1, wherein the first compound is an organic compound comprising any one of triazine, pyridine, a furodiazine skeleton, and a diazine skeleton.

5. The light-emitting device according to claim 4, wherein the first compound is an organic compound having a dibenzoquinoxaline skeleton.

6. The light-emitting device according to claim 1, wherein the second compound is an organic compound comprising any one of a phenanthroline skeleton, a triazine skeleton, a pyridine skeleton, a furodiazine skeleton, and a diazine skeleton or an organometallic complex comprising a quinolinol ligand.

7. The light-emitting device according to claim 1, wherein the second compound is an organic compound comprising any one of a phenanthroline skeleton, a triazine skeleton, a pyridine skeleton, and a pyrimidine skeleton or an organometallic complex comprising a quinolinol ligand.

8. The light-emitting device according to claim 1,
wherein the first compound is an organic compound comprising any one of a triazine skeleton, a pyridine skeleton, a furodiazine skeleton, and a diazine skeleton, and
wherein the second compound is an organic compound comprising any one of a phenanthroline skeleton, a triazine skeleton, a pyridine skeleton, and a pyrimidine skeleton or an organometallic complex comprising a quinolinol ligand.

9. The light-emitting device according to claim 1,
wherein the first compound is an organic compound comprising a dibenzoquinoxaline skeleton, and
wherein the second compound is an organic compound comprising any one of a phenanthroline skeleton, a triazine skeleton, a pyridine skeleton, a furodiazine skeleton, and a diazine skeleton or an organometallic complex comprising a quinolinol ligand.

10. A method for manufacturing a light-emitting apparatus comprising:
forming a plurality of first electrodes over an insulating surface;
forming a first film including a light-emitting layer and a first electron-transport layer over the plurality of first electrodes;
performing a photolithography process on the first film to form a plurality of first layers over the respective first electrodes;
performing a heat treatment at higher than or equal to 80° C. and lower than 110° C. at a vacuum degree lower than or equal to 1×10⁻⁴ Pa;
forming a second layer over the plurality of first layers; and
forming a second electrode over the second layer.

11. The method for manufacturing a light-emitting apparatus according to claim 10,
wherein the heat treatment is performed for longer than or equal to one hour and shorter than or equal to three hours.

12. The method for manufacturing a light-emitting apparatus according to claim 10, wherein a wavelength of light irradiation from the formation of the first film until the formation of the second electrode is greater than or equal to 480 nm.
